(19) United States
(12) Patent Application Publication
(10) Pub. No.: US 2024/0371901 A1
(43) Pub. Date: Nov. 7, 2024

(54) SOLID-STATE IMAGING DEVICE AND ELECTRONIC APPARATUS

(71) Applicant: SONY SEMICONDUCTOR SOLUTIONS CORPORATION, KANAGAWA (JP)

(72) Inventors: KENJI FUJIYAMA, KANAGAWA (JP); HIROFUMI YAMASHITA, KANAGAWA (JP); YOSUKE SATAKE, KANAGAWA (JP)

(21) Appl. No.: 18/692,394

(22) PCT Filed: Mar. 24, 2022
(86) PCT No.: PCT/JP2022/013974

§ 371 Date: Mar. 15, 2024

(30) Foreign Application Priority Data
Sep. 30, 2021 (JP) 2021-160954

(51) Int. Cl. H01L 27/146; H04N 25/778; H04N 25/78

(52) U.S. Cl. CPC H01L 27/1463; H01L 27/14612; H04N 25/778; H04N 25/78

(57) ABSTRACT

The present disclosure relates to a solid-state imaging device and an electronic apparatus capable of achieving a high resolution and a high dynamic range by arranging a large-sized pixel transistor in a case where only one pixel transistor other than a transfer transistor is arrangeable within one pixel. The solid-state imaging device includes a pixel array unit that includes pixels each having a photoelectric conversion element, a floating diffusion region, a transfer transistor, and one pixel transistor other than a transfer transistor, the pixels being two-dimensionally arranged in a matrix shape. The one pixel transistor is any one of a reset transistor, a switching transistor, an amplification transistor, or a selection transistor. The present disclosure is applicable to a solid-state imaging device having small-sized pixels, for example.

### TECHNICAL FIELD

The present disclosure relates to a solid-state imaging device and an electronic apparatus, and particularly to a solid-state imaging device and an electronic apparatus capable of achieving a high resolution and a high dynamic range by arranging a large-sized pixel transistor in a case where only one pixel transistor other than a transfer transistor is arrangeable within one pixel.

### BACKGROUND ART

A pixel size of each pixel has been decreasing with improvement of resolutions of image sensors. For example, there is such a type of image sensor which includes unit pixel groups each including 1×3 pixels forming three pixels to share a reset transistor, an amplification transistor, and a selection transistor and being arranged mirror-symmetrically to cope with the decrease in the pixel size (for example, see PTL 1).

### Citation List

### Patent Literature

### [PTL]

US Patent Application Publication No. 2021/0136303

### SUMMARY

### Technical Problem

It is predicted that further size reduction of pixels in the future may bring about such a situation where only one pixel transistor other than a transfer transistor is providable within one pixel. It is thus necessary to examine a more preferable pixel arrangement to cope with the case where only one pixel transistor other than a transfer transistor is providable within one pixel.

The present disclosure has been developed in consideration of the abovementioned circumstances, and achieves a high resolution and a high dynamic range by arranging a large-sized pixel transistor in a case where only one pixel transistor other than a transfer transistor is arrangeable within one pixel.

### Solution to Problem

A solid-state imaging device according to a first aspect of the present disclosure includes a pixel array unit that includes pixels each having a photoelectric conversion element, a floating diffusion region, a transfer transistor, and one pixel transistor other than a transfer transistor, the pixels being two-dimensionally arranged in a matrix shape. The one pixel transistor is any one of a reset transistor, a switching transistor, an amplification transistor, or a selection transistor.

An electronic apparatus according to a second aspect of the present disclosure includes a solid-state imaging device including a pixel array unit that includes pixels each having a photoelectric conversion element, a floating diffusion region, a transfer transistor, and one pixel transistor other than a transfer transistor, the pixels being two-dimensionally arranged in a matrix shape. The one pixel transistor is any one of a reset transistor, a switching transistor, an amplification transistor, or a selection transistor.

According to the first and second aspects of the present disclosure, there is provided a pixel array unit which includes pixels that are two-dimensionally arranged in a matrix shape and that each have a photoelectric conversion element, a floating diffusion region, a transfer transistor, and one pixel transistor other than a transfer transistor. The one pixel transistor is any one of a reset transistor, a switching transistor, an amplification transistor, or a selection transistor.

Each of the solid-state imaging device and the electronic apparatus may be either an independent device or a module incorporated in a different device.

### BRIEF DESCRIPTION OF DRAWINGS

FIG. 1 is a block diagram depicting a schematic configuration of a solid-state imaging device to which the technology of the present disclosure is applied.

FIG. 2 is a plan diagram depicting a configuration example of a pixel.

FIG. 3 depicts cross-sectional diagrams illustrating the configuration example of the pixel.

FIG. 4 depicts plan diagrams explaining a first configuration example of pixel units.

FIG. 5 depicts diagrams explaining an arrangement of color filters and on-chip lenses.

FIG. 6 is a diagram depicting a circuit configuration example of two pixel units connected to each other via an FD link.

FIG. 7 is a plan diagram depicting a detailed arrangement of the respective pixels within the pixel units in the first configuration example.

FIG. 8 depicts diagrams explaining metal wires in the first configuration example.

FIG. 9 is a plan diagram explaining a second configuration example of the pixel units.

FIG. 10 depicts diagrams explaining the metal wires in the second configuration example.

FIG. 11 depicts diagrams illustrating a different example of the metal wires in the second configuration example.

FIG. 12 is a diagram depicting a circuit configuration example in a case where four pixel units are connected.

FIG. 13 is a plan diagram explaining a third configuration example of the pixel units.

FIG. 14 depicts diagrams explaining the metal wires in the third configuration example.

FIG. 15 is a plan diagram explaining a fourth configuration example of the pixel units.

FIG. 16 depicts diagrams explaining the metal wires in the fourth configuration example.

FIG. 17 is a diagram depicting a modification of a circuit configuration in a case where two pixel units are connected in a lateral direction.

FIG. 18 is a plan diagram explaining a fifth configuration example of the pixel units.

FIG. 19 depicts diagrams explaining the metal wires in the fifth configuration example.

FIG. 20 is a plan diagram explaining a sixth configuration example of the pixel units.

FIG. 21 depicts diagrams explaining the metal wires in the sixth configuration example.

FIG. 22 is a plan diagram explaining a seventh configuration example of the pixel units.

FIG. 23 depicts diagrams explaining the metal wires in the seventh configuration example.

FIG. 24 depicts diagrams explaining a different in-pixel layout of the pixels.

FIG. 25 depicts diagrams explaining a different in-pixel layout of the pixels.

FIG. 26 is a diagram depicting a pixel configuration example in a case where a pixel transistor is a Fin-type transistor.

FIG. 27 is a diagram explaining an arrangement example of the sixth in-pixel layout arranged in the first configuration example of the pixel units.

FIG. 28 depicts diagrams explaining the metal wires in FIG. 27.

FIG. 29 is a diagram explaining an arrangement example of the sixth in-pixel layout arranged in the third configuration example of the pixel units.

FIG. 30 depicts diagrams explaining the metal wires in FIG. 29.

FIG. 31 is a diagram explaining an arrangement example of the sixth in-pixel layout arranged in the fourth configuration example of the pixel units.

FIG. 32 depicts diagrams explaining the metal wires in FIG. 31.

FIG. 33 depicts diagrams explaining variations of the FD link.

FIG. 34 depicts diagrams explaining variations of the FD link.

FIG. 35 depicts diagrams explaining variations of the FD link.

FIG. 36 is a diagram depicting a first example of a different in-pixel layout of the pixels.

FIG. 37 is a plan diagram explaining an eighth configuration example of the pixel units.

FIG. 38 is a diagram explaining an arrangement example of the pixel transistors in the eighth configuration example of the pixel units.

FIG. 39 is a plan diagram depicting a wiring example of the metal wires in the eighth configuration example of the pixel units.

FIG. 40 is a diagram explaining a different arrangement example of the pixel transistors in the eighth configuration example of the pixel units.

FIG. 41 is a diagram explaining a connection example of the FD links of the pixel units according to the eighth configuration example.

FIG. 42 is a diagram explaining a connection example of the FD links of the pixel units according to the eighth configuration example.

FIG. 43 is a diagram explaining a connection example of the FD links of the pixel units according to the eighth configuration example.

FIG. 44 is a diagram explaining a connection example of the FD links of the pixel units according to the eighth configuration example.

FIG. 45 is a plan diagram explaining a ninth configuration example of the pixel units.

FIG. 46 is a diagram explaining an arrangement example of the pixel transistors in the ninth configuration example of the pixel units.

FIG. 47 is a diagram depicting a circuit configuration example of the pixel unit according to the ninth configuration example.

FIG. 48 is a plan diagram depicting a wiring example of the metal wires of the pixel units in the ninth configuration example.

FIG. 49 is a plan diagram depicting a wiring example of the metal wires of the pixel units in the ninth configuration example.

FIG. 50 is a plan diagram depicting a modification of the wiring example of the metal wires of the pixel units in the ninth configuration example.

FIG. 51 is a diagram explaining a connection example of the FD links of the pixel units according to the ninth configuration example.

FIG. 52 is a diagram explaining a connection example of the FD links of the pixel units according to the ninth configuration example.

FIG. 53 is a diagram explaining a connection example of the FD links of the pixel units according to the ninth configuration example.

FIG. 54 is a diagram explaining a connection example of the FD links of the pixel units according to the ninth configuration example.

FIG. 55 is a diagram explaining a connection example of the FD links of the pixel units according to the ninth configuration example.

FIG. 56 is a diagram explaining a connection example of the FD links of the pixel units according to the ninth configuration example.

FIG. 57 depicts diagrams explaining an arrangement example of the pixel transistors of the pixel units in the ninth configuration example.

FIG. 58 depicts diagrams explaining an arrangement example of the pixel transistors of the pixel units in the ninth configuration example.

FIG. 59 depicts diagrams explaining an arrangement example of the pixel transistors of the pixel units in the ninth configuration example.

FIG. 60 depicts diagrams explaining an arrangement example of the pixel transistors of the pixel units in the ninth configuration example.

FIG. 61 depicts diagrams explaining an arrangement example of the pixel transistors of the pixel units in the ninth configuration example.

FIG. 62 is a block diagram depicting a configuration example of an imaging device as an electronic apparatus to which the technology of the present disclosure is applied.

FIG. 63 is a diagram explaining use examples of an image sensor.

FIG. 64 is a block diagram depicting an example of schematic configuration of a vehicle control system.

FIG. 65 is a diagram of assistance in explaining an example of installation positions of an outside-vehicle information detecting section and an imaging section.

### DESCRIPTION OF EMBODIMENTS

Modes for carrying out the technology of the present disclosure (hereinafter referred to as embodiments) will hereinafter be described with reference to the accompanying drawings. The description will be presented in the following order.
1. Schematic configuration example of solid-state imaging device
2. Configuration example of pixel
3. First configuration example of pixel unit (1×4)
4. Second configuration example of pixel unit (1×4)
5. Third configuration example of pixel unit (1×4)
6. Fourth configuration example of pixel unit (1×4)
7. Fifth configuration example of pixel unit (1×4)
8. Sixth configuration example of pixel unit (1×4)
9. Seventh configuration example of pixel unit (1×4)
10. Other examples of in-pixel layout
11. Configuration example of Fin-type transistor
12. Arrangement example of pixel unit in case of adoption of sixth in-pixel layout (first configuration example)
13. Arrangement example of pixel unit in case of adoption sixth in-pixel layout (third configuration example)
14. Arrangement example of pixel unit in case of adoption sixth in-pixel layout (fourth configuration example)
15. FD link variations
16. Eighth configuration example of pixel unit (2×2)
17. Ninth configuration example of pixel unit (4×2)
18. Summary
19. Examples of application to electronic apparatus
20. Examples of application to mobile body

Identical or similar parts in the figures referred to in the following description will be given identical or similar reference signs to avoid repetition of the same explanation where appropriate. Each of the figures is a schematic illustration, and contains a relation between a thickness and a planar size, a thickness ratio of respective layers, and others different from those in actual situations. Moreover, a relation between respective sizes and a ratio contained in one figure may be different from those in the other figures.

In addition, definitions of upward, downward, longitudinal, lateral, and other directions included in the following description are only definitions presented for convenience of explanation. It is hence not intended that these definitions limit the technical ideas of the present disclosure. For example, observation in an up-down direction is converted into observation in a left-right direction by rotation of a target by 90 degrees, and is converted into the opposite direction by rotation of the target by 180 degrees.

### 1. Schematic Configuration Example of Solid-State Imaging Device

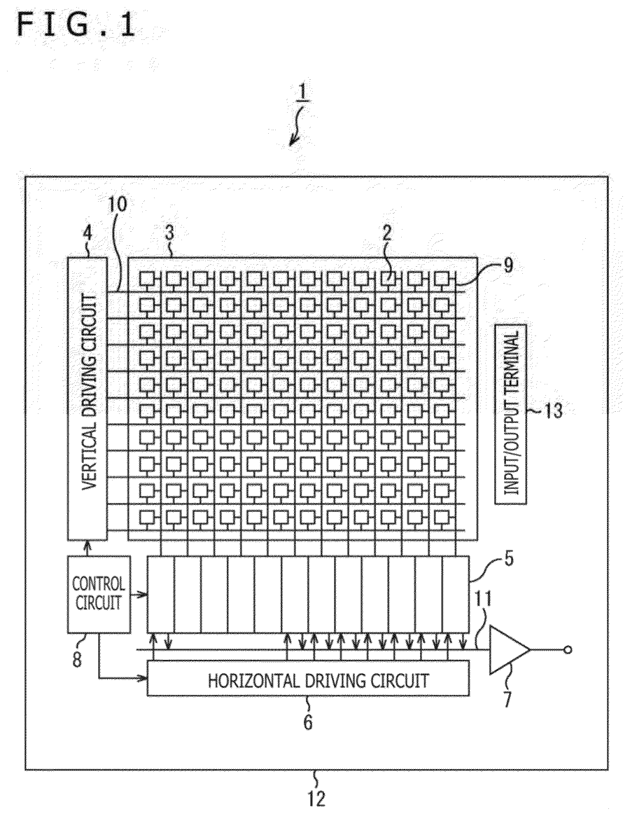

FIG. 1 depicts a schematic configuration of a solid-state imaging device to which the present technology is applied.

A solid-state imaging device 1 in FIG. 1 includes a semiconductor substrate 12 including a semiconductor such as silicon (Si), and further includes a pixel array unit 3 containing pixels 2 two-dimensionally arranged in a matrix shape on the semiconductor substrate 12, and peripheral circuit units provided around the pixel array unit 3. The peripheral circuit units include a vertical driving circuit 4, column signal processing circuits 5, a horizontal driving circuit 6, an output circuit 7, a control circuit 8, and others.

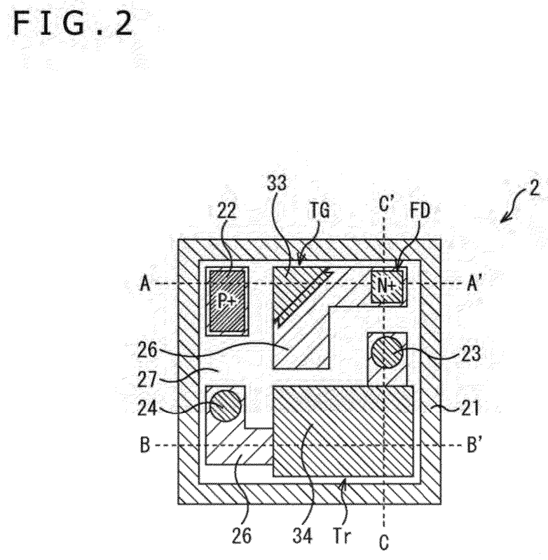

Each of the pixels 2 arrayed in the pixel array unit 3 includes a photodiode PD as a photoelectric conversion element, and a transfer transistor TG, and has a shared pixel structure for sharing a readout circuit, which is a circuit provided to read signal charge generated by the photodiode PD, between a plurality of the pixels. As will specifically be described below with reference to FIG. 2 and the following figures, each of the pixels 2 includes a floating diffusion region FD, the photodiode PD, and the transfer transistor TG, and shares the floating diffusion region FD, a switching transistor FDG, an amplification transistor AMP, a reset transistor RST, or a selection transistor SEL with different pixels 2.

The control circuit 8 receives an input clock, and data for commanding an operation mode or the like, and outputs such data as internal information associated with the solid-state imaging device 1. Specifically, the control circuit 8 generates a clock signal and a control signal as references for operations of the vertical driving circuit 4, the column signal processing circuits 5, the horizontal driving circuit 6, and others in reference to a vertical synchronized signal, a horizontal driving circuit, and a master clock. In addition, the control circuit 8 outputs the generated clock signal and control signal to the vertical driving circuit 4, the column signal processing circuits 5, the horizontal driving circuit 6, and others.

The vertical driving circuit 4 includes a shift register, for example, and is configured to select a predetermined pixel driving wire 10, supply a pulse for driving the pixels 2 to the selected pixel driving wire 10, and drive the pixels 2 for each unit of one or more rows. For example, the vertical driving circuit 4 sequentially selects and scans the respective pixels 2 of the pixel array unit 3 in a vertical direction for each row, and causes a pixel signal corresponding to signal charge generated according to a light quantity received by a photoelectric conversion unit of each of the pixels 2 to be supplied to the corresponding column signal processing circuit 5, via a vertical signal line 9.

The column signal processing circuit 5 is disposed for each column of the pixels 2, and performs signal processing such as noise removal for signals output from the pixels 2 in one row for each pixel column. For example, the column signal processing circuit 5 performs signal processing, such as CDS (Correlated Double Sampling) for removing fixed pattern noise unique to each pixel, and AD conversion.

The horizontal driving circuit 6 includes a shift register, for example, and sequentially outputs a horizontal scanning pulse to sequentially select the respective column signal processing circuits 5 and cause each of the column signal processing circuits 5 to output a pixel signal to a horizontal signal line 11.

The output circuit 7 performs signal processing for signals sequentially supplied from each of the column signal processing circuits 5 via the horizontal signal line 11, and outputs the processed signal. For example, the output circuit 7 executes only buffering in some cases, or carries out processing such as black level adjustment, column variation correction, and various types of digital signal processing in other cases. An input/output terminal 13 exchanges signals with the outside.

The solid-state imaging device 1 configured as above is a CMOS image sensor called a column AD system where the column signal processing circuit 5 performing CDS processing and AD conversion processing is disposed for each pixel column.

Moreover, the solid-state imaging device 1 is a back-illuminated MOS-type solid-state imaging device which introduces light from a rear side of the semiconductor substrate 12, which is a side opposite to a front side where the pixel transistors are formed.

Note that the substrate on which the solid-state imaging device 1 is formed may be a laminated substrate produced by laminating a plurality of semiconductor substrates, rather than the single semiconductor substrate 12.

### 2. Configuration Example of Pixel

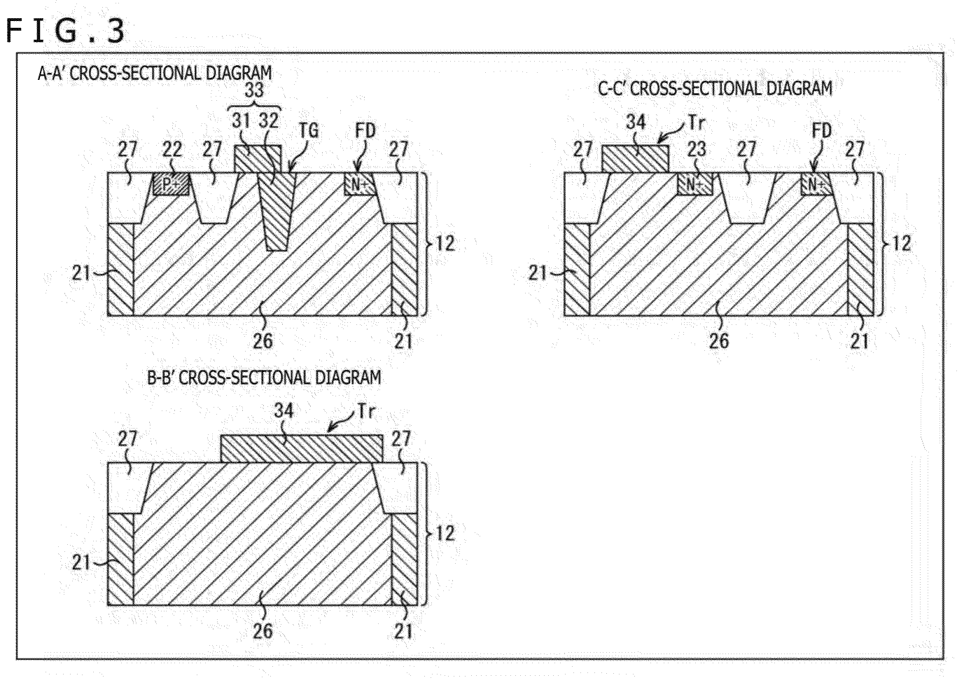

A configuration example of each of the pixels 2 will be explained with reference to FIGS. 2 and 3.

FIG. 2 is a plan diagram of the pixel 2 viewed from a transistor forming surface which is one of surfaces of the semiconductor substrate 12, while FIG. 3 depicts cross-sectional diagrams of the pixel 2. FIG. 3 contains a cross-sectional diagram taken along a line A-A′, a cross-sectional diagram taken along a line B-B′, and a cross-sectional diagram taken along a line C-C′ in FIG. 2.

As depicted in the plan diagram of FIG. 2, the pixel 2 includes a rectangular pixel region, and has a pixel separation portion 21 in an outer peripheral portion of the pixel region near a pixel boundary with the adjacent pixel. Arranged inside the pixel separation portion 21 are the transfer transistor TG having a gate electrode 33, and a pixel transistor Tr which has a gate electrode 34 and high concentration N-type layers (N+) 23 and 24 each corresponding to a source region or a drain region (hereinafter referred to as a source/drain region where appropriate). Further arranged are the floating diffusion region FD including a high concentration N-type layer (N+), and a well contact portion 22 including a high concentration P-type layer (P+).

Each of the floating diffusion region FD, the well contact portion 22, and the high concentration N-type layers 23 and 24 is connected to an active region 26. The active region 26 includes a P-type layer as a well layer corresponding to a first conductivity-type (P-type) semiconductor region, and an N-type layer as a semiconductor region corresponding to a second conductivity-type (N-type) semiconductor region different from the first conductivity-type, and constitutes a region where the photodiode PD is formed. The active region 26 is separated by an element separation region 27 formed by STI (Shallow Trench Isolation), for example, on the front surface of the semiconductor substrate 12 corresponding to the transistor forming surface. Meanwhile, as depicted in the cross-sectional diagrams of FIG. 3, the active region 26 is formed in an entire region inside the pixel separation portion 21 in an area on the rear surface side of the semiconductor substrate 12 (lower side of the semiconductor substrate 12 in FIG. 3) corresponding to the side of a light entrance surface where on-chip lenses and the like are formed.

Note that the pixel separation portion 21 having a width smaller than a width of the element separation region 27 is formed below (on the rear surface side of) the element separation region 27 at a position overlapping with the element separation region 27 formed on the front surface side of the semiconductor substrate 12 in a planar view as depicted in the cross-sectional diagrams of FIG. 3. In other words, the pixel separation portion 21 is contained in the element separation region 27 in the plan view. In FIG. 2 which is a plan diagram of the front surface of the semiconductor substrate 12, the pixel separation portion 21 is not visually recognizable in an accurate sense. FIG. 2 depicts the pixel separation portion 21 in a part lower than the element separation region 27 to indicate the arrangement of the pixel separation portion 21, for convenience of explanation.

As depicted in FIG. 3, the transfer transistor TG is a vertical transistor which has the gate electrode 33 including a planar portion 31 on an upper surface of the semiconductor substrate 12, and a carved portion 32 carved in a depth direction of the semiconductor substrate 12. In contrast, the pixel transistor Tr is a planar transistor which has the gate electrode 34 formed on only the upper surface of the semiconductor substrate 12.

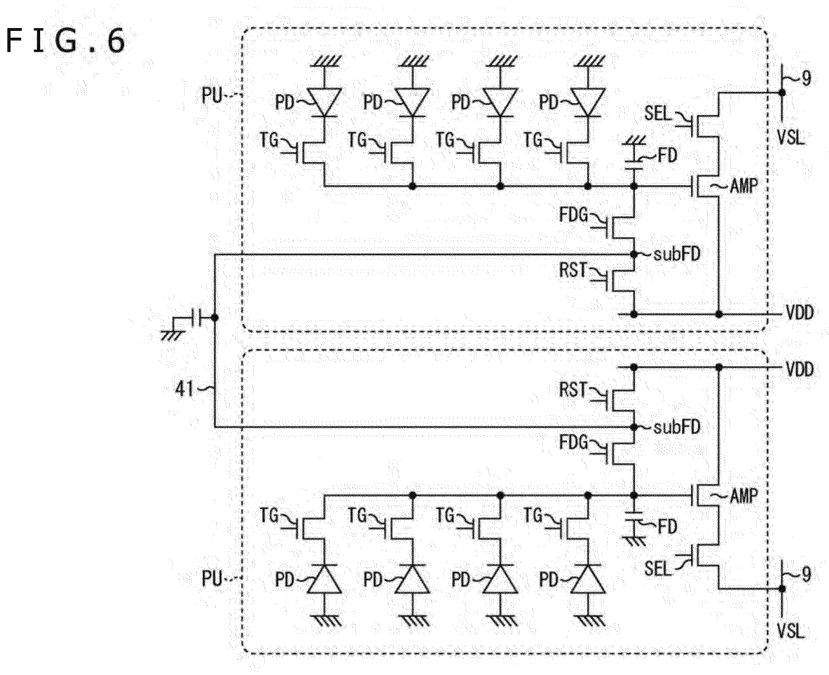

As described above, the pixel 2 has a structure which includes the transfer transistor TG and only one pixel transistor Tr other than the transfer transistor TG. The one pixel transistor Tr here is any one of the switching transistor FDG, the amplification transistor AMP, the reset transistor RST, or the selection transistor SEL described later with reference to FIG. 6.

The pixel 2 includes only, as transistors, the transfer transistor TG for transferring signal charge generated by the photodiode PD, and the one pixel transistor Tr which is any one of the switching transistor FDG, the amplification transistor AMP, the reset transistor RST, or the selection transistor SEL. Accordingly, a plurality of adjacent pixels 2 constitute a pixel unit to read signal charge from each of the pixels 2 with use of a readout circuit provided for each pixel unit.

Various possible configuration examples of the pixel unit applicable to the solid-state imaging device 1 will hereinafter be described.

### 3. First Configuration Example of Pixel Unit (1×4)

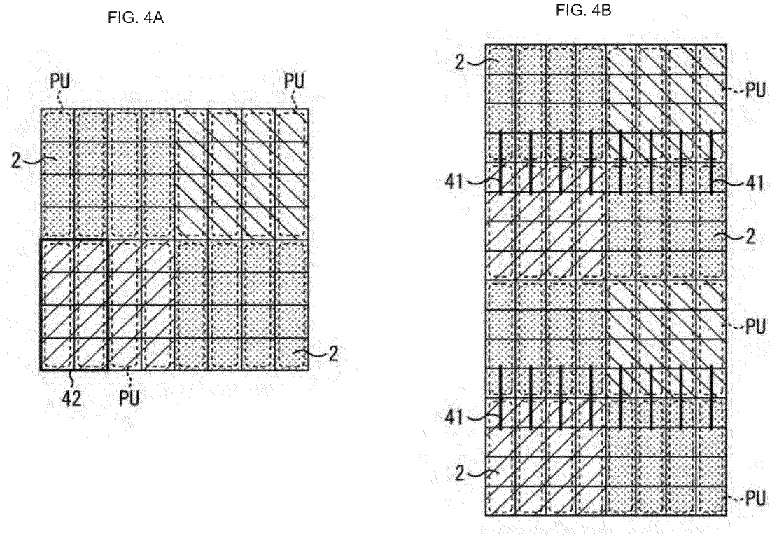

FIG. 4 depicts plan diagrams explaining a first configuration example of the pixel units. The plan diagrams of FIG. 4 each correspond to a part of the pixel array unit 3 containing two-dimensional arrays in a matrix shape.

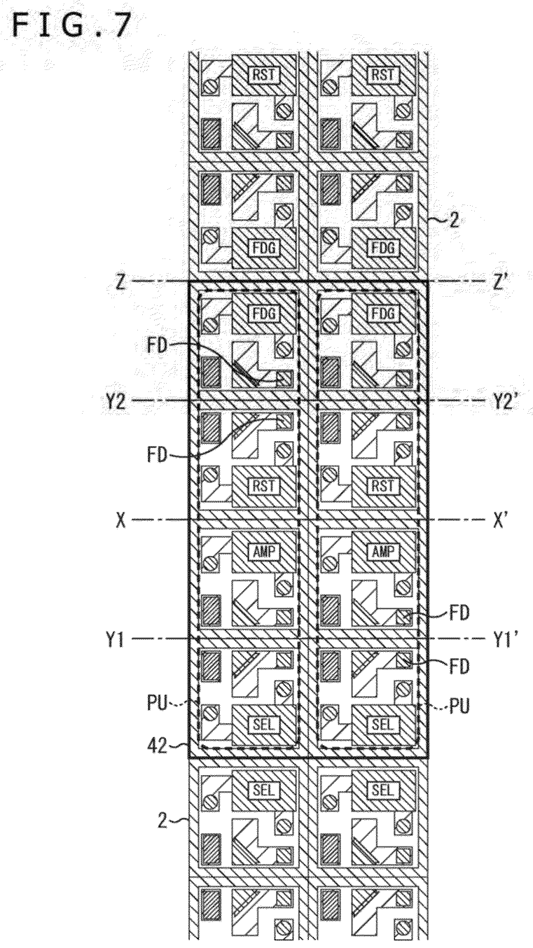

As depicted in A of FIG. 4, each of pixel units PU according to the first configuration example is a unit of four pixels forming an array of one pixel in a lateral direction and four pixels in a longitudinal direction (hereinafter referred to as 1×4; this similarly applies to other pixel units). According to the present embodiment, the lateral direction corresponds to a horizontal direction of the pixel array unit 3, while the longitudinal direction corresponds to a vertical direction of the pixel array unit 3. The horizontal direction of the pixel array unit 3 can be rephrased as a row direction of the pixel array unit 3, while the vertical direction of the pixel array unit 3 can be rephrased as a column direction of the pixel array unit 3. A region 42 including two pixel units PU arranged side by side in the lateral direction corresponds to the region 42 described later with reference to FIG. 7.

As depicted in B of FIG. 4, a part of readout circuits of each set of the two pixel units PU adjacent to each other in the longitudinal direction are electrically connected via an FD link 41. The FD link 41 is a metal wire included in a multilayer wiring layer formed on the transistor forming surface side of the semiconductor substrate 12 to electrically connect respective additional capacitances subFD of the floating diffusion regions FD. A circuit configuration of the pixel units PU and connection of the FD link 41 will be described later with reference to FIG. 6.

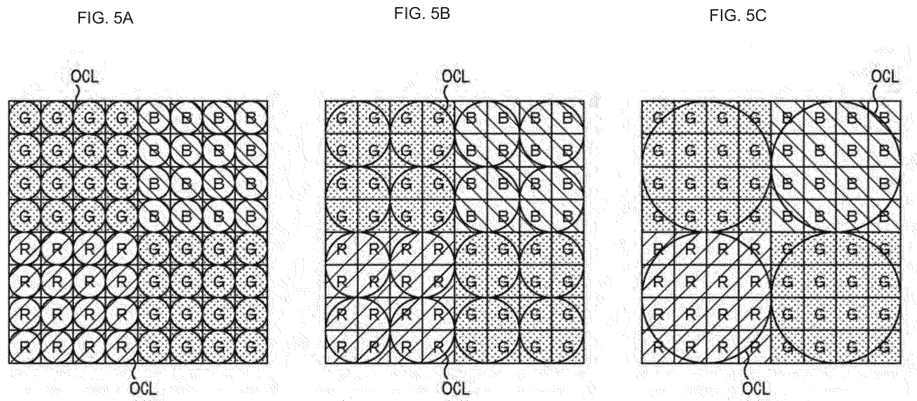

A pattern given to each unit of 4×4 pixels forming 16 pixels in FIG. 4 represents a pattern of color filters in R (Red), G (Green), or B (Blue). Specifically, as depicted in FIG. 5, color filters in the same color of R, G, or B are repeatedly arranged in what is generally called a Bayer array for each of a pixel unit of 4×4 pixels forming 16 pixels. Moreover, an on-chip lens OCL disposed on the upper part (light entrance side) of the color filter is provided for each unit of one pixel as depicted in A of FIG. 5, each unit of 2×2 pixels forming four pixels as depicted in B of FIG. 5, or each unit of 4×4 pixels forming 16 pixels as depicted in C of FIG. 5.

FIG. 6 depicts a circuit configuration example of the two pixel units PU connected to each other by the FD link 41.

Each of the pixel units PU includes four photodiodes PD, four transfer transistors TG, the floating diffusion region FD, the switching transistor FDG, the reset transistor RST, the amplification transistor AMP, the selection transistor SEL, and the additional capacitance subFD. Each of the pixel transistors Tr, i.e., the transfer transistor TG, the switching transistor FDG, the reset transistor RST, the amplification transistor AMP, and the selection transistor SEL, is an N-type MOS transistor (MOS FET), and constitutes a readout circuit.

Each of the pixel units PU has the floating diffusion region FD, the photodiode PD, and the transfer transistor TG for each of the pixels, and shares the floating diffusion region FD, the switching transistor FDG, the reset transistor RST, the amplification transistor AMP, the selection transistor SEL, and the additional capacitance subFD between the four pixels within the pixel unit PU.

The photodiode PD generates charge (signal charge) corresponding to a light quantity of received light, and accumulates the generated charge. An anode terminal of the photodiode PD is grounded, while a cathode terminal thereof is connected to the floating diffusion region FD via the transfer transistor TG.

The transfer transistor TG reads charge generated by the transfer transistor TG, and transfers the charge to the floating diffusion region FD when turned on by a transfer driving signal supplied to the gate electrode. The floating diffusion region FD retains charge read from at least one of the four photodiodes PD.

The switching transistor FDG turns on or off connection between the floating diffusion region FD and the additional capacitance subFD according to a capacitance switching signal supplied to the gate electrode, to switch conversion efficiency. Specifically, for example, the vertical driving circuit 4 turns on the switching transistor FDG to connect the floating diffusion region FD and the additional capacitance subFD at the time of high illuminance corresponding to a large light quantity of incident light. In such a manner, more charge can be accumulated at the time of high illuminance. In contrast, at the time of low illuminance corresponding to a small light quantity of incident light, the vertical driving circuit 4 turns off the switching transistor FDG to separate the additional capacitance subFD from the floating diffusion region FD. In such a manner, conversion efficiency can be raised.

The reset transistor RST drains charge accumulated in the floating diffusion region FD to a drain (constant voltage source VDD) to reset potential of the floating diffusion region FD when turned on by a reset driving signal supplied to the gate electrode. Note that the switching transistor FDG is also simultaneously turned on to reset the additional capacitance subFD when the reset transistor RST is turned on.

The additional capacitance subFD includes a diffusion layer (high concentration N-type layer) concurrently functioning as a drain region of the switching transistor FDG and a source region of the reset transistor RST. The additional capacitance subFD of one of the pixel units PU and the additional capacitance subFD of the other pixel unit PU are connected to each other by the FD link 41. As described above, the FD link 41 is a metal wire included in the multilayer wiring layer formed on the transistor forming surface side of the semiconductor substrate 12, and constitutes wiring capacitance.

The amplification transistor AMP outputs a pixel signal according to potential of the floating diffusion region FD. Specifically, the amplification transistor AMP constitutes a source follower circuit in cooperation with a load MOS (not depicted) that corresponds to a constant-current source and that is connected thereto via the vertical signal line 9. A pixel signal VSL indicating a level of charge accumulated in the floating diffusion region FD is output from the amplification transistor AMP to the column signal processing circuit 5 (FIG. 1) via the selection transistor SEL.

The selection transistor SEL is turned on when the pixel unit PU is selected according to a selection driving signal supplied to the gate electrode, and outputs the pixel signal VSL generated by the pixel unit PU to the column signal processing circuit 5 via the vertical signal line 9. Each of signal lines through which the transfer driving signal, the capacitance switching signal, the selection driving signal, and the reset driving signal are transferred corresponds to the pixel driving wire 10 in FIG. 1.

The solid-state imaging device 1 is operable while changing accumulated charge capacitance of the floating diffusion region FD in the following manners according to a light quantity of incident light or an operation mode, for example, with use of the pixel units PU having the foregoing circuit configuration.

For example, a first operation mode as a mode for reading the pixel signal VSL is achievable by turning off the switching transistors FDG of both the two pixel units PU connected by the FD link 41 and transferring charge accumulated in the photodiodes PD of the respective pixels 2 within the pixel units PU to the floating diffusion region FD included in the own pixel unit PU.

For example, a second operation mode as a mode for reading the pixel signal VSL is achievable by turning on the switching transistor FDG of one of the two pixel units PU connected via the FD link 41 and transferring charge accumulated in the photodiodes PD of the respective pixels 2 within the pixel units PU to the floating diffusion region FD, the additional capacitance subFD, and the FD link 41 included in the own pixel unit PU.

For example, a third operation mode as a mode for reading the pixel signal VSL is achievable by turning on the switching transistor FDG of both the two pixel units PU connected by the FD link 41 and transferring charge accumulated in the photodiodes PD of the respective pixels 2 within the pixel units PU to the floating diffusion regions FD, the additional capacitances subFD, and the FD link 41 included in the connected two pixel units PU.

An accumulated amount of signal charge is switchable in three levels by switching between the first operation mode to the third operation mode. In each of the first operation mode to the third operation mode, the pixel signal VSL may be read for each pixel unit of one pixel, or for each pixel unit of a plurality of pixels. In a case where the pixel signal VSL is read for each unit of a plurality of pixels, FD addition which adds a plurality of pixel signals VSL is executed by the floating diffusion region FD.

In addition, a fourth operation mode as a mode for simultaneously reading the pixel signals VSL of all the eight pixels of the two pixel units PU is achievable by turning on the switching transistors FDG of both the two pixel units PU connected by the FD link 41. In this case as well, the pixel signals VSL of the eight pixels of the two pixel units PU are also added by FD addition via the floating diffusion regions FD, the additional capacitances subFD, and the FD link 41 of the respective pixel units PU.

FIG. 7 is a plan diagram depicting a detailed arrangement of the respective pixels 2 within the pixel units PU in the first configuration example.

The pixel arrangement within the pixel units PU will be described with reference to FIG. 7 with focus placed on the region 42 where the two pixel units PU are arranged in the lateral direction (row direction). The region 42 corresponds to the region 42 depicted in FIG. 4.

Each of the pixel units PU includes 1×4 pixels forming four pixels, and each of the pixels 2 contained in these four pixels includes, as the pixel transistor Tr, any one of the switching transistor FDG, the reset transistor RST, the amplification transistor AMP, or the selection transistor SEL. More specifically, the switching transistor FDG, the reset transistor RST, the amplification transistor AMP, and the selection transistor SEL are arranged, each as the pixel transistor Tr, in the pixels 2 in this order from the upper side in the figure.

Note that “FGD,” “RST,” “AMP,” or “SEL” is given onto the gate electrode 34 of each of the pixel transistors Tr in FIG. 7 to indicate which one of the switching transistor FDG, the reset transistor RST, the amplification transistor AMP, and the selection transistor SEL corresponds to the pixel transistor Tr, and that reference signs of details other than the floating diffusion region FD in each of the pixels are omitted.

In addition, for simplifying the description, the pixel 2 including the switching transistor FDG, the pixel 2 including the reset transistor RST, the pixel 2 including the amplification transistor AMP, and the pixel 2 including the selection transistor SEL, each provided as the pixel transistor Tr, will hereinafter be referred to as a switching transistor pixel 2 (hereinafter indicated as an FDG pixel 2), a reset transistor pixel 2 (hereinafter indicated as an RST pixel 2), an amplification transistor pixel 2 (hereinafter indicated as an AMP pixel 2), and a selection transistor pixel SEL (hereinafter indicated as an SEL pixel 2), respectively. The respective pixels will simply be referred to as the pixels 2 in a case where no particular distinction is needed between the types of the pixel transistors Tr within the pixels.

Each of the pixel units PU in FIG. 7 includes the FDG pixel 2 and the RST pixel 2 arranged adjacently to each other as the upper two pixels and the AMP pixel 2 and the SEL pixel 2 arranged adjacently to each other as the lower two pixels. As indicated in the circuit configuration in FIG. 6, the source/drain regions of the FDG pixel 2 and the RST pixel 2 are connected to each other, while the source/drain regions of the AMP pixel 2 and the SEL pixel 2 are connected to each other. Accordingly, such an arrangement facilitates the connection between the source/drain regions.

The FDG pixel 2 and the RST pixel 2 within each pixel are line-symmetrically arranged with respect to a line Y2-Y2′, which is a center line of the paired pixels of the FDG pixel 2 and the RST pixel 2 in the longitudinal direction, such that each of the floating diffusion regions FD comes close to the line Y2-Y2′.

The AMP pixel 2 and the SEL pixel 2 within each pixel are line-symmetrically arranged in a similar manner with respect to a line Y1-Y1′, which is a center line of the paired pixels of the AMP pixel 2 and the SEL pixel 2 in the longitudinal direction, such that each of the floating diffusion regions FD comes close to the line Y1-Y1′.

The floating diffusion region FD of each of the pixels 2 is arranged at a position close to the line Y1-Y1′ or the line Y2-Y2′ corresponding to an axis of the line symmetry. On the contrary, the pixel transistor Tr is arranged at a position farther from the line Y-Y1′ or the line Y2-Y2′ than the floating diffusion region FD.

In addition, the two pixels of the FDG pixel 2 and the RST pixel 2 and the two pixels of the FDG pixel 2 and the RST pixel 2 are line-symmetrically arranged with respect to a line X-X′ which is a center line of these four pixels of the pixel unit PU in the longitudinal direction.

The AMP pixel 2 is not arranged at either one of pixel positions of the two longitudinal ends of the 1×4 pixels forming four pixels of the pixel unit PU, but is arranged at either one of the inner two pixels. This configuration can eliminate crosstalk with the floating diffusion region FD of the different adjacent pixel unit PU in the longitudinal direction.

The pixel unit PU including the FDG pixel 2, the RST pixel 2, the AMP pixel 2, and the SEL pixel 2 arranged in the manner described above is translation-symmetrically arranged, i.e., cyclically provided in a similar arrangement, in the lateral direction (horizontal direction) of the pixel array unit 3. Meanwhile, as for the longitudinal direction (vertical direction), the FDG pixels 2 of the two pixel units PU electrically connected by the FD link 41 are located adjacently to each other, and line-symmetrically arranged with respect to a longitudinal center line of the paired two pixel units PU, such as a line Z-Z′ in FIG. 7. This configuration facilitates connection by the FD link 41.

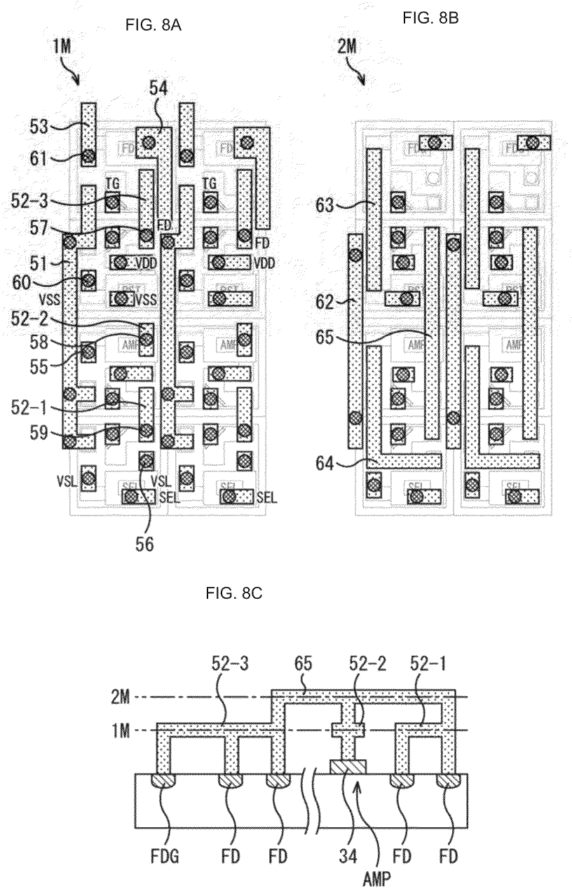

FIG. 8 depicts diagrams explaining metal wires of a wiring layer 1M closest to the semiconductor substrate 12 and a wiring layer 2M as the second closest layer in the multilayer wiring layer provided on the transistor forming surface side of the semiconductor substrate 12.

A of FIG. 8 is a plan diagram of the wiring layer 1M corresponding to the region 42 where the two pixel units PU are arranged side by side in the lateral direction, while B of FIG. 8 is a plan diagram of the wiring layer 2M corresponding to the region 42 where the two pixel units PU are arranged side by side in the lateral direction.

For the one pixel unit PU, the wiring layer 1M includes a metal wire 51 connected to the ground corresponding to predetermined potential VSS and metal wires 52-1 to 52-3 for connecting the respective floating diffusion regions FD formed in the respective pixels 2 within the pixel unit PU. Moreover, a metal wire 53 is formed as the FD link 41 for connecting the respective additional capacitances subFD of the paired two pixel units PU. A metal wire 54 is a part of a metal wire constituting the additional capacitance subFD.

For the one pixel unit PU, the wiring layer 2M includes a metal wire 62 connected to the ground corresponding to the predetermined potential VSS, a metal wire 63 for connecting the FDG pixel 2 and the RST pixel 2 within the pixel unit PU, and a metal wire 64 for connecting the AMP pixel 2 and the SEL pixel 2 within the pixel unit PU.

The metal wire 63 of the wiring layer 2M is connected to the RST pixel 2 via a via 60 of the wiring layer 1M, and connected to the FDG pixel 2 via a via 61 of the wiring layer 1M. The metal wire 64 of the wiring layer 2M is connected to the AMP pixel 2 via a via 55 of the wiring layer 1M, and connected to the SEL pixel 2 via a via 56 of the wiring layer 1M.

Moreover, for the one pixel unit PU, the wiring layer 2M includes a metal wire 65 for connecting the respective floating diffusion regions FD formed in the respective pixels 2 within the pixel unit PU. The metal wire 65 is connected to the metal wires 52-1 to 52-3 of the wiring layer 1M via vias 57 to 59 of the wiring layer 1M.

C of FIG. 8 is a cross-sectional diagram depicting metal wires that are included in the wiring layer 1M and the wiring layer 2M and that connect the respective floating diffusion regions FD within the pixel unit PU.

The floating diffusion region FD and the gate electrode 34 of the AMP pixel 2 within the pixel unit PU are electrically connected by the metal wires 52-1 to 52-3 of the wiring layer 1M and the metal wire 65 of the wiring layer 2M.

The floating diffusion regions FD of the respective pixels 2 constituting the pixel unit PU are shared by connection between the metal wires 52-1 to 52-3 of the wiring layer 1M and the metal wire 65 of the wiring layer 2M within the pixel unit PU. The AMP pixel 2 is not arranged at either one of the pixel positions at the two ends of the 1×4 pixels forming four pixels in the pixel unit PU, but is arranged at either one of the inner two pixels. This configuration can eliminate crosstalk with the floating diffusion region FD of the different adjacent pixel unit PU in the longitudinal direction.

The pixel units PU are translation-symmetrically arranged in the lateral direction. Accordingly, the wiring layer 1M and the wiring layer 2M have the same configuration for each pixel column. This configuration can eliminate crosstalk with the floating diffusion region FD of the different adjacent pixel unit PU also in the lateral direction.

According to the first configuration example of the pixel units PU including the 1×4 pixels forming four pixels as described above, each of the pixels 2 includes the transfer transistor TG and the pixel transistor Tr which is any one of the switching transistor FDG, the reset transistor RST, the amplification transistor AMP, or the selection transistor SEL. The arrangement of the FDG pixel 2, the RST pixel 2, the AMP pixel 2, and the SEL pixel 2 within the pixel unit PU in the manner described above is able to increase a transistor size of the pixel transistor Tr, and thus achieve a high resolution and a high dynamic range. In other words, even in a case where only one pixel transistor Tr other than the transfer transistor TG is arrangeable within one pixel, a high resolution and a high dynamic range are achievable by increasing the size of the pixel transistor.

### 4. Second Configuration Example of Pixel Unit (1×4)

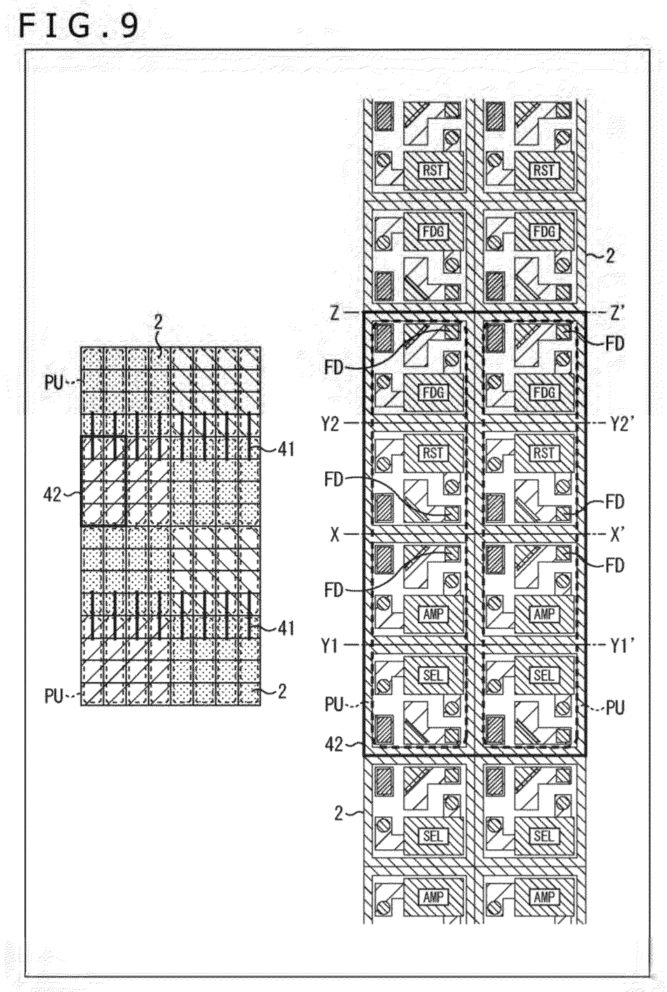

FIG. 9 is a plan diagram explaining a second configuration example of the pixel unit.

A left figure of FIG. 9 is a plan diagram depicting an arrangement of the pixel units PU constituting a part of the pixel array unit 3.

As in the first configuration example described above, each of the pixel units PU according to the second configuration example includes units of 1×4 pixels forming four pixels. In addition, the two pixel units PU adjacent to each other in the longitudinal direction are electrically connected to each other by the FD link 41. Arrays of the color filters and the on-chip lenses OCL in the second configuration example and all subsequent configuration examples are similar to the corresponding arrays of the first configuration example described above, and therefore will not be repeatedly explained.

A right figure of FIG. 9 is an enlarged diagram depicting a pixel arrangement within the pixel units PU with focus placed on the region 42 which includes two pixel units PU adjacent to each other in the lateral direction in the left figure of FIG. 9.

Each of the pixel units PU includes the FDG pixel 2 and the RST pixel 2 arranged adjacently to each other as the upper two pixels and the AMP pixel 2 and the SEL pixel 2 arranged adjacently to each other as the lower two pixels. As indicated in the circuit configuration in FIG. 6, the source/drain regions of the FDG pixel 2 and the RST pixel 2 are connected to each other, while the source/drain regions of the AMP pixel 2 and the SEL pixel 2 are connected to each other. Accordingly, this arrangement facilitates the connection between the source/drain regions.

The in-pixel arrangements of the FDG pixel 2 and the RST pixel 2 are line-symmetrical with respect to the line Y2-Y2′, which is a center line of the paired pixels of the FDG pixel 2 and the RST pixel 2 in the longitudinal direction. Moreover, the in-pixel arrangements of the AMP pixel 2 and the SEL pixel 2 are also line-symmetrical with respect to the line Y1-Y1′, which is a center line of the paired pixels of the AMP pixel 2 and the SEL pixel 2 in the longitudinal direction. Yet, the second configuration example is different from the first configuration example depicted in FIG. 7 in the in-pixel arrangements of the floating diffusion region FD and the pixel transistor Tr.

Specifically, in the first configuration example, the floating diffusion region FD of each of the pixels 2 is arranged at a position close to the line Y1-Y1′ or the line Y2-Y2′ as an axis of the line symmetry, while the pixel transistor Tr is arranged at a position farther from the line Y1-Y1′ or the line Y2-Y2′ than the floating diffusion region FD. Meanwhile, in the second configuration example, the pixel transistor Tr is arranged at a position close the line Y1-Y1′ or the line Y2-Y2′, while the floating diffusion region FD is arranged at a position farther from the line Y1-Y1′ or the line Y2-Y2′ than the pixel transistor Tr.

The second configuration example is similar to the first configuration example except for the difference in the in-pixel arrangements of the floating diffusion region FD and the pixel transistor Tr.

Specifically, the two pixels of the FDG pixel 2 and the RST pixel 2 and the two pixels of the FDG pixel 2 and the RST pixel 2 are line-symmetrically arranged with respect to the line X-X′ which is a center line of these four pixels of the pixel unit PU in the longitudinal direction. This configuration facilitates connection by the FD link 41.

The AMP pixel 2 is not arranged at either one of pixel positions of the two longitudinal ends of the 1×4 pixels forming four pixels of the pixel unit PU, but is arranged at either one of the inner two pixels. This configuration can eliminate crosstalk with the floating diffusion region FD of a different adjacent pixel unit PU in the longitudinal direction.

The pixel unit PU is translation-symmetrically arranged, i.e., cyclically arranged in a similar arrangement, in the lateral direction of the pixel array unit 3. Meanwhile, as for the longitudinal direction of the pixel array unit 3, the FDG pixels 2 of the two pixel units PU electrically connected by the FD link 41 are located adjacently to each other, and line-symmetrically arranged with respect to a longitudinal center line of the paired two pixel units PU, such as the line Z-Z′ in FIG. 9. This configuration facilitates connection by the FD link 41.

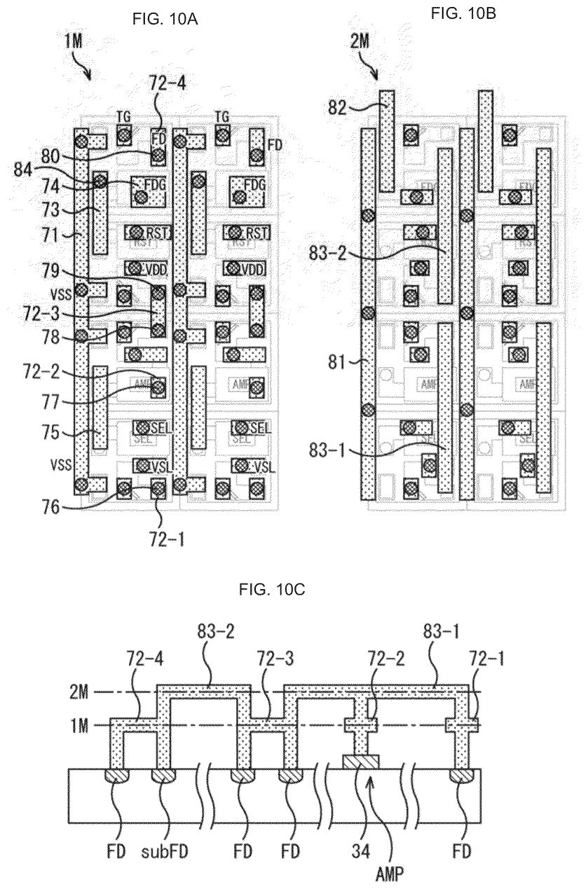

A of FIG. 10 is a plan diagram of the wiring layer 1M in the region 42 in the second configuration example, while B of FIG. 10 is a plan diagram of the wiring layer 2M in the region 42 in the second configuration example. C of FIG. 10 is a cross-sectional diagram depicting metal wires that are included in the wiring layer 1M and the wiring layer 2M and that connect the respective floating diffusion regions FD within the pixel unit PU in the second configuration example.

For the one pixel unit PU, the wiring layer 1M includes a metal wire 71 connected to the ground corresponding to the predetermined potential VSS and metal wires 72-1 to 72-4 for connecting the respective floating diffusion regions FD formed in the respective pixels 2 within the pixel unit PU. The wiring layer 1M further includes a metal wire 73 for connecting the FDG pixel 2 and the RST pixel 2 within the pixel unit PU and a metal wire 75 for connecting the AMP pixel 2 and the SEL pixel 2 within the pixel unit PU. A metal wire 74 is a part of a metal wire constituting the additional capacitance subFD.

For the one pixel unit PU, the wiring layer 2M includes a metal wire 81 connected to the ground corresponding to the predetermined potential VSS and a metal wire 82 as the FD link 41 connecting the respective additional capacitances subFD of the paired two pixel units PU. The wiring layer 2M further includes metal wires 83-1 and 83-2 for connecting the respective floating diffusion regions FD formed in the respective pixels 2 within the pixel unit PU.

The metal wire 82 of the wiring layer 2M is connected to the metal wire 73 connecting the FDG pixel 2 and the RST pixel 2 via a via 84 of the wiring layer 1M. The metal wire 83-1 of the wiring layer 2M is connected to the metal wires 72-1 to 72-3 via vias 76 to 78 of the wiring layer 1M. The metal wire 83-2 of the wiring layer 2M is connected to the metal wires 72-3 and 72-4 via vias 79 and 80 of the wiring layer 1M.

As depicted in the cross-sectional diagram in C of FIG. 10, the floating diffusion regions FD within the pixel unit PU and the gate electrode 34 of the AMP pixel 2 are electrically connected to each other by the metal wires 72-1 to 72-4 of the wiring layer 1M and the metal wires 83-1 and 83-2 of the wiring layer 2M. The floating diffusion regions FD of the respective pixels 2 constituting the pixel unit PU are shared by connection between the metal wires 72-1 to 72-4 of the wiring layer 1M and the metal wires 83-1 and 83-2 of the wiring layer 2M within the pixel unit PU. The AMP pixel 2 is not arranged at either one of the pixel positions of the two ends of the 1×4 pixels forming four pixels in the pixel unit PU, but is arranged at either one of the inner two pixels. This configuration can eliminate crosstalk with the floating diffusion region FD of a different adjacent pixel unit PU located on the upper or lower side.

The pixel units PU are translation-symmetrically arranged in the lateral direction. Accordingly, the wiring layer 1M and the wiring layer 2M have the same configuration for each pixel column. This configuration can eliminate crosstalk with the floating diffusion region FD of a different adjacent pixel unit PU also in the lateral direction.

According to the second configuration example of the pixel units PU described above, each of the pixels 2 includes the transfer transistor TG and the pixel transistor Tr which is any one of the switching transistor FDG, the reset transistor RST, the amplification transistor AMP, or the selection transistor SEL. The arrangement of the FDG pixel 2, the RST pixel 2, the AMP pixel 2, and the SEL pixel 2 within the pixel unit PU in the manner described above can increase a transistor size of the pixel transistors Tr, and thus achieve a high resolution and a high dynamic range. In other words, even in a case where only one pixel transistor Tr other than the transfer transistor TG is arrangeable within one pixel, a high resolution and a high dynamic range are achievable by increasing the size of the pixel transistor.

### Example Connecting Four Pixel Units PU by FD Link

While the second configuration example described above has been an example which electrically connects the two pixel units PU adjacent to each other in the longitudinal direction with use of the FD link 41, also adoptable is such a configuration which electrically connects the four pixel units PU adjacent to each other in the longitudinal direction with use of the FD link 41.

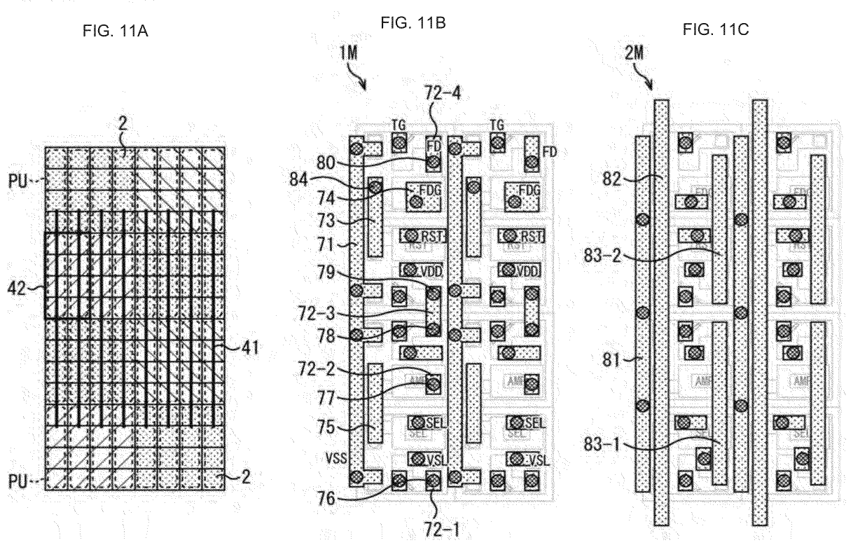

FIG. 11 depicts plan diagrams illustrating a wiring example in a case where the four pixel units PU adjacent to each other in the longitudinal direction are connected by the FD link 41 in the arrangement of the pixel units PU according to the second configuration example.

A of FIG. 11 is a plan diagram depicting an arrangement of the four pixel units PU that constitute a part of the pixel array unit 3 and that are connected by the FD link 41. As depicted in A of FIG. 11, the four pixel units PU adjacent to each other in the longitudinal direction are electrically connected via the FD link 41.

B of FIG. 11 is a plan diagram of the wiring layer 1M in the region 42 in A of FIG. 11, while C of FIG. 11 is a plan diagram of the wiring layer 2M in the region 42 in A of FIG. 11. Note that the arrangement of the respective pixels 2 in the pixel units PU is similar to the arrangement in FIG. 9, and thus is not depicted in the figure.

According to comparison between metal wiring for the connection of the four pixel units PU in the longitudinal direction by the FD link 41 and metal wiring for connection of the two pixel units PU in the longitudinal direction by the FD link 41, only the metal wire 82 of the wiring layer 2M is different.

Specifically, in the wiring layer 2M depicted in B of FIG. 10, the metal wire 82 constituting the FD link 41 is only required to connect the paired two pixel units PU, and thus has a small length. In contrast, in the wiring layer 2M depicted in C of FIG. 11, the metal wire 82 constituting the FD link 41 has a length extending through the four pixel units PU to connect the set of four pixel units PU.

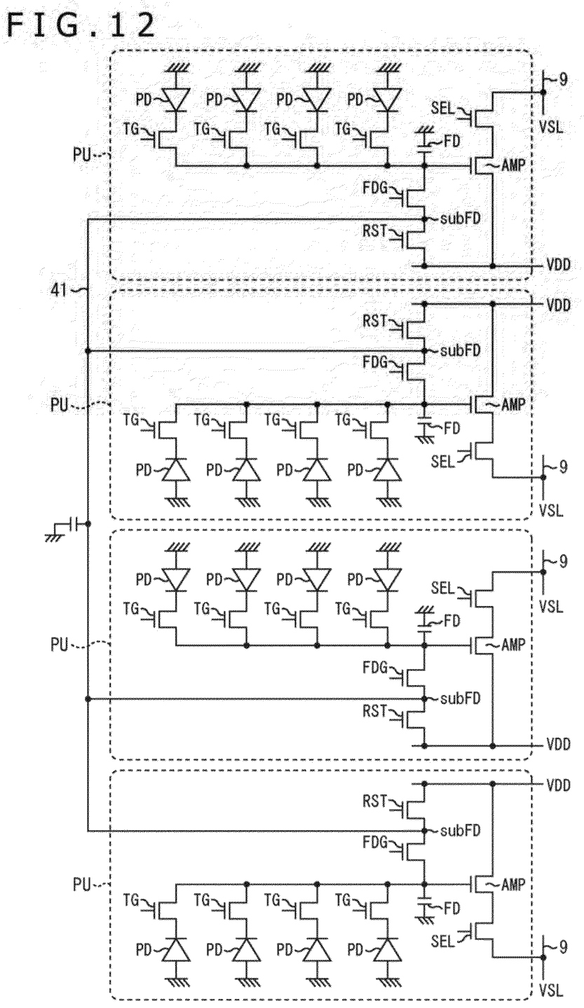

FIG. 12 depicts a circuit configuration example of a case where the four pixel units PU are connected by the FD link 41.

The FD link 41 connects the respective additional capacitances subFD of the four pixel units PU.

Advantageous effects similar to those of the example which arranges the two pixel units PU in the longitudinal direction with use of the FD link 41 can be offered by the second configuration example which arranges the four pixel units PU adjacently to each other in the longitudinal direction with use of the FD link 41. Moreover, the electrical connection between the four pixel units PU by the FD link 41 can increase accumulated capacitance of signal charge.

### 5. Third Configuration Example of Pixel Unit (1×4)

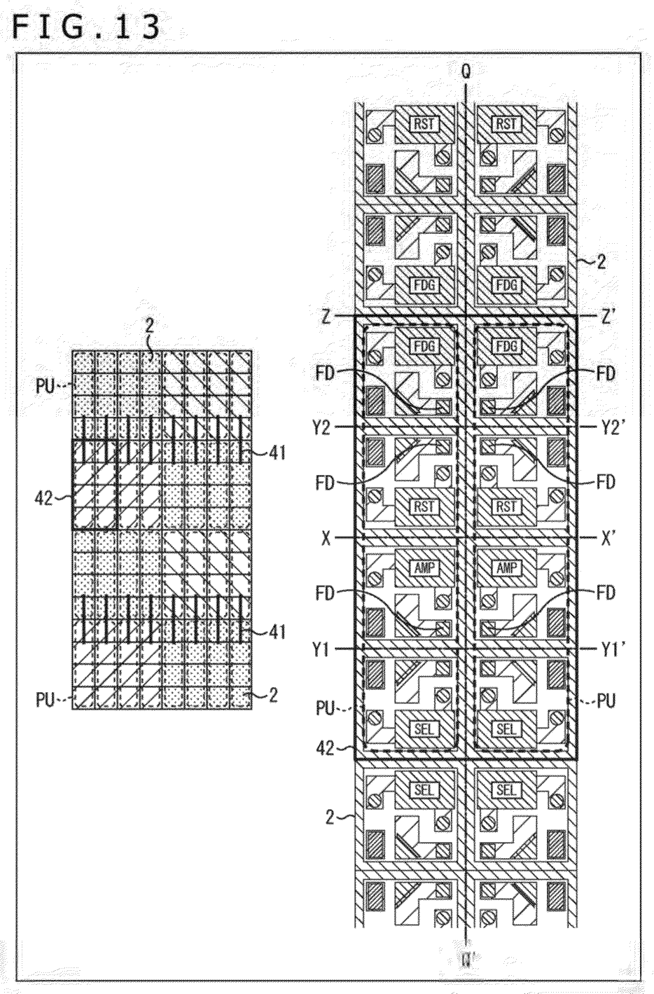

FIG. 13 is a plan diagram explaining a third configuration example of the pixel unit.

A left figure of FIG. 13 is a plan diagram depicting an arrangement of the pixel units PU constituting a part of the pixel array unit 3.

As in the first configuration example and the like described above, each of the pixel units PU according to the third configuration example includes a unit of 1×4 pixels forming four pixels. In addition, the two pixel units PU adjacent to each other in the longitudinal direction are electrically connected to each other by the FD link 41.

A right figure of FIG. 13 is an enlarged diagram depicting a pixel arrangement within the pixel units PU with focus placed on the region 42 which includes the two pixel units PU adjacent to each other in the lateral direction in the left figure of FIG. 13.

Each of the pixel units PU includes the FDG pixel 2 and the RST pixel 2 arranged adjacently to each other as the upper two pixels and the AMP pixel 2 and the SEL pixel 2 arranged adjacently to each other as the lower two pixels. As indicated in the circuit configuration in FIG. 6, the source/drain regions of the FDG pixel 2 and the RST pixel 2 are connected to each other, while the source/drain regions of the AMP pixel 2 and the SEL pixel 2 are connected to each other. Accordingly, such an arrangement facilitates the connection between the source/drain regions.

The in-pixel arrangements of the FDG pixel 2 and the RST pixel 2 are line-symmetrical with respect to the line Y2-Y2′, which is a center line of the paired pixels of the FDG pixel 2 and the RST pixel 2 in the longitudinal direction. Further, the in-pixel arrangements of the AMP pixel 2 and the SEL pixel 2 are also line-symmetrical with respect to the line Y1-Y1′, which is a center line of the paired pixels of the AMP pixel 2 and the SEL pixel 2 in the longitudinal direction. According to the third configuration example, the floating diffusion region FD of each of the pixels 2 is arranged at a position close to the line Y1-Y1′ and the line Y2-Y2′ each corresponding to an axis of the line symmetry, while the pixel transistor Tr is arranged at a position away from the line Y1-Y1′ and the line Y2-Y2′, as in the first configuration example depicted in FIG. 7.

The third configuration example is different from the first configuration example depicted in FIG. 7 in the arrangement of the floating diffusion region FD, the well contact portion 22, and the pixel transistor Tr of each of the pixels 2 within the two pixel units PU constituting the region 42. Specifically, according to the first configuration example depicted in FIG. 7, the floating diffusion region FD, the well contact portion 22, and the pixel transistor Tr in each of the pixels 2 are translation-symmetrically arranged, i.e., cyclically provided in a similar arrangement, in the lateral direction of the pixel array unit 3. In contrast, according to the third configuration example, the floating diffusion region FD, the well contact portion 22, and the pixel transistor Tr in each of the pixels 2 are arranged in a line symmetric (mirror symmetric) manner with respect to a line Q-Q′ which is a center line in the lateral direction of the region 42. More specifically, the floating diffusion region FD is arranged in an inner part of the region 42, i.e., the line Q-Q′ side, while the well contact portion 22 is arranged in an outer part of the region 42. In addition, two pixel columns mirror-symmetrically arranged are translation-symmetrically provided in the lateral direction of the pixel array unit 3.

Other configurations of the third configuration example are similar to the corresponding configurations of the first configuration example.

Specifically, the two pixels of the FDG pixel 2 and the RST pixel 2 and the two pixels of the FDG pixel 2 and the RST pixel 2 are line-symmetrically arranged with respect to the line X-X′ which is a center line of these four pixels of the pixel unit PU in the longitudinal direction.

The AMP pixel 2 is not arranged at either one of pixel positions of the two longitudinal ends of the 1×4 pixels forming four pixels of the pixel unit PU, but is arranged at either one of the inner two pixels. This configuration can eliminate crosstalk with the floating diffusion region FD of a different adjacent pixel unit PU in the longitudinal direction.

As for the longitudinal direction of the pixel array unit 3, the respective FDG pixels 2 of the two pixel units PU electrically connected by the FD link 41 are located adjacently to each other, and line-symmetrically arranged with respect to a longitudinal center line of the paired two pixel units PU, such as the line Z-Z′ in FIG. 13. This configuration facilitates connection by the FD link 41.

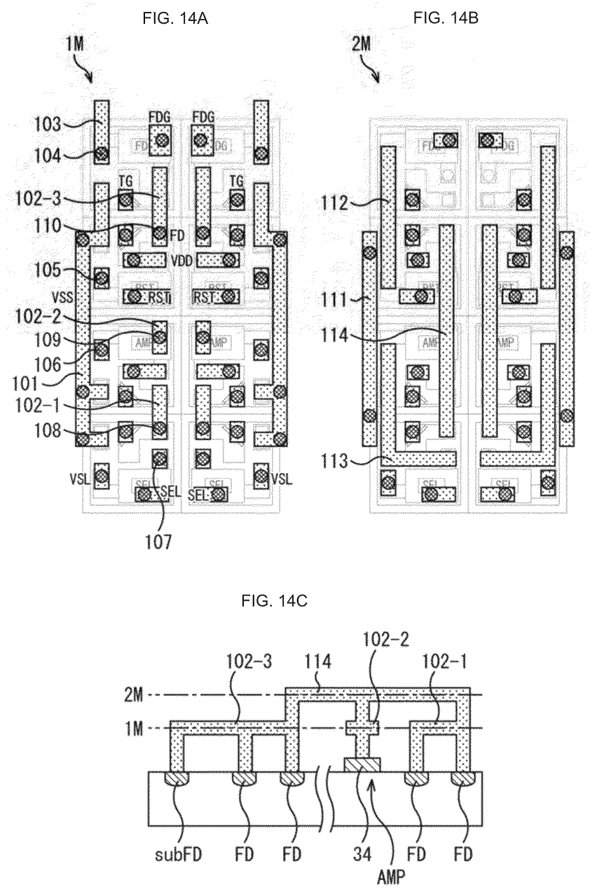

A of FIG. 14 is a plan diagram of the wiring layer 1M in the region 42 in the third configuration example, while B of FIG. 14 is a plan diagram of the wiring layer 2M in the region 42 in the third configuration example. C of FIG. 14 is a cross-sectional diagram depicting metal wires that are included in the wiring layer 1M and the wiring layer 2M and that connect the respective floating diffusion regions FD within the pixel unit PU in the third configuration example.

For the one pixel unit PU, the wiring layer 1M includes a metal wire 101 connected to the ground corresponding to the predetermined potential VSS and metal wires 102-1 to 102-3 for connecting the respective floating diffusion regions FD formed in the respective pixels 2 within the pixel unit PU. Further, a metal wire 103 is formed as the FD link 41 for connecting the respective additional capacitances subFD of the paired two pixel units PU.

For the one pixel unit PU, the wiring layer 2M includes a metal wire 111 connected to the ground corresponding to the predetermined potential VSS, a metal wire 112 for connecting the FDG pixel 2 and the RST pixel 2 within the pixel unit PU, and a metal wire 113 for connecting the AMP pixel 2 and the SEL pixel 2 within the pixel unit PU.

Each of the pixels 2 is so arranged as to become mirror-symmetrical to the adjacent pixel in the lateral direction. Accordingly, each of the metal wires of the wiring layer 1M and the wiring layer 2M is also arranged mirror-symmetrically to the adjacent pixel.

The metal wire 112 of the wiring layer 2M connects the FDG pixel 2 and the RST pixel 2 within the pixel unit PU via vias 104 and 105 of the wiring layer 1M. The metal wire 113 of the wiring layer 2M connects the AMP pixel 2 and the SEL pixel 2 within the pixel unit PU via vias 106 and 107 of the wiring layer 1M. The metal wire 114 of the wiring layer 2M is connected to the metal wires 102-1 to 102-3 of the wiring layer 1M via vias 108 to 110 of the wiring layer 1M.

As depicted in the cross-sectional diagram in C of FIG. 14, the floating diffusion regions FD within the pixel unit PU and the gate electrode 34 of the AMP pixel 2 are electrically connected by the metal wires 102-1 to 102-3 of the wiring layer 1M and the metal wire 114 of the wiring layer 2M. The floating diffusion regions FD of the respective pixels 2 constituting the pixel unit PU are shared by connection between the metal wires 102-1 to 102-3 of the wiring layer 1M and the metal wire 114 of the wiring layer 2M. The AMP pixel 2 is not arranged at either one of the pixel positions of the two ends of the 1×4 pixels forming four pixels in the pixel unit PU, but is arranged at either one of the inner two pixels. This configuration can eliminate crosstalk with the floating diffusion region FD of a different adjacent pixel unit PU located on the upper or lower side.

The pixel unit PU is arranged mirror-symmetrically to the adjacent pixel in the lateral direction. This configuration includes the pixel 2 close to the floating diffusion region FD of a different adjacent pixel unit PU. In this case, crosstalk is caused between the pixels each having the color filter in the same color in comparison with the case of the translational symmetry. However, this crosstalk has only a small effect.

According to the third configuration example of the pixel units PU described above, each of the pixels 2 includes the transfer transistor TG and the pixel transistor Tr which is any one of the switching transistor FDG, the reset transistor RST, the amplification transistor AMP, or the selection transistor SEL. The arrangement of the FDG pixel 2, the RST pixel 2, the AMP pixel 2, and the SEL pixel 2 within the pixel unit PU in the manner described can increase a transistor size of the pixel transistor Tr, and thus achieve a high resolution and a high dynamic range. In other words, even in a case where only one pixel transistor Tr other than the transfer transistor TG is arrangeable within one pixel, a high resolution and a high dynamic range are achievable by increasing the size of the pixel transistor.

While the second configuration example described above has been an example of translation-symmetrical arrangement in the lateral direction of the pixel array unit 3, each of the pixels 2 of the pixel unit PU may be arranged mirror-symmetrically to the adjacent pixel in the second configuration example, as in the third configuration example.

### 6. Fourth Configuration Example of Pixel Unit (1×4)

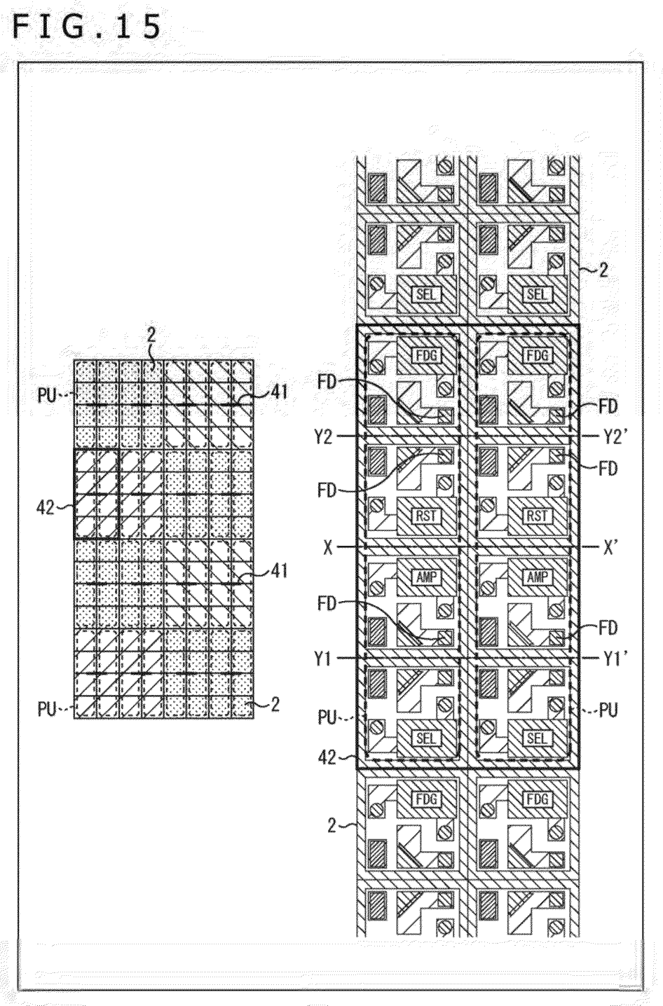

FIG. 15 is a plan diagram explaining a fourth configuration example of the pixel unit.

A left figure of FIG. 15 is a plan diagram depicting an arrangement of the pixel units PU constituting a part of the pixel array unit 3.

As in the first configuration example and the like described above, each of the pixel units PU according to the fourth configuration example includes units of 1×4 pixels forming four pixels. However, unlike in the first configuration example, the two pixel units PU adjacent to each other in the lateral direction are electrically connected by the FD link 41 in the fourth configuration example.

A right figure of FIG. 15 is an enlarged diagram depicting a pixel arrangement within the pixel units PU with focus placed on the region 42 which includes the two pixel units PU adjacent to each other in the lateral direction in the left figure of FIG. 15.

The arrangement of the 1×4 pixels forming four pixels each constituting the one pixel unit PU is similar to the corresponding arrangement of the first configuration example depicted in FIG. 7.

Specifically, the pixel unit PU includes the FDG pixel 2 and the RST pixel 2 arranged adjacently to each other as the upper two pixels and the AMP pixel 2 and the SEL pixel 2 arranged adjacently to each other as the lower two pixels. The source/drain regions of the FDG pixel 2 and the RST pixel 2 are connected to each other, while the source/drain regions of the AMP pixel 2 and the SEL pixel 2 are connected to each other. Accordingly, such an arrangement facilitates the connection between the source/drain regions.

The in-pixel arrangements of the FDG pixel 2 and the RST pixel 2 are line-symmetrical with respect to the line Y2-Y2′, which is a center line of the paired pixels of the FDG pixel 2 and the RST pixel 2 in the longitudinal direction, with the floating diffusion regions FD located adjacently to each other. Moreover, the in-pixel arrangements of the AMP pixel 2 and the SEL pixel 2 are also line-symmetrical with respect to the line Y1-Y1′, which is a center line of the paired pixels of the AMP pixel 2 and the SEL pixel 2 in the longitudinal direction, with the floating diffusion regions FD located adjacently to each other.

In addition, the two pixels of the FDG pixel 2 and the RST pixel 2 and the two pixels of the FDG pixel 2 and the RST pixel 2 are line-symmetrically arranged with respect to the line X-X′ which is a center line of these four pixels of the pixel unit PU in the longitudinal direction.

The fourth configuration example is different from the first configuration example depicted in FIG. 7 in the arrangement of the pixel unit PU in the longitudinal direction. Specifically, according to the pixel arrangement of the first configuration example depicted in FIG. 7, the FDG pixels 2 of the two pixel units PU connected by the FD link 41 are located adjacently to each other such that the paired two pixel units PU become line-symmetrical in the longitudinal direction.

In contrast, according to the fourth configuration example, the pixel unit PU is translation-symmetrically arranged, i.e., cyclically provided in a similar arrangement, in the longitudinal direction of the pixel array unit 3. As for the lateral direction of the pixel array unit 3, the pixel unit PU is translation-symmetrically arranged, as in the pixel arrangement of the first configuration example depicted in FIG. 7.

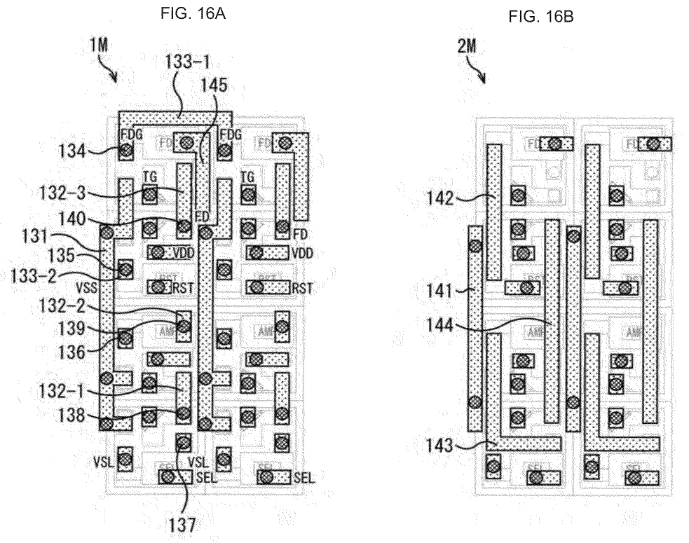

A of FIG. 16 is a plan diagram of the wiring layer 1M in the region 42 in the fourth configuration example, while B of FIG. 16 is a plan diagram of the wiring layer 2M in the region 42 in the fourth configuration example.

For the one pixel unit PU, the wiring layer 1M includes a metal wire 131 connected to the ground corresponding to the predetermined potential VSS and metal wires 132-1 to 132-3 for connecting the respective floating diffusion regions FD formed in the respective pixels 2 within the pixel unit PU. Further, a metal wire 133-1 is formed as the FD link 41 for connecting the respective additional capacitances subFD of the paired two pixel units PU. The metal wire 133-1 connects the respective FDG pixels 2 of the two pixel units PU adjacent to each other in the lateral direction. A metal wire 145 is a part of a metal wire constituting the additional capacitance subFD.

For the one pixel unit PU, the wiring layer 2M includes a metal wire 141 connected to the ground corresponding to the predetermined potential VSS and a metal wire 142 for connecting the FDG pixel 2 and the RST pixel 2 within the pixel unit PU. The metal wire 142 of the wiring layer 2M is connected to the metal wire 133-1 constituting the FD link 41 via a via 134 of the wiring layer 1M, and connected to a metal wire 133-2 of the RST pixel 2 via a via 135 of the wiring layer 1M.

Moreover, the wiring layer 2M includes a metal wire 143 for connecting the AMP pixel 2 and the SEL pixel 2 within the pixel unit PU. The metal wire 143 of the wiring layer 2M connects the AMP pixel 2 and the SEL pixel 2 within the pixel unit PU via vias 136 and 137 of the wiring layer 1M.

Further, for the one pixel unit PU, the wiring layer 2M includes a metal wire 144 for connecting the respective floating diffusion regions FD formed in the respective pixels 2 within the pixel unit PU. The metal wire 144 is connected to the metal wires 132-1 to 132-3 of the wiring layer 1M via vias 138 to 140 of the wiring layer 1M.

According to the fourth configuration example of the pixel units PU described above, each of the pixels 2 includes the transfer transistor TG and the pixel transistor Tr which is any one of the switching transistor FDG, the reset transistor RST, the amplification transistor AMP, or the selection transistor SEL. The arrangement of the FDG pixel 2, the RST pixel 2, the AMP pixel 2, and the SEL pixel 2 within the pixel unit PU in the manner described above can increase a transistor size of the pixel transistor Tr, thereby achieving a high resolution and a high dynamic range. In other words, even in a case where only one pixel transistor Tr other than the transfer transistor TG is arrangeable within one pixel, a high resolution and a high dynamic range are achievable by increasing the size of the pixel transistor.

According to the fourth configuration example, the two pixel units PU having the color filters in the same color are connected by the FD link 41. This configuration achieves FD addition via the additional capacitances subFD between the pixel units PU.

According to the fourth configuration example, the two pixel units PU adjacent to each other in the lateral direction are connected by the FD link 41. Accordingly, the pixel units PU are arranged not line-symmetrically but translation-symmetrically in the longitudinal direction of the pixel array unit 3. In this case, such an arrangement of the FDG pixels 2 of the two pixel units PU located adjacently to each other in the longitudinal direction is avoidable. Accordingly, crosstalk between the additional capacitances subFD of the pixel units PU in the longitudinal direction is preventable. However, in a case where the crosstalk between the additional capacitances subFD of the pixel units PU in the longitudinal direction has only a small effect, the pixel units PU may be line-symmetrically arranged also in the longitudinal direction of the pixel array unit 3, as in the pixel arrangement of the first configuration example depicted in FIG. 7.

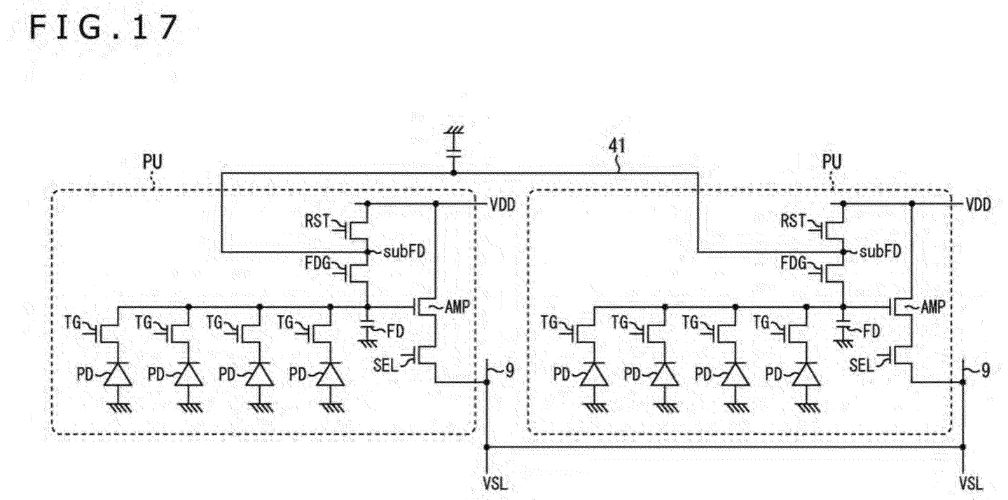

FIG. 17 depicts a modification of the circuit configuration example of the case where the two pixel units PU adjacent to each other in the lateral direction are connected via the FD link 41.

In the case where the two pixel units PU adjacent to each other in the lateral direction are connected by the FD link 41, it is allowed to adopt such a circuit configuration which connects the respective vertical signal lines 9 of the two pixel columns corresponding to the two pixel units PU connected by the FD link 41, as depicted in FIG. 17. This configuration can increase speed for reading the pixel signal VSL in a case of execution of FD addition using the floating diffusion region FD as an addition unit.

The circuit configuration in FIG. 17 is similar to the circuit configuration in FIG. 6 except for a point that the respective vertical signal lines 9 of the two pixel columns are connected. Accordingly, the configuration other than this point will not be repeatedly explained.

### 7. Fifth Configuration Example of Pixel Unit (1×4)

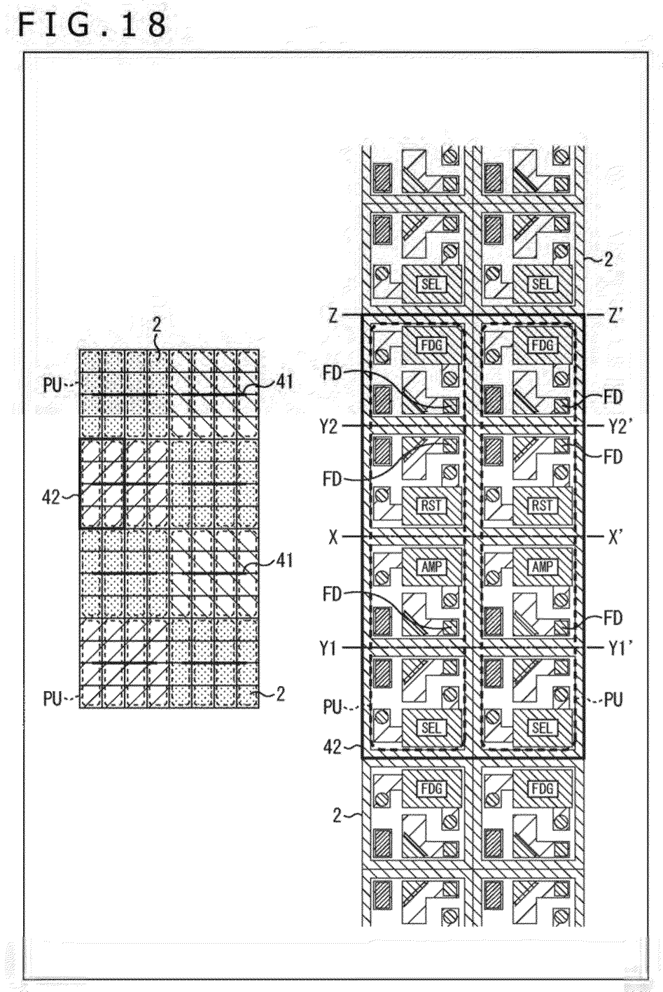

FIG. 18 is a plan diagram explaining a fifth configuration example of the pixel unit.

A left figure of FIG. 18 is a plan diagram depicting an arrangement of the pixel units PU constituting a part of the pixel array unit 3.

As in the fourth configuration example described above, each of the pixel units PU according to the fifth configuration example includes units of 1×4 pixels forming four pixels. While the fourth configuration example described above has been an example which electrically connects the two pixel units PU adjacent to each other in the lateral direction by the FD link 41, the fifth configuration example electrically connects the four pixel units PU adjacent to each other in the lateral direction by the FD link 41.

A right figure of FIG. 18 is an enlarged diagram depicting a pixel arrangement within the pixel units PU with focus placed on the region 42 which includes the two pixel units PU adjacent to each other in the lateral direction in the left figure of FIG. 18.

The arrangement of the 1×4 pixels forming four pixels each constituting the one pixel unit PU is similar to the corresponding arrangement of the fourth configuration example depicted in FIG. 15. The arrays of the pixel units PU within the pixel array unit 3 in both the longitudinal direction and the lateral direction are also similar to the corresponding arrays of the fourth configuration example depicted in FIG. 15. Specifically, the region 42 including 2×4 pixels forming eight pixels is translation-symmetrically arranged in both the longitudinal direction and the lateral direction.

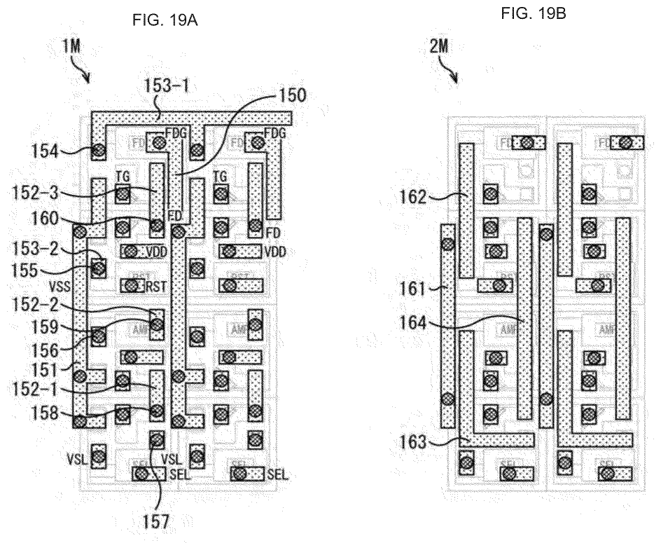

A of FIG. 19 is a plan diagram of the wiring layer 1M in the region 42 in the fifth configuration example, while B of FIG. 19 is a plan diagram of the wiring layer 2M in the region 42 in the fifth configuration example.

In comparison with the metal wires of the wiring layers 1M and 2M in the region 42 of the fourth configuration example, those of the fifth configuration example are different in having a metal wire 153-1 constituting the FD link 41 for connecting a set of the four pixel units PU.

Specifically, for the one pixel unit PU, the wiring layer 1M includes a metal wire 151 connected to the ground corresponding to the predetermined potential VSS and metal wires 152-1 to 152-3 for connecting the respective floating diffusion regions FD formed in the respective pixels 2 within the pixel unit PU. Moreover, the wiring layer 1M includes the metal wire 153-1 as the FD link 41 for connecting the respective additional capacitances subFD of the set of four pixel units PU. The metal wire 153-1 connects the respective FDG pixels 2 of the four pixel units PU adjacent to each other in the lateral direction. A metal wire 150 is a part of a metal wire constituting the additional capacitance subFD.

For the one pixel unit PU, the wiring layer 2M includes a metal wire 161 connected to the ground corresponding to the predetermined potential VSS and a metal wire 162 for connecting the FDG pixel 2 and the RST pixel 2 within the pixel unit PU. The metal wire 162 of the wiring layer 2M is connected to the metal wire 153-1 constituting the FD link 41 via a via 154 of the wiring layer 1M, and connected to a metal wire 153-2 of the RST pixel 2 via a via 155 of the wiring layer 1M.

Moreover, the wiring layer 2M includes a metal wire 163 for connecting the AMP pixel 2 and the SEL pixel 2 within the pixel unit PU. The metal wire 163 of the wiring layer 2M connects the AMP pixel 2 and the SEL pixel 2 within the pixel unit PU via vias 156 and 157 of the wiring layer 1M.

Further, for the one pixel unit PU, the wiring layer 2M includes a metal wire 164 for connecting the respective floating diffusion regions FD formed in the respective pixels 2 within the pixel unit PU. The metal wire 164 is connected to the metal wires 152-1 to 152-3 of the wiring layer 1M via vias 158 to 160 of the wiring layer 1M.

According to the fifth configuration example of the pixel units PU described above, each of the pixels 2 includes the transfer transistor TG and the pixel transistor Tr which is any one of the switching transistor FDG, the reset transistor RST, the amplification transistor AMP, or the selection transistor SEL. The arrangement of the FDG pixel 2, the RST pixel 2, the AMP pixel 2, and the SEL pixel 2 within the pixel unit PU in the manner described above can increase a transistor size of the pixel transistor Tr, and thus achieve a high resolution and a high dynamic range. In other words, even in a case where only one pixel transistor Tr other than the transfer transistor TG is arrangeable within one pixel, a high resolution and a high dynamic range are achievable by increasing the size of the pixel transistor.

According to the fifth configuration example, the pixel units PU are translation-symmetrically arranged in the longitudinal direction of the pixel array unit 3, as in the fourth configuration example. This configuration can eliminate crosstalk between the additional capacitances subFD of the pixel units PU in the longitudinal direction. However, in a case where the crosstalk between the additional capacitances subFD of the pixel units PU in the longitudinal direction has only a small effect, the pixel units PU may be line-symmetrically arranged also in the longitudinal direction of the pixel array unit 3, as in the pixel arrangement of the first configuration example depicted in FIG. 7.

In addition, according to the fifth configuration example, the 4×4 pixels forming 16 pixels each having the color filter in the same color are connected by the FD link 41. This configuration achieves FD addition of the 4×4 pixels forming 16 pixels in the same color via the additional capacitances subFD.

### 8. Sixth Configuration Example of Pixel Unit (1×4)

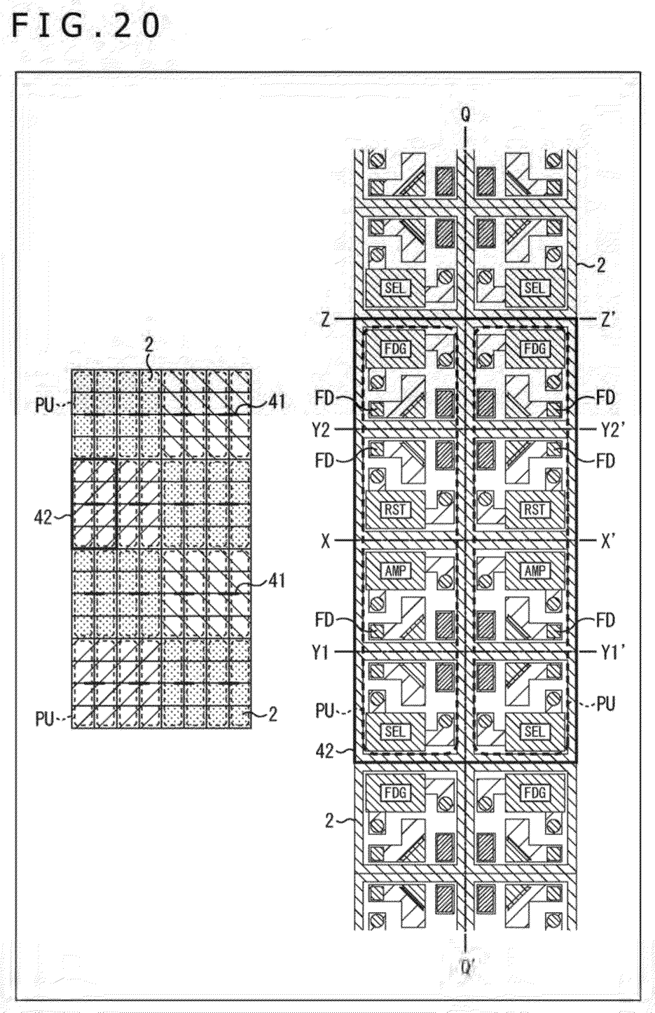

FIG. 20 is a plan diagram explaining a sixth configuration example of the pixel units.

A left figure of FIG. 20 is a plan diagram depicting an arrangement of the pixel units PU constituting a part of the pixel array unit 3.

As in the fourth configuration example described above, each of the pixel units PU according to the sixth configuration example includes units of 1×4 pixels forming four pixels. Moreover, as in the fourth configuration example, the two pixel units PU adjacent to each other in the lateral direction are electrically connected by the FD link 41 in the sixth configuration example.

A right figure of FIG. 20 is an enlarged diagram depicting a pixel arrangement within the pixel units PU with focus placed on the region 42 which includes the two pixel units PU adjacent to each other in the lateral direction in the left figure of FIG. 20.

The arrangement of the four pixels, i.e., the FDG pixel 2, the RST pixel 2, the AMP pixel 2, and the SEL pixel 2, constituting the one pixel unit PU is similar to the corresponding arrangement of the fourth configuration example depicted in FIG. 15. The arrays of the pixel units PU in both the longitudinal direction and the lateral direction are also similar to the corresponding arrays of the fourth configuration example depicted in FIG. 15. Specifically, the region 42 including 2×4 pixels forming eight pixels is translation-symmetrically arranged in both the longitudinal direction and the lateral direction.

Meanwhile, the sixth configuration example is different from the fourth configuration example depicted in FIG. 15 in the arrangement of the floating diffusion region FD, the well contact portion 22, and the pixel transistor Tr in each of the FDG pixel 2, the RST pixel 2, the AMP pixel 2, and the SEL pixel 2.

Specifically, according to the fourth configuration example in FIG. 15, the two pixel units PU that constitute the region 42 and that are connected by the FD link 41 are translation-symmetrically arranged. Accordingly, the floating diffusion region FD, the well contact portion 22, and the pixel transistor Tr of each of the pixels 2 are arranged in the same direction.

In contrast, according to the sixth configuration example, the floating diffusion region FD, the well contact portion 22, and the pixel transistor Tr in each of the pixels 2 are line-symmetrically (mirror-symmetrically) arranged with respect to the line Q-Q′ as a center line in the lateral direction of the region 42. More specifically, the well contact portion 22 is arranged in an inner part of the region 42, i.e., the line Q-Q′ side, while the floating diffusion region FD is arranged in an outer part of the region 42.

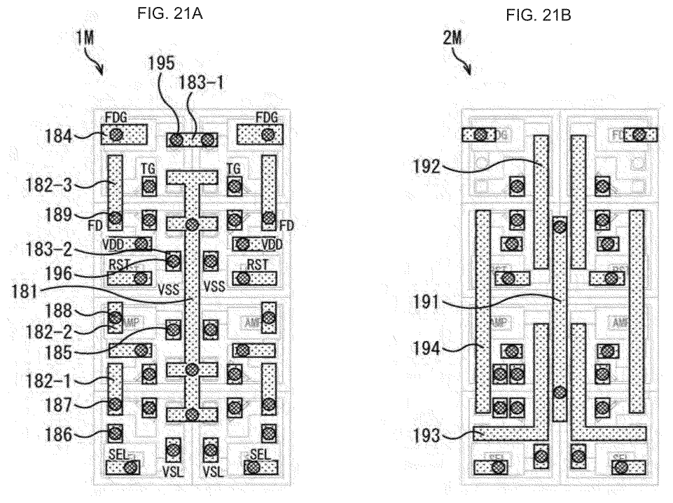

A of FIG. 21 is a plan diagram of the wiring layer 1M in the region 42 in the sixth configuration example, while B of FIG. 21 is a plan diagram of the wiring layer 2M in the region 42 in the sixth configuration example.

For the one pixel unit PU, the wiring layer 1M includes a metal wire 181 connected to the ground corresponding to the predetermined potential VSS and metal wires 182-1 to 182-3 for connecting the respective floating diffusion regions FD formed in the respective pixels 2 within the pixel unit PU. The metal wire 181 is provided as a common ground line for the paired two pixel units PU, and is arranged at a center thereof. The metal wires 182-1 to 182-3 connecting the respective floating diffusion regions FD are arranged in an outer part of the paired two pixel units PU.

Moreover, the wiring layer 1M includes a metal wire 183-1 constituting the FD link 41 for connecting the respective additional capacitances subFD of the paired two pixel units PU. In the fourth configuration example, the two pixel units PU adjacent to each other in the lateral direction are connected by the FD link 41. Accordingly, the metal wire 183-1 connects the respective FDG pixels 2 adjacent to each other in the lateral direction via a via 195. A metal wire 184 is a part of a metal wire constituting the additional capacitance subFD.

For the one pixel unit PU, the wiring layer 2M includes a metal wire 191 connected to the ground corresponding to the predetermined potential VSS and a metal wire 192 for connecting the FDG pixel 2 and the RST pixel 2 within the pixel unit PU. The metal wire 192 of the wiring layer 2M is connected to the metal wire 183-1 constituting the FD link 41 via the via 195, and connected to a metal wire 183-2 of the RST pixel 2 via a via 196.

Moreover, the wiring layer 2M includes a metal wire 193 for connecting the AMP pixel 2 and the SEL pixel 2 within the pixel unit PU. The metal wire 193 of the wiring layer 2M connects the AMP pixel 2 and the SEL pixel 2 via vias 185 and 186 of the wiring layer 1M.

Further, for the one pixel unit PU, the wiring layer 2M includes a metal wire 194 for connecting the respective floating diffusion regions FD formed in the respective pixels 2 within the pixel unit PU. The metal wire 194 is connected to the metal wires 182-1 to 182-3 of the wiring layer 1M via vias 187 to 189 of the wiring layer 1M.

According to the sixth configuration example of the pixel units PU described above, each of the pixels 2 includes the transfer transistor TG and the pixel transistor Tr which is any one of the switching transistor FDG, the reset transistor RST, the amplification transistor AMP, or the selection transistor SEL. The arrangement of the FDG pixel 2, the RST pixel 2, the AMP pixel 2, and the SEL pixel 2 within the pixel unit PU in the manner described above can increase a transistor size of the pixel transistor Tr, thereby achieving a high resolution and a high dynamic range. In other words, even in a case where only one pixel transistor Tr other than the transfer transistor TG is arrangeable within one pixel, a high resolution and a high dynamic range are achievable by increasing the size of the pixel transistor.

Moreover, according to the sixth configuration example, the two pixel units PU having the color filters in the same color are connected by the FD link 41. This configuration achieves FD addition via the additional capacitances subFD between the pixel units PU.

Further, according to the sixth configuration example, the floating diffusion regions FD are line-symmetrically (mirror-symmetrically) arranged in the outer parts with respect to the line Q-Q′ which is the center line of the two pixel units PU connected by the FD link 41. This configuration can shorten the metal wire 183-1 connecting the respective FDG pixels 2 of the two pixel units PU.

While the pixel array units PU are translation-symmetrically arrayed in the longitudinal direction of the pixel array unit 3 in the sixth configuration example, the pixel units PU may be line-symmetrically arranged.

### 9. Seventh Configuration Example of Pixel Unit (1×4)

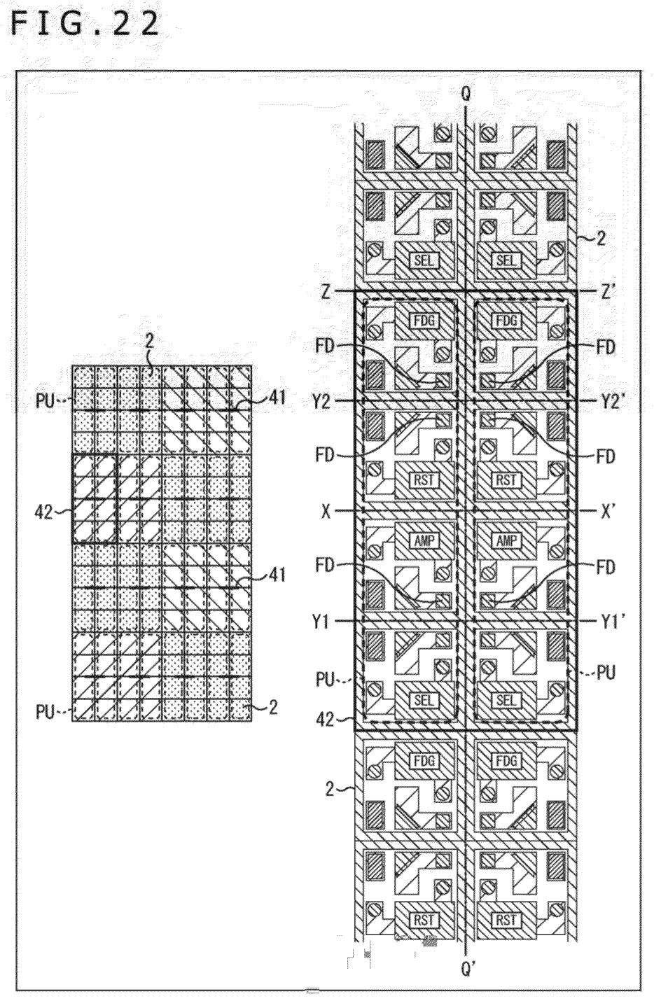

FIG. 22 is a plan diagram explaining a seventh configuration example of the pixel unit.

A left figure of FIG. 22 is a plan diagram depicting an arrangement of the pixel units PU constituting a part of the pixel array unit 3.

As in the sixth configuration example described above, each of the pixel units PU according to the seventh configuration example includes units of 1×4 pixels forming four pixels. Moreover, as in the sixth configuration example, the two pixel units PU adjacent to each other in the lateral direction are electrically connected by the FD link 41 in the seventh configuration example.

A right figure of FIG. 22 is an enlarged diagram depicting a pixel arrangement within the pixel units PU with focus placed on the region 42 which includes the two pixel units PU adjacent to each other in the lateral direction in the left figure of FIG. 22.

The arrangement of the four pixels, i.e., the FDG pixel 2, the RST pixel 2, the AMP pixel 2, and the SEL pixel 2, included in each of the two pixel units PU that constitute the region 42 and that are located adjacently to each other in the lateral direction is similar to the corresponding arrangement of the third configuration example depicted in FIG. 13.

Specifically, each of the pixel units PU includes the FDG pixel 2 and the RST pixel 2 arranged adjacently to each other as the upper two pixels and the AMP pixel 2 and the SEL pixel 2 arranged adjacently to each other as the lower two pixels. As indicated in the circuit configuration in FIG. 6, the source/drain regions of the FDG pixel 2 and the RST pixel 2 are connected to each other, while the source/drain regions of the AMP pixel 2 and the SEL pixel 2 are connected to each other. Accordingly, such an arrangement facilitates the connection between the source/drain regions.

The in-pixel arrangements of the FDG pixel 2 and the RST pixel 2 are line-symmetrical with respect to the line Y2-Y2′, which is a center line of the paired pixels of the FDG pixel 2 and the RST pixel 2 in the longitudinal direction. Moreover, the in-pixel arrangements of the AMP pixel 2 and the SEL pixel 2 are also line-symmetrical with respect to the line Y1-Y1′, which is a center line of the paired pixels of the AMP pixel 2 and the SEL pixel 2 in the longitudinal direction. The floating diffusion region FD is arranged at a position close to the line Y1-Y1′ and the line Y2-Y2′ each corresponding to an axis of the line symmetry, while the pixel transistor Tr is arranged at a position away from the line Y-Y1′ and the line Y2-Y2′.

Further, the floating diffusion region FD, the well contact portion 22, and the pixel transistor Tr in each of the pixels 2 are line-symmetrically (mirror-symmetrically) arranged with respect to the line Q-Q′ which is a center line in the lateral direction of the region 42. More specifically, the floating diffusion region FD is arranged in an inner part of the region 42, i.e., the line Q-Q′ side, while the well contact portion 22 is arranged in an outer part of the region 42.

Conversely, the seventh configuration example is different from the third configuration example depicted in FIG. 13 in the longitudinal arrangement method of the two pixel units PU connected by the FD link 41. Specifically, in the third configuration example depicted in FIG. 13, the respective FDG pixels 2 located in the longitudinal direction are arranged close to each other in a line-symmetrical manner with respect to the line Z-Z′, for example. In contrast, in the seventh configuration example, the pixel units PU are translation-symmetrically arranged in the longitudinal direction of the pixel array unit 3. Note that the two pixel columns mirror-symmetrically arranged with respect to the line Q-Q′ are translation-symmetrically arranged in the lateral direction of the pixel array unit 3.

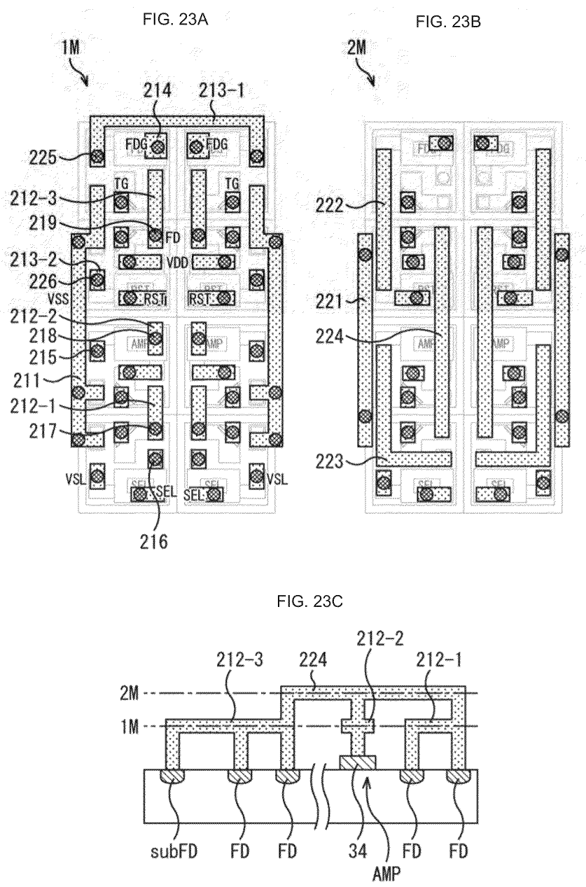

A of FIG. 23 is a plan diagram of the wiring layer 1M in the region 42 in the seventh configuration example, while B of FIG. 23 is a plan diagram of the wiring layer 2M in the region 42 in the seventh configuration example. C of FIG. 23 is a cross-sectional diagram depicting metal wires that are included in the wiring layer 1M and the wiring layer 2M and that connect the respective floating diffusion regions FD within the pixel unit PU in the seventh configuration example.

For the one pixel unit PU, the wiring layer 1M includes a metal wire 211 connected to the ground corresponding to the predetermined potential VSS and metal wires 212-1 to 212-3 for connecting the respective floating diffusion regions FD formed in the respective pixels 2 within the pixel unit PU. Moreover, a metal wire 213-1 is formed as the FD link 41 for connecting the respective additional capacitances subFD of the paired two pixel units PU. In the seventh configuration example, the two pixel units PU adjacent to each other in the lateral direction are connected by the FD link 41. Accordingly, the metal wire 213-1 connects the respective FDG pixels 2 adjacent to each other in the lateral direction via a via 225. A metal wire 214 is a part of a metal wire constituting the additional capacitance subFD.

For the one pixel unit PU, the wiring layer 2M includes a metal wire 221 connected to the ground corresponding to the predetermined potential VSS, a metal wire 222 for connecting the FDG pixel 2 and the RST pixel 2 within the pixel unit PU, and a metal wire 223 for connecting the AMP pixel 2 and the SEL pixel 2 within the pixel unit PU.

The metal wire 222 of the wiring layer 2M connects the FDG pixel 2 and the RST pixel 2 within the pixel unit PU via vias 225 and 226 of the wiring layer 1M. The metal wire 223 of the wiring layer 2M connects the AMP pixel 2 and the SEL pixel 2 within the pixel unit PU via vias 215 and 216 of the wiring layer 1M. The metal wire 224 of the wiring layer 2M is connected to the metal wires 212-1 to 212-3 via vias 217 to 219 of the wiring layer 1M.

Each of the pixels 2 is so arranged as to become mirror-symmetrical to the adjacent pixel in the lateral direction. Accordingly, each of the metal wires of the wiring layer 1M and the wiring 2M is also arranged mirror-symmetrically to the adjacent pixel.

As depicted in the cross-sectional diagram in C of FIG. 23, the floating diffusion region FD and the gate electrode 34 of the AMP pixel 2 within the pixel unit PU are electrically connected by the metal wires 212-1 to 212-3 of the wiring layer 1M and the metal wire 224 of the wiring layer 2M. The floating diffusion regions FD of the respective pixels 2 constituting the pixel unit PU are shared by connection between the metal wires 212-1 to 212-3 of the wiring layer 1M and the metal wire 224 of the wiring layer 2M within the pixel unit PU. The AMP pixel 2 is not arranged at either one of the pixel positions of the two ends of the 1×4 pixels forming four pixels in the pixel unit PU, but is arranged at either one of the inner two pixels. This configuration can eliminate crosstalk with the floating diffusion region FD of a different adjacent pixel unit PU located on the upper or lower side.

According to the seventh configuration example of the pixel units PU described above, each of the pixels 2 includes the transfer transistor TG and the pixel transistor Tr which is any one of the switching transistor FDG, the reset transistor RST, the amplification transistor AMP, or the selection transistor SEL. The arrangement of the FDG pixel 2, the RST pixel 2, the AMP pixel 2, and the SEL pixel 2 within the pixel unit PU in the manner described above can increase a transistor size of the pixel transistor Tr, and thus achieve a high resolution and a high dynamic range. In other words, even in a case where only one pixel transistor Tr other than the transfer transistor TG is arrangeable within one pixel, a high resolution and a high dynamic range are achievable by increasing the size of the pixel transistor.

While the seventh configuration example described above has been an example of a translationally symmetrical arrangement in the longitudinal direction of the pixel array unit 3, the pixels 2 of the pixel units PU may be line-symmetrically arranged such that the respective FDG pixels 2 of the pixel units PU adjacent to each other in the longitudinal direction come close to each other in the seventh configuration example, as in the third configuration example.

### 10. Other Examples of In-Pixel Layout

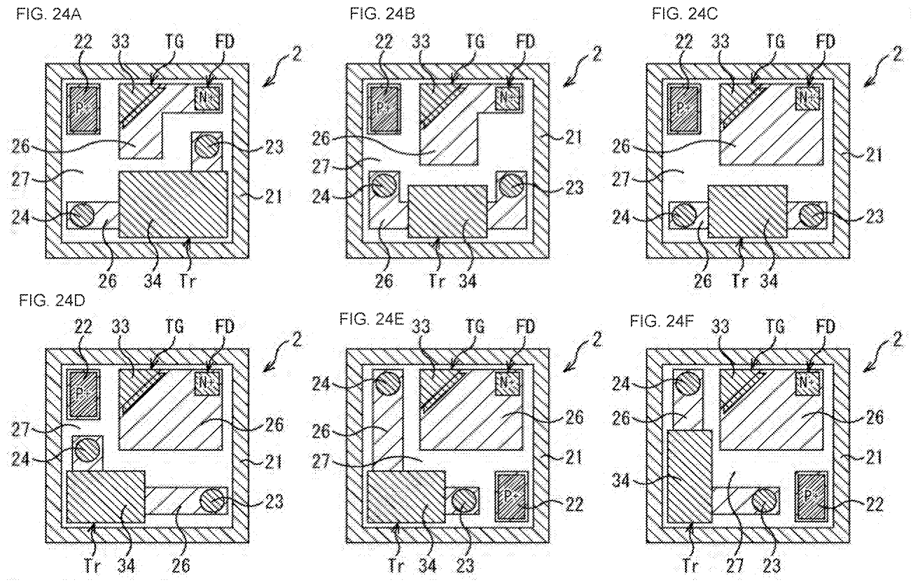

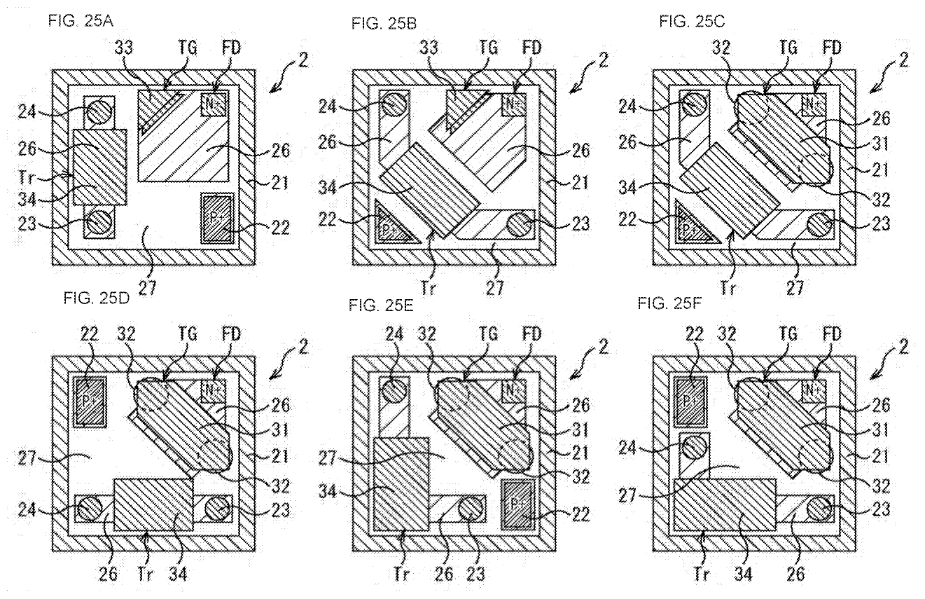

Different examples of the in-pixel layout of the pixel 2 will next be explained with reference to FIGS. 24 and 25.

A of FIG. 24 is a plan diagram again presenting the in-pixel layout of the pixel 2 depicted in FIG. 2 as a basic arrangement of the pixel 2.

In the basic arrangement of the pixel 2 in A of FIG. 24, the gate electrode 34 of the pixel transistor Tr is arranged at a corner that is among four corners of a rectangular pixel region and that is close to a corner where the floating diffusion region FD is positioned. Moreover, in this arrangement of the gate electrode 34 located at the corner, the high concentration N-type layers 23 and 24 each corresponding to a source/drain region are arranged in a left-right asymmetrical L shape. The well contact portion 22 including a high concentration P-type layer (P+) is arranged at a corner opposite to the floating diffusion region FD with the gate electrode 33 of the transfer transistor TG interposed between the well contact portion 22 and the floating diffusion region FD.

B of FIG. 24 is a plan diagram depicting a first example of the different in-pixel layout of the pixel 2.

According to the first example in B of FIG. 24, the gate electrode 34 of the pixel transistor Tr is arranged at a central portion of one side of the rectangular pixel region in the left-right direction, while the high concentration N-type layers 23 and 24 each corresponding to a source/drain region are arranged in a left-right symmetrical recessed shape.

C of FIG. 24 is a plan diagram depicting a second example of the different in-pixel layout of the pixel 2.

According to the second example in C of FIG. 24, the gate electrode 34 of the pixel transistor Tr is arranged at a central portion of one side of the rectangular pixel region in the left-right direction, while the high concentration N-type layers 23 and 24 each corresponding to a source/drain region are arranged in a left-right symmetrical I shape.

D of FIG. 24 is a plan diagram depicting a third example of the different in-pixel layout of the pixel 2.

According to the third example in D of FIG. 24, the gate electrode 34 of the pixel transistor Tr is arranged at a corner that is among the four corners of the rectangular pixel region, that is formed at a position facing the floating diffusion region FD, and that is located farthest from the corner where the floating diffusion region FD is positioned. Moreover, in this arrangement of the gate electrode 34 located at the corner, the high concentration N-type layers 23 and 24 each corresponding to a source/drain region are arranged in a left-right asymmetrical L shape.

E of FIG. 24 is a plan diagram depicting a fourth example of the different in-pixel layout of the pixel 2.

According to the fourth example in E of FIG. 24, the gate electrode 34 of the pixel transistor Tr is arranged at a corner that is among the four corners of the rectangular pixel region, that is formed at a position facing the floating diffusion region FD, and that is located farthest from the corner where the floating diffusion region FD is positioned. Moreover, in this arrangement of the gate electrode 34 located at the corner, the high concentration N-type layers 23 and 24 each corresponding to a source/drain region are arranged in a left-right asymmetrical L shape. The well contact portion 22 including a high concentration P-type layer (P+) is arranged at a corner different from the corner on the side opposite to the floating diffusion region FD with the gate electrode 33 of the transfer transistor TG interposed between the corner and the floating diffusion region FD. The gate electrode 34 having a rectangular shape is arranged in a laterally elongated shape along the same one side as the side where the well contact portion 22 is positioned.

F of FIG. 24 is a plan diagram depicting a fifth example of the different in-pixel layout of the pixel 2.

According to the fifth example in F of FIG. 24, the gate electrode 34 of the pixel transistor Tr is arranged at a corner that is among the four corners of the rectangular pixel region, that is formed at a position facing the floating diffusion region FD, and that is located farthest from the corner where the floating diffusion region FD is positioned. Moreover, in this arrangement of the gate electrode 34 located at the corner, the high concentration N-type layers 23 and 24 each corresponding to a source/drain region are arranged in a left-right asymmetrical L shape. The well contact portion 22 including a high concentration P-type layer (P+) is arranged at a corner different from the corner opposite to the floating diffusion region FD with the gate electrode 33 of the transfer transistor TG interposed between the corner and the floating diffusion region FD. The gate electrode 34 having a rectangular shape is arranged in a longitudinally elongated shape along one side different from the side where the well contact portion 22 is positioned.

A of FIG. 25 is a plan diagram depicting a fifth example of the different in-pixel layout of the pixel 2.

According to the fifth example in A of FIG. 25, the pixel transistor Tr and the transfer transistor TG are separately arranged in the left-right direction, while the high concentration N-type layers 23 and 24 each corresponding to a source/drain region of the pixel transistor Tr are arranged in a longitudinally elongated I shape. In the case where the high concentration N-type layers 23 and 24 each corresponding to a source/drain region of the pixel transistor Tr are arranged in a longitudinally elongated shape as described above, connection between the FDG pixel 2 and the RST pixel 2, and connection between the AMP pixel 2 and the SEL pixel 2 are facilitated in the pixel arrangement of 1×4 pixels forming four pixels.

B of FIG. 25 is a plan diagram depicting a sixth example of the different in-pixel layout of the pixel 2.

According to the sixth example in B of FIG. 25, the well contact portion 22 including the high concentration P-type layer (P+) is arranged at a corner that is among the four corners of the rectangular pixel region, that is formed at a position facing the floating diffusion region FD, and that is located farthest from the corner where the floating diffusion region FD is positioned. The active region 26 connected to the floating diffusion region FD has a home-plate-shaped planar shape. The gate electrode 34 of the pixel transistor Tr is arranged at an angle of 45 degrees between the floating diffusion region FD arranged at the facing corner and the well contact portion 22. The high concentration N-type layers 23 and 24 each corresponding to a source/drain region of the pixel transistor Tr are arranged at the remaining one and the other corners, respectively. The gate electrode 33 of the transfer transistor TG is arranged between the floating diffusion region FD and the high concentration N-type layer 24. The gate electrode 33 of the transfer transistor TG may be arranged between the floating diffusion region FD and the high concentration N-type layer 23. In the case where the high concentration N-type layers 23 and 24 each corresponding to a source/drain region of the pixel transistor Tr are arranged at the one and the other corners, respectively, as described above, connection between the FDG pixel 2 and the RST pixel 2 and connection between the AMP pixel 2 and the SEL pixel 2 are facilitated by the pixel arrangement of the 1×4 pixels forming four pixels.

C of FIG. 25 is a plan diagram depicting a seventh example of a different in-pixel layout of the pixel 2.

According to a structure of the seventh example in C of FIG. 25, the carved portion 32 of the gate electrode 33 of the transfer transistor TG is provided at two positions, i.e., a position between the floating diffusion region FD and the high concentration N-type layer 24 and a position between the floating diffusion region FD and the high concentration N-type layer 23, and the two carved portions 32 are connected by the planar portion 31 on the upper surface. The arrangement of the transfer transistor TG other than the gate electrode 33 is similar to the corresponding arrangement of the sixth example in B of FIG. 25.

Each of D to F of FIG. 25 is a combined arrangement example of the arrangement of the transfer transistor TG including the two carved portions 32 as the gate electrode 33 as adopted in the seventh example in C of FIG. 25 and the arrangement of the well contact portion 22 and the pixel transistor Tr as adopted in other in-pixel layouts.

D of FIG. 25 is a plan diagram depicting an eighth example of the different in-pixel layout of the pixel 2.

According to a structure of the eighth example in D of FIG. 25, the gate electrode 33 of the transfer transistor TG is arranged in a manner similar to that of the seventh example in C of FIG. 25, while the arrangement of the well contact portion 22 and the pixel transistor Tr is similar to the corresponding arrangement of the second example in C of FIG. 24.

E of FIG. 25 is a plan diagram depicting a ninth example of the different in-pixel layout of the pixel 2.

According to a structure of the ninth example in E of FIG. 25, the gate electrode 33 of the transfer transistor TG is arranged in a manner similar to that of the seventh example in C of FIG. 25, while the arrangement of the well contact portion 22 and the pixel transistor Tr is similar to the corresponding arrangement of the fourth example in E of FIG. 24.

F of FIG. 25 is a plan diagram depicting a tenth example of the different in-pixel layout of the pixel 2.

According to a structure of the tenth example in F of FIG. 25, the gate electrode 33 of the transfer transistor TG is arranged in a manner similar to that of the seventh example in C of FIG. 25, while the arrangement of the well contact portion 22 and the pixel transistor Tr is similar to the corresponding arrangement of the third example in D of FIG. 24.

Note that other combinations of the transfer transistor TG including the two carved portions 32 as the gate electrode 33 and the arrangement of the well contact portion 22 and the pixel transistor Tr as adopted in any one of the different in-pixel layouts may be used instead of the examples depicted in D to F of FIG. 25.

### 11. Configuration Example of Fin-Type Transistor

A Fin-type MOS transistor is applicable to the pixel transistor Tr of each of the pixels 2 described above.

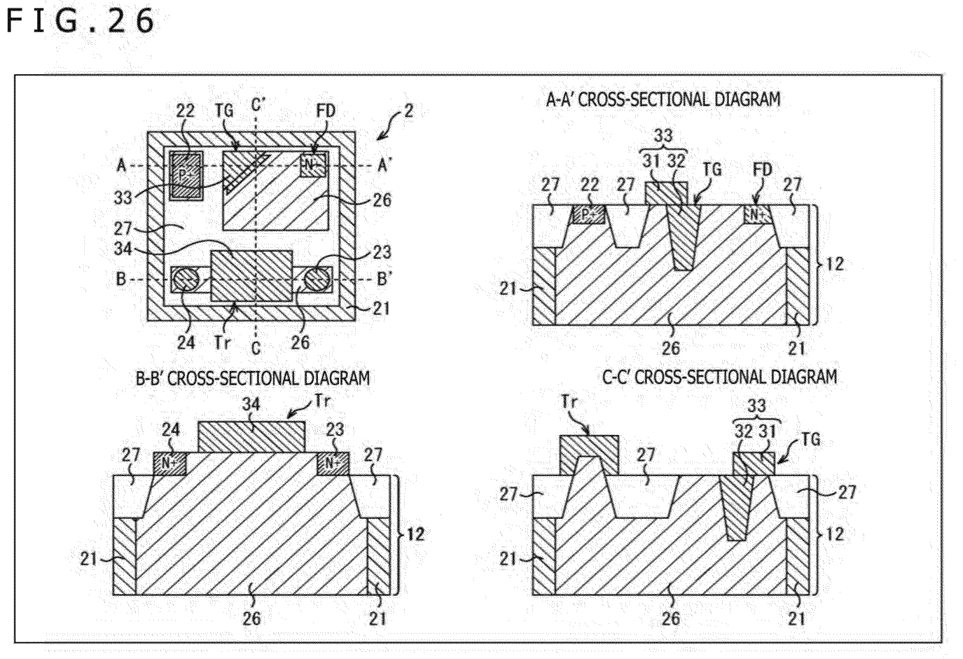

FIG. 26 depicts a configuration example of the pixel 2 which includes a Fin-type MOS transistor adopted as the pixel transistor Tr of the pixel 2.

FIG. 26 includes a plan diagram of the pixel 2 and cross-sectional diagrams taken along a line A-A′, a line B-B′, and a line C-C′ in the plan diagram.

The plan diagram of the pixel 2 is similar to that of the second example of the different in-pixel layout depicted in C of FIG. 24. The gate electrode 34 of the pixel transistor Tr is arranged at a central portion of one side of the rectangular pixel region in the left-right direction, while the high concentration N-type layers 23 and 24 each corresponding to a source/drain region are arranged in a left-right symmetrical I shape.

According to the pixel transistor Tr which is a Fin-type MOS transistor, the gate electrode 34 has a recessed shape facing the substrate side in such a manner as to surround the upper surface and both the side surfaces of the active region 26 formed up to a position higher than an interface of the semiconductor substrate 12 as depicted in the B-B′ line cross-sectional diagram and the C-C′ line cross-sectional diagram. The high concentration N-type layers 23 and 24 each corresponding to a source/drain region of the pixel transistor Tr are also formed at positions higher than the interface of the semiconductor substrate 12. Configurations other than the pixel transistor Tr are similar to the corresponding configurations described above.

The pixel transistor Tr including the Fin-type MOS transistor can effectively enlarge a channel width W, and therefore can reduce noise components.

### 12. Arrangement Example of Pixel Unit in Case of Adoption of Sixth In-Pixel Layout (First Configuration Example)

Described here will be an arrangement example of the pixel units PU in the case of adopting the sixth example of the in-pixel layout depicted in B of FIG. 25 among the different in-pixel layouts of the pixel 2 described above.

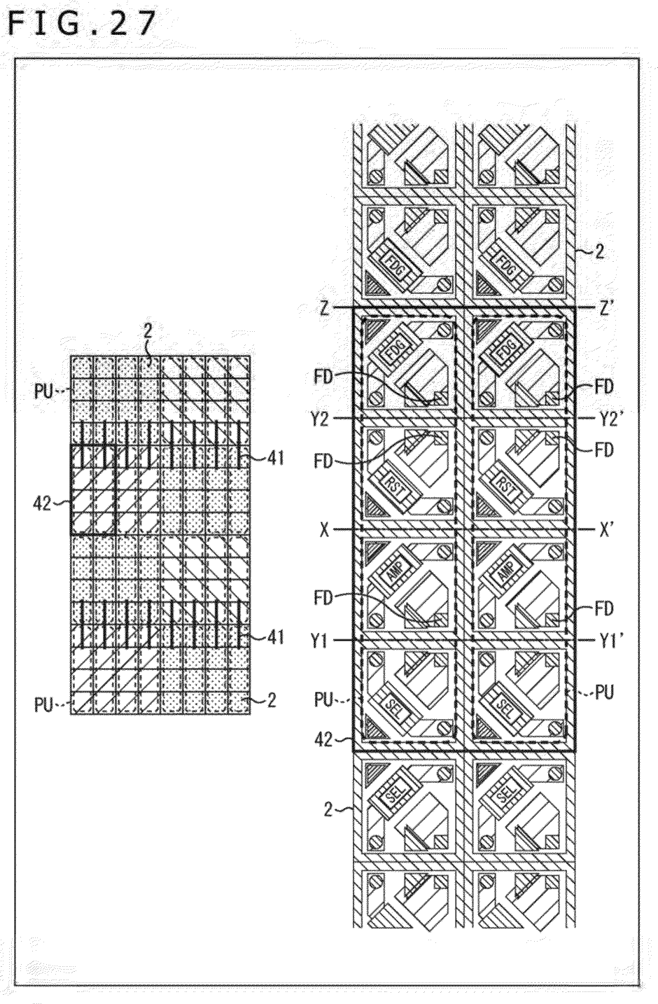

FIG. 27 depicts an example where the sixth example of the in-pixel layout in B of FIG. 25 is arranged in the first configuration example of the pixel units described with reference to FIGS. 4 and 7.

Each of the pixel units PU includes units of 1×4 pixels forming four pixels. In addition, the two pixel units PU adjacent to each other in the longitudinal direction are electrically connected to each other by the FD link 41.

A right figure of FIG. 27 is an enlarged diagram depicting a pixel arrangement within the pixel units PU with focus placed on the region 42 which includes the two pixel units PU adjacent to each other in the lateral direction in a left figure of FIG. 27.

Each of the pixel units PU in FIG. 27 includes the FDG pixel 2 and the RST pixel 2 arranged adjacently to each other as the upper two pixels in the pixel unit PU, and the AMP pixel 2 and the SEL pixel 2 arranged adjacently to each other as the lower two pixels in the pixel unit PU. The source/drain regions of the FDG pixel 2 and the RST pixel 2 are connected to each other, while the source/drain regions of the AMP pixel 2 and the SEL pixel 2 are connected to each other. Accordingly, such an arrangement facilitates the connection between the source/drain regions.

The FDG pixel 2 and the RST pixel 2 within each pixel are line-symmetrically arranged with respect to the line Y2-Y2′, which is a center line of the paired pixels of the FDG pixel 2 and the RST pixel 2 in the longitudinal direction, such that each of the floating diffusion regions FD comes close to the line Y2-Y2′.

The AMP pixel 2 and the SEL pixel 2 within each pixel are line-symmetrically arranged in a similar manner with respect to the line Y1-Y1′, which is a center line of the paired pixels of the AMP pixel 2 and the SEL pixel 2 in the longitudinal direction, such that each of the floating diffusion regions FD comes close to the line Y1-Y1′.

In addition, the two pixels of the FDG pixel 2 and the RST pixel 2 and the two pixels of the FDG pixel 2 and the RST pixel 2 are line-symmetrically arranged with respect to the line X-X′ which is a center line of these four pixels of the pixel unit PU in the longitudinal direction.

The AMP pixel 2 is not arranged at either one of pixel positions of the two longitudinal ends of the 1×4 pixels forming four pixels of the pixel unit PU, but is arranged at either one of the inner two pixels. Such a configuration can eliminate crosstalk with the floating diffusion region FD of the different adjoining pixel unit PU in the longitudinal direction.

As described above, the pixel unit PU having an arrangement of the FDG pixel 2, the RST pixel 2, the AMP pixel 2, and the SEL pixel 2 is translation-symmetrically arranged, i.e., cyclically provided in a similar arrangement, in the lateral direction of the pixel array unit 3. Meanwhile, as for the longitudinal direction, the FDG pixels 2 of the two pixel units PU electrically connected by the FD link 41 are located adjacently to each other, and line-symmetrically arranged with respect to a longitudinal center line of the paired two pixel units PU, such as the line Z-Z′ in FIG. 27. Such a configuration facilitates connection by the FD link 41.

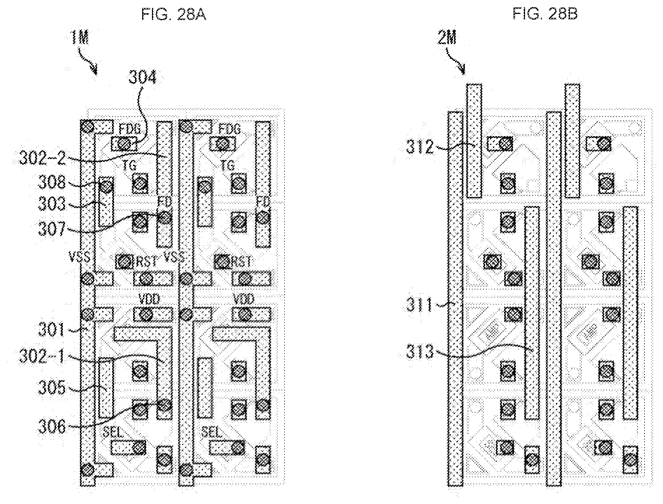

FIG. 28 depicts plan diagrams illustrating the wiring layer 1M and the wiring layer 2M in the region 42 in FIG. 27.

For the one pixel unit PU, the wiring layer 1M includes a metal wire 301 connected to the ground corresponding to the predetermined potential VSS and metal wires 302-1 and 302-2 for connecting the respective floating diffusion regions FD formed in the respective pixels 2 within the pixel unit PU. The wiring layer 1M further includes a metal wire 303 for connecting the FDG pixel 2 and the RST pixel 2 within the pixel unit PU and a metal wire 305 for connecting the AMP pixel 2 and the SEL pixel 2 within the pixel unit PU. A metal wire 304 is a part of a metal wire constituting the additional capacitance subFD.

For the one pixel unit PU, the wiring layer 2M includes a metal wire 311 connected to the ground corresponding to the predetermined potential VSS and a metal wire 312 as the FD link 41 connecting the respective additional capacitances subFD of the paired two pixel units PU. The wiring layer 2M further includes a metal wire 313 for connecting the respective floating diffusion regions FD formed in the respective pixels 2 within the pixel unit PU.

The metal wire 313 of the wiring layer 2M is connected to the metal wire 302-1 via a via 306 of the wiring layer 1M, and connected to a metal wire 302-2 via a via 307 of the wiring layer 1M. In this manner, the floating diffusion regions FD of the four pixels constituting the pixel unit PU are connected to each other.

The metal wire 312 of the wiring layer 2M is connected to the additional capacitance subFD of the pixel unit PU on the upper side, and also connected to the metal wire 303 via a via 308 of the wiring layer 1M. In this manner, the respective additional capacitances subFD of the paired two pixel units PU are connected to each other.

The sixth example of the in-pixel layout in B of FIG. 25 adopted as the in-pixel layout of the pixel 2 can shorten the metal wire 303 connecting the FDG pixel 2 and the RST pixel 2, and also shorten the metal wire 305 connecting the AMP pixel 2 and the SEL pixel 2. Accordingly, connection between the FDG pixel 2 and the RST pixel 2 and connection between the AMP pixel 2 and the SEL pixel 2 can be facilitated.

### 13. Arrangement Example of Pixel Unit in Case of Adoption of Sixth In-Pixel Layout (Third Configuration Example)

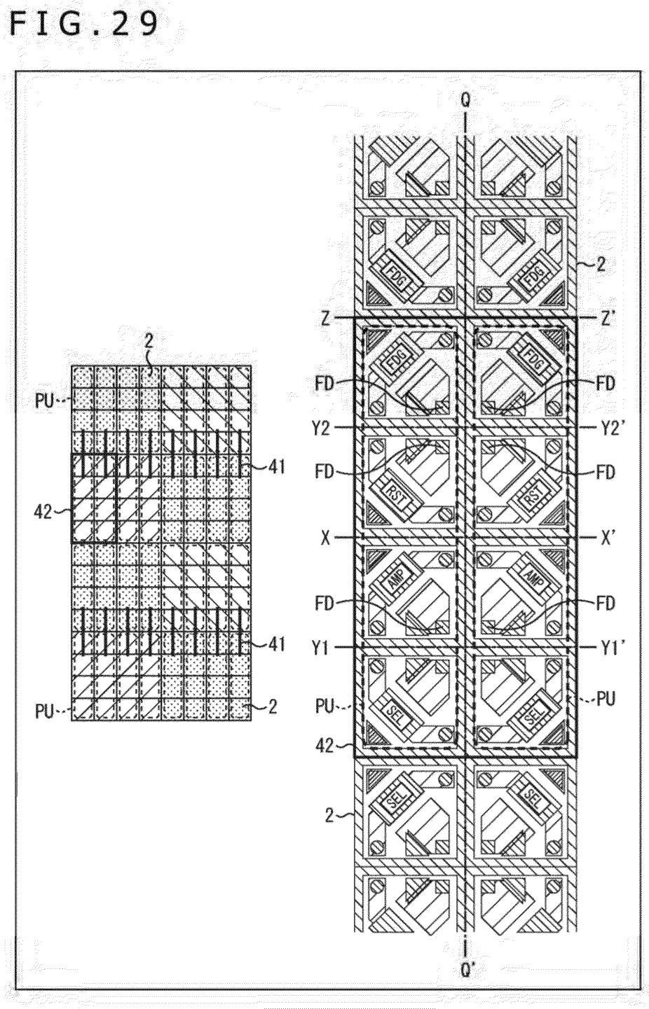

FIG. 29 depicts an example where the sixth example of the in-pixel layout in B of FIG. 25 is arranged in the third configuration example of the pixel units described with reference to FIG. 13.

Each of the pixel units PU includes units of 1×4 pixels forming four pixels. In addition, the two pixel units PU adjacent to each other in the longitudinal direction are electrically connected to each other by the FD link 41.

A right figure of FIG. 29 is an enlarged diagram depicting a pixel arrangement within the pixel units PU with focus placed on the region 42 which includes the two pixel units PU adjacent to each other in the lateral direction in a left figure of FIG. 29.

Each of the pixel units PU includes the FDG pixel 2 and the RST pixel 2 arranged adjacently to each other as the upper two pixels and the AMP pixel 2 and the SEL pixel 2 arranged adjacently to each other as the lower two pixels. The source/drain regions of the FDG pixel 2 and the RST pixel 2 are connected to each other, while the source/drain regions of the AMP pixel 2 and the SEL pixel 2 are connected to each other. Accordingly, such an arrangement facilitates the connection between the source/drain regions.

The in-pixel arrangements of the FDG pixel 2 and the RST pixel 2 are line-symmetrical with respect to the line Y2-Y2′, which is a center line of the paired pixels of the FDG pixel 2 and the RST pixel 2 in the longitudinal direction. Moreover, the in-pixel arrangements of the AMP pixel 2 and the SEL pixel 2 are also line-symmetrical with respect to the line Y1-Y1′, which is a center line of the paired pixels of the AMP pixel 2 and the SEL pixel 2 in the longitudinal direction. The floating diffusion regions FD are arranged at positions close to the line Y1-Y1′ and the line Y2-Y2′ each corresponding to an axis of the line symmetry, while the pixel transistors Tr are arranged at positions away from the line Y-Y1′ and the line Y2-Y2′.

The floating diffusion region FD, the well contact portion 22, and the pixel transistor Tr in each of the pixels 2 are line-symmetrically (mirror-symmetrically) arranged with respect to the line Q-Q′ which is a center line in the lateral direction of the region 42. More specifically, the floating diffusion region FD is arranged in an inner part of the region 42, i.e., the line Q-Q′ side, while the well contact portion 22 and the pixel transistor Tr are arranged in an outer part of the region 42. In addition, two pixel columns mirror-symmetrically arranged are translation-symmetrically provided in the lateral direction of the pixel array unit 3.

The two pixels of the FDG pixel 2 and the RST pixel 2 and the two pixels of the FDG pixel 2 and the RST pixel 2 are line-symmetrically arranged with respect to the line X-X′ which is a center line of these four pixels of the pixel unit PU in the longitudinal direction.

The AMP pixel 2 is not arranged at either one of pixel positions of the two longitudinal ends of the 1×4 pixels forming four pixels of the pixel unit PU, but is arranged at either one of the inner two pixels. This configuration can eliminate crosstalk with the floating diffusion region FD of a different adjacent pixel unit PU in the longitudinal direction.

In the longitudinal direction of the pixel array unit 3, the FDG pixels 2 of the two pixel units PU electrically connected by the FD link 41 are located adjacently to each other, and line-symmetrically arranged with respect to a longitudinal central line of the paired two pixel units PU, such as the line Z-Z′ in FIG. 29. This configuration facilitates connection by the FD link 41.

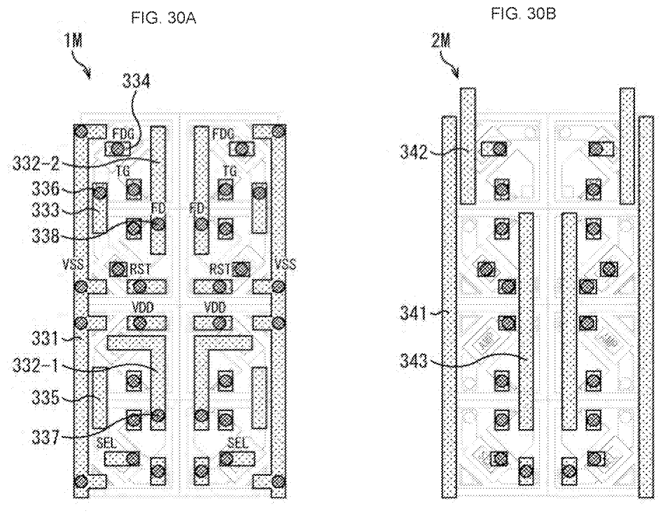

FIG. 30 depicts plan diagrams of the wiring layer 1M and the wiring layer 2M in the region 42 in FIG. 29.

For the one pixel unit PU, the wiring layer 1M includes a metal wire 331 connected to the ground corresponding to the predetermined potential VSS and metal wires 332-1 and 332-2 for connecting the respective floating diffusion regions FD formed in the respective pixels 2 within the pixel unit PU. The wiring layer 1M further includes a metal wire 333 for connecting the FDG pixel 2 and the RST pixel 2 within the pixel unit PU and a metal wire 335 for connecting the AMP pixel 2 and the SEL pixel 2 within the pixel unit PU. A metal wire 334 is a part of a metal wire constituting the additional capacitance subFD.

For the one pixel unit PU, the wiring layer 2M includes a metal wire 341 connected to the ground corresponding to the predetermined potential VSS and a metal wire 342 as the FD link 41 connecting the respective additional capacitances subFD of the paired two pixel units PU. The wiring layer 2M further includes a metal wire 343 for connecting the respective floating diffusion regions FD formed in the respective pixels 2 within the pixel unit PU.

The metal wire 343 of the wiring layer 2M is connected to the metal wire 332-1 via a via 337 of the wiring layer 1M, and connected to the metal wire 332-2 via a via 338 of the wiring layer 1M. In this manner, the floating diffusion regions FD of the four pixels constituting the pixel unit PU are connected to each other.

The metal wire 342 of the wiring layer 2M is connected to the additional capacitance subFD of the pixel unit PU located on the upper side, and also connected to the metal wire 333 via a via 336 of the wiring layer 1M. In this manner, the respective additional capacitances subFD of the paired two pixel units PU are connected to each other.

The sixth example of the in-pixel layout in B of FIG. 25 adopted as the in-pixel layout of the pixel 2 can shorten the metal wire 333 connecting the FDG pixel 2 and the RST pixel 2, and also shorten the metal wire 335 connecting the AMP pixel 2 and the SEL pixel 2. Accordingly, connection between the FDG pixel 2 and the RST pixel 2 and connection between the AMP pixel 2 and the SEL pixel 2 can be facilitated.

### 14. Arrangement Example of Pixel Unit in Case of Adoption of Sixth In-Pixel Layout (Fourth Configuration Example)

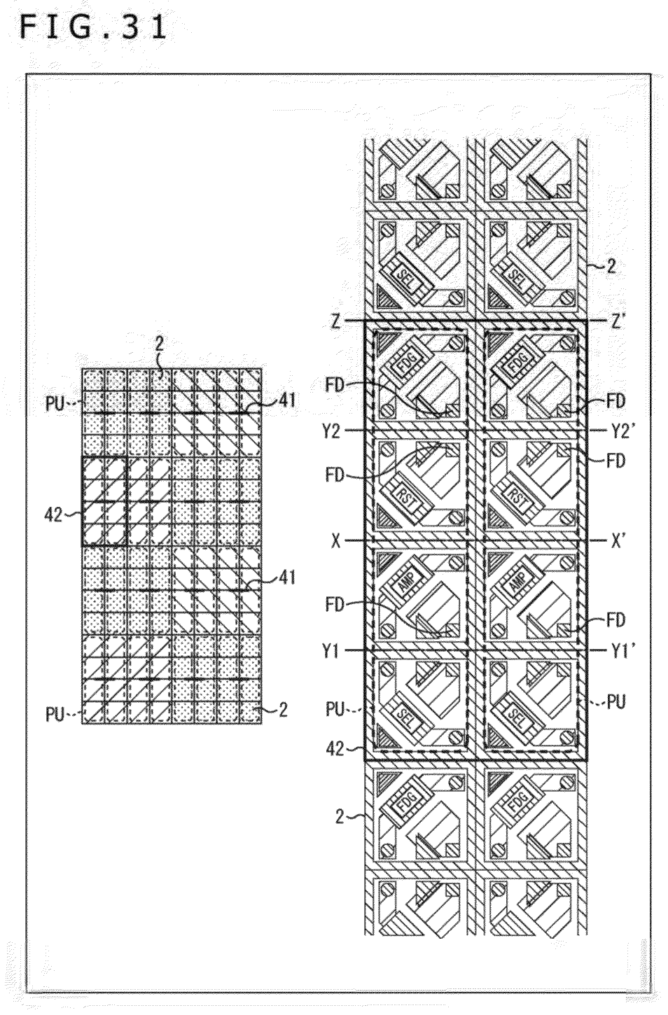

FIG. 31 depicts an example where the sixth example of the in-pixel layout in B of FIG. 25 is arranged in the fourth configuration example of the pixel units described with reference to FIG. 15.

Each of the pixel units PU includes units of 1×4 pixels forming four pixels. In addition, the two pixel units PU adjacent to each other in the lateral direction are electrically connected to each other by the FD link 41.

A right figure of FIG. 31 is an enlarged diagram depicting a pixel arrangement within the pixel units PU with focus placed on the region 42 which includes the two pixel units PU adjacent to each other in the lateral direction in a left figure of FIG. 31.

Each of the pixel units PU includes the FDG pixel 2 and the RST pixel 2 arranged adjacently to each other as the upper two pixels and the AMP pixel 2 and the SEL pixel 2 arranged adjacently to each other as the lower two pixels. The source/drain regions of the FDG pixel 2 and the RST pixel 2 are connected to each other, while the source/drain regions of the AMP pixel 2 and the SEL pixel 2 are connected to each other. Accordingly, such an arrangement facilitates the connection between the source/drain regions.

The FDG pixel 2 and the RST pixel 2 within the pixels are line-symmetrically arranged with respect to the line Y2-Y2′, which is a center line of the paired pixels of the FDG pixel 2 and the RST pixel 2 in the longitudinal direction, such that the floating diffusion regions FD come close to the line Y2-Y2′. Similarly, the AMP pixel 2 and the SEL pixel 2 within each pixel are line-symmetrically arranged with respect to the line Y1-Y1′, which is a center line of the paired pixels of the AMP pixel 2 and the SEL pixel 2 in the longitudinal direction, such that the floating diffusion regions FD come close to the line Y1-Y1′.

In addition, the two pixels of the FDG pixel 2 and the RST pixel 2 and the two pixels of the FDG pixel 2 and the RST pixel 2 are line-symmetrically arranged with respect to the line X-X′ which is a center line of these four pixels of the pixel unit PU in the longitudinal direction.

In the longitudinal direction of the pixel array unit 3, the pixel units PU are translation-symmetrically arranged. In the lateral direction of the pixel array unit 3, the pixel units PU are also translation-symmetrically arranged.

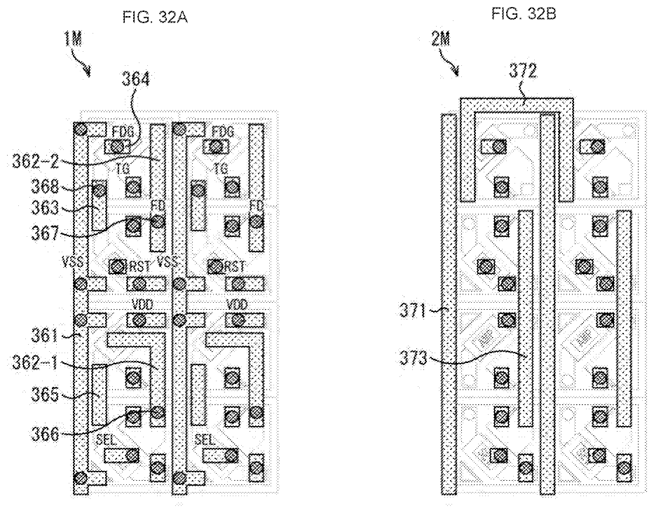

FIG. 32 depicts plan diagrams of the wiring layer 1M and the wiring layer 2M in the region 42 in FIG. 31.

For the one pixel unit PU, the wiring layer 1M includes a metal wire 361 connected to the ground corresponding to the predetermined potential VSS and metal wires 362-1 and 362-2 for connecting the respective floating diffusion regions FD formed in the respective pixels 2 within the pixel unit PU. The wiring layer 1M further includes a metal wire 363 for connecting the FDG pixel 2 and the RST pixel 2 within the pixel unit PU and a metal wire 365 for connecting the AMP pixel 2 and the SEL pixel 2 within the pixel unit PU. A metal wire 364 is a part of a metal wire constituting the additional capacitance subFD.

For the one pixel unit PU, the wiring layer 2M includes a metal wire 371 connected to the ground corresponding to the predetermined potential VSS and a metal wire 372 as the FD link 41 connecting the respective additional capacitances subFD of the paired two pixel units PU. The wiring layer 2M further includes a metal wire 373 for connecting the respective floating diffusion regions FD formed in the respective pixels 2 within the pixel unit PU.

The metal wire 373 of the wiring layer 2M is connected to the metal wire 362-1 via a via 366 of the wiring layer 1M, and connected to the metal wire 362-2 via a via 367 of the wiring layer 1M. In this manner, the floating diffusion regions FD of the four pixels constituting the pixel unit PU are connected to each other.

The metal wire 372 of the wiring layer 2M is connected to the metal wire 363 connecting the FDG pixel 2 and the RST pixel 2 within the pixel unit PU via a via 368 of the wiring layer 1M, and also connects the respective FDG pixels 2 adjacent to each other in the lateral direction. In such a manner, the respective additional capacitances subFD of the paired two pixel units PU are connected to each other.

The sixth example of the in-pixel layout in B of FIG. 25 adopted as the in-pixel layout of the pixel 2 can shorten the metal wire 363 connecting the FDG pixel 2 and the RST pixel 2, and also shorten the metal wire 365 connecting the AMP pixel 2 and the SEL pixel 2. Accordingly, connection between the FDG pixel 2 and the RST pixel 2 and connection between the AMP pixel 2 and the SEL pixel 2 can be facilitated.

### 15. FD Link Variations

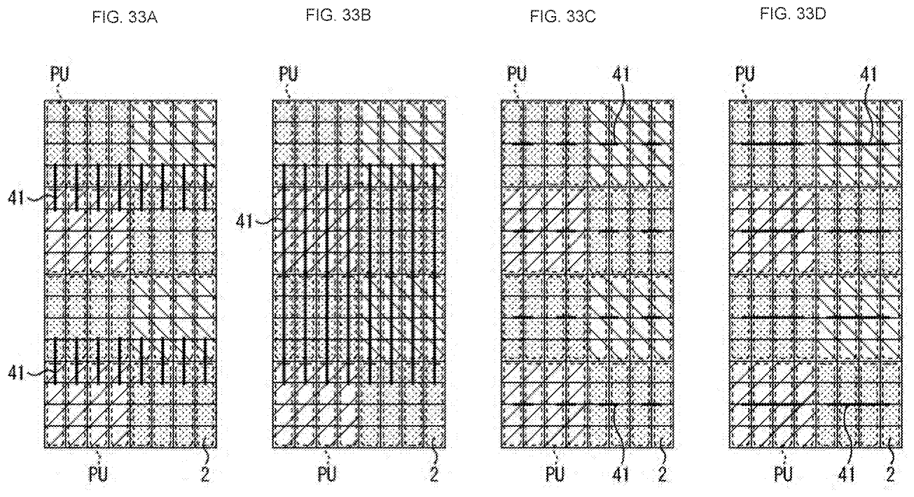

Variations of the FD link 41 will be described with reference to FIGS. 33 to 35.

Each of FIGS. 33 to 35 depicts a pixel region containing 8×16 pixels forming 128 pixels that is a part of the pixel array unit 3 which includes two-dimensional arrays forming a matrix shape. The eight pixel units PU in the lateral direction and the four pixel units PU in the longitudinal direction, each unit including 1×4 pixels forming 4 pixels, are arrayed in the pixel region including 8×16 pixels forming 128 pixels.

A of FIG. 33 depicts an example where the two pixel units PU adjacent to each other in the longitudinal direction are connected by the FD link 41 to share the floating diffusion regions FD of the two pixel units PU.

B of FIG. 33 depicts an example where the four pixel units PU adjacent to each other in the longitudinal direction are connected by the FD link 41 to share the floating diffusion regions FD of the four pixel units PU.

C of FIG. 33 depicts an example where the two pixel units PU adjacent to each other in the lateral direction are connected by the FD link 41 to share the floating diffusion regions FD of the two pixel units PU.

D of FIG. 33 depicts an example where the four pixel units PU adjacent to each other in the lateral direction are connected by the FD link 41 to share the floating diffusion regions FD of the two pixel units PU.

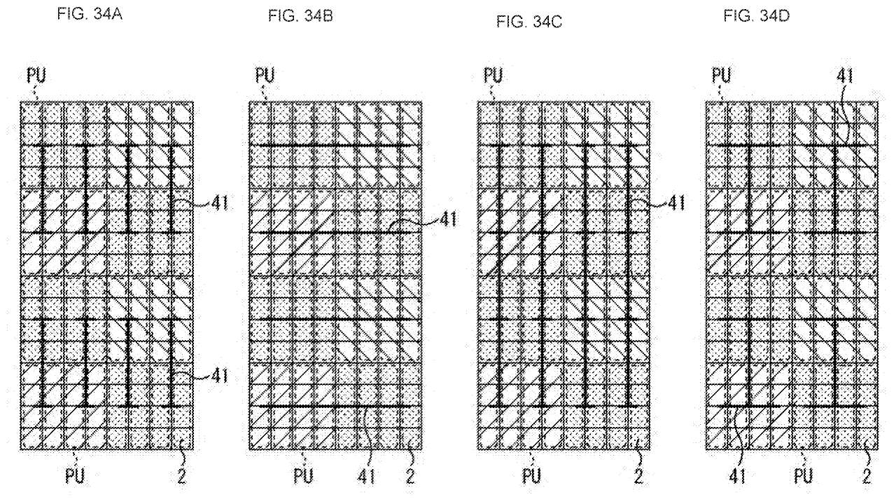

A of FIG. 34 depicts an example where the 2×2 pixel units PU forming the four pixel units PU, i.e., the two pixel units PU in the lateral direction and the two pixel units PU in the longitudinal direction, are connected by the FD link 41 to share the floating diffusion regions FD of the four pixel units PU.

B of FIG. 34 depicts an example where the eight pixel units PU adjacent to each other in the lateral direction are connected by the FD link 41 to share the floating diffusion regions FD of the eight pixel units PU.

C of FIG. 34 depicts an example where the 2×4 pixel units PU forming the eight pixel units PU, i.e., the two pixel units PU in the lateral direction and the four pixel units PU in the longitudinal direction, are connected by the FD link 41 to share the floating diffusion regions FD of the eight pixel units PU.

D of FIG. 34 depicts an example where the 4×2 pixel units PU forming the eight pixel units PU, i.e., the four pixel units PU in the lateral direction and the two pixel units in the longitudinal direction, are connected by the FD link 41 to share the floating diffusion regions FD of the eight pixel units PU.

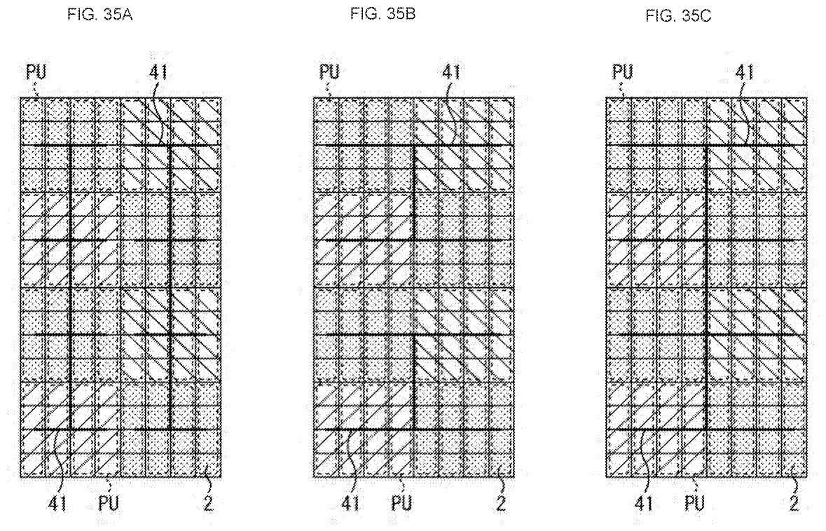

A of FIG. 35 depicts an example where the 4×4 pixel units PU forming the 16 pixel units, i.e., the four pixel units PU in the lateral direction and the four pixel units PU in the longitudinal direction, are connected by the FD link 41 to share the floating diffusion regions FD of the 16 pixel units PU.

B of FIG. 35 depicts an example where the 8×2 pixel units PU forming the 16 pixel units PU, i.e., the eight pixel units PU in the lateral direction and the two pixel units PU in the longitudinal direction, are connected by the FD link 41 to share the floating diffusion regions FD of the 16 pixel units PU.

C of FIG. 35 depicts an example where the 8×4 pixel units PU forming the 32 pixel units, i.e., the eight pixel units PU in the lateral direction and the four pixel units PU in the longitudinal direction, are connected by the FD link 41 to share the floating diffusion regions FD of the 32 pixel units PU.

Various connection methods such as those described above are adoptable for the FD link 41. Accumulable capacity of the floating diffusion region FD increases as the number of connection of the pixel units PU increases with use of the FD link 41. Accordingly, accumulable signal charge can increase in a case of execution of FD addition.

### 16. Eighth Configuration Example of Pixel Unit (2×2)

Described in the above embodiment has been a case of the pixel unit PU including 1×4 pixels forming four pixels. Described next will be a case of the pixel unit PU including 2×2 pixels forming four pixels. In the following description, the first example of the different in-pixel layout depicted in B of FIG. 24 is adopted as the in-pixel layout of the pixels 2.

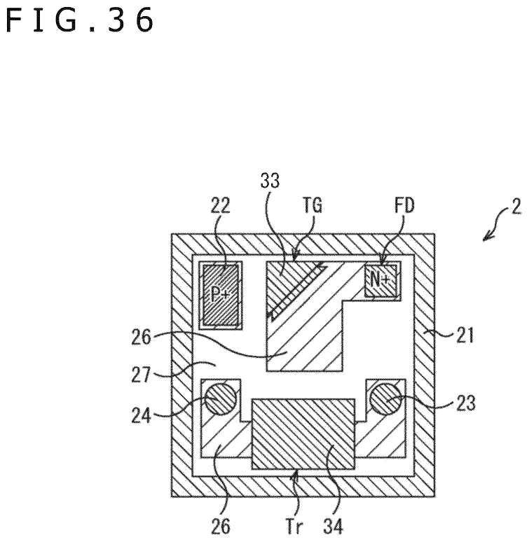

FIG. 36 is a diagram depicting again the first example of the different in-pixel layout of the pixel 2 depicted in B of FIG. 24.

In the pixel 2 depicted in FIG. 36, the gate electrode 34 of the pixel transistor Tr is arranged at a central portion of one side of the rectangular pixel region in the left-right direction, while the high concentration N-type layers 23 and 24 each corresponding to a source/drain region are arranged in a left-right symmetrical recessed shape. The pixel transistor Tr is arranged in one of regions formed by dividing the rectangular pixel region of the pixel 2 in the longitudinal direction, while the transfer transistor TG, the floating diffusion region FD, and the well contact portion 22 are arranged in the other region.

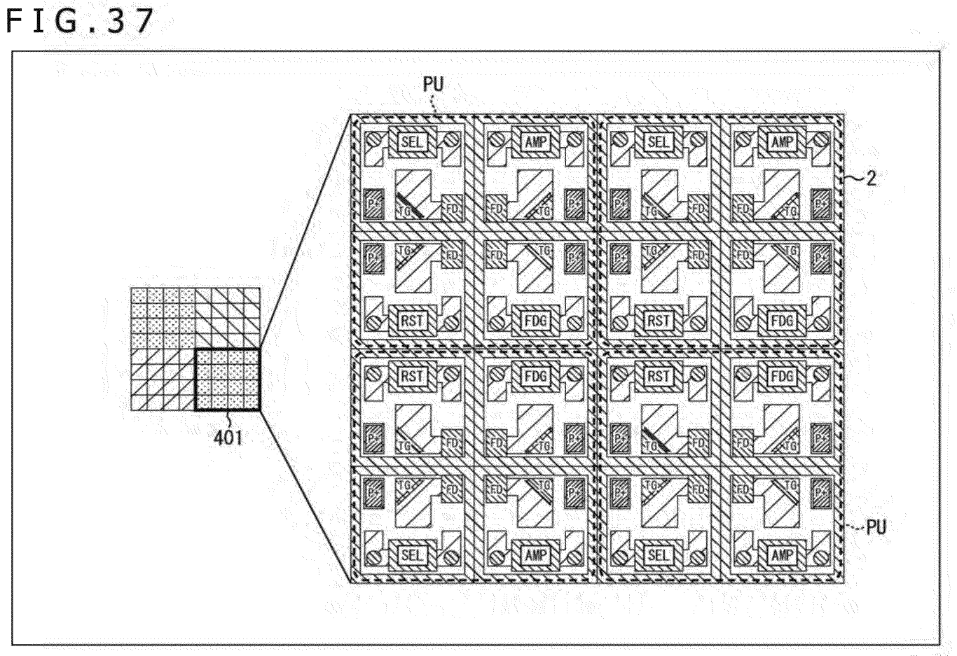

FIG. 37 is a plan diagram explaining an eighth configuration example of the pixel unit.

A left figure of FIG. 37 is a plan diagram depicting a part of the pixel array unit 3 and indicating a pixel region including 8×8 pixels forming 64 pixels.

A right figure of FIG. 37 is an enlarged diagram depicting a pixel arrangement within the pixel units PU with focus placed on a region 401 which is a pixel region unit including the color filters in the same color in the left figure of FIG. 37.

While reference signs are given to the pixel units PU and the pixel 2 in the enlarged diagram of the region 401 in the right part of FIG. 37, reference signs are not given to the transfer transistor TG, the floating diffusion region FD, the well contact portion 22, and the pixel transistor Tr within each pixel to avoid complication of the figure. “FGD,” “RST,” “AMP,” or “SEL” is given onto the gate electrode 34 of each of the pixel transistors Tr to indicate which one of the switching transistor FDG, the reset transistor RST, the amplification transistor AMP, and the selection transistor SEL corresponds to the pixel transistor Tr of each of the pixels 2. Moreover, “TG” is given to the part corresponding to the gate electrode 33 in the transfer transistor TG, “FD” is given to the floating diffusion region FD, and “P+” is given to the well contact portion 22.

According to the eighth configuration example, each of the pixel units PU includes 2×2 pixels forming four pixels, and each of the pixels 2 contained in these four pixels includes any one of the switching transistor FDG, the reset transistor RST, the amplification transistor AMP, or the selection transistor SEL as the pixel transistor Tr.

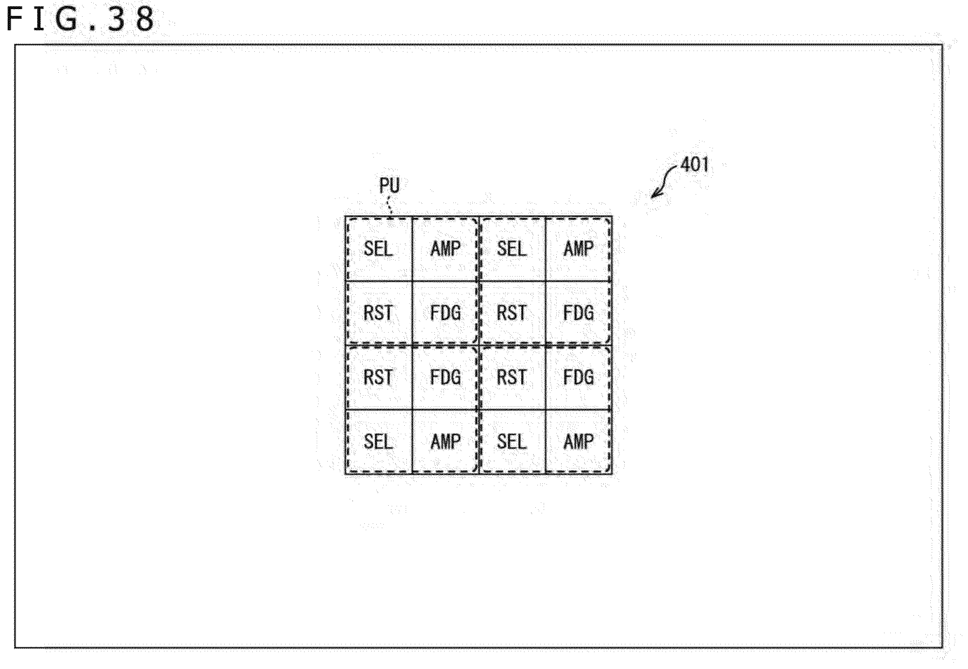

FIG. 38 is a diagram depicting only the arrangement of the switching transistor FDG, the reset transistor RST, the amplification transistor AMP, and the selection transistor SEL of each of the pixels 2 in the region 401 including 4×4 pixels forming 16 pixels in FIG. 37.

In the region 401 which is a pixel region unit including the color filters in the same color, the FDG pixels 2, the RST pixels 2, the AMP pixels 2, and the SEL pixels 2 are arranged such that 4×2 pixels forming eight pixels in upper two rows and 4×2 pixels forming eight pixels in lower two rows are line-symmetrically arranged.

In 2×2 pixels forming four pixels constituting the pixel unit PU, the AMP pixel 2 and the SEL pixel 2 are arranged in the same row, while the FDG pixel 2 and the RST pixel 2 are arranged in the same row. The FDG pixel 2 and the RST pixel 2 are arranged in inner two rows in the region 401 including 4×4 pixels forming 16 pixels, while the FDG pixel 2 and the RST pixel 2 are arranged in outer two rows in the region 401.

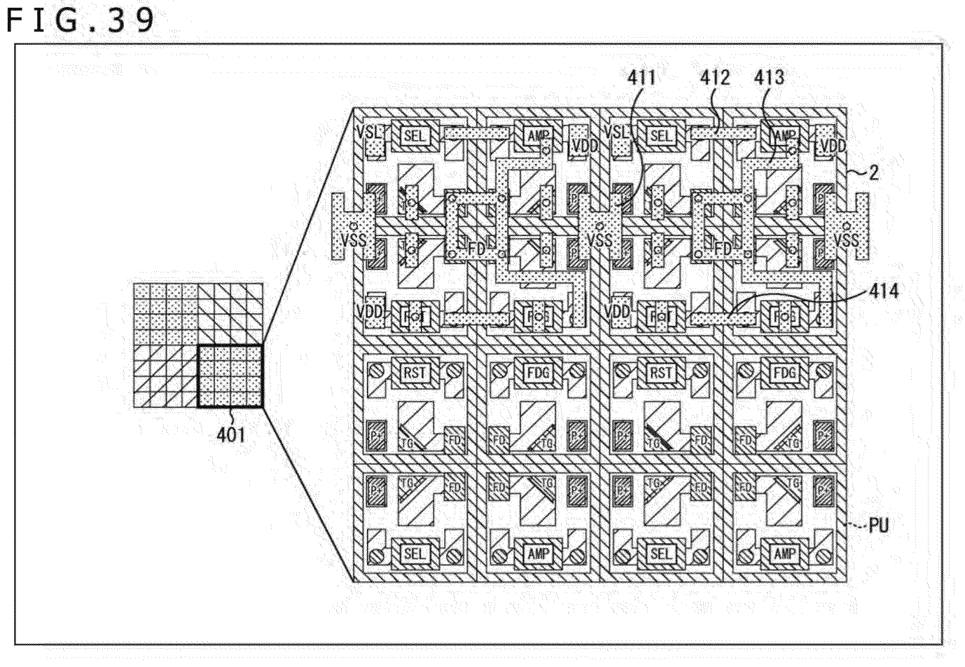

FIG. 39 is a plan diagram depicting a wiring example of metal wires within the pixel unit PU. Note that the metal wires are depicted for only the region of the upper 4×2 pixels forming eight pixels in the region 401 including 4×4 pixels forming 16 pixels in FIG. 39, and not for the region of the lower 4×4 pixels forming 16 pixels which are translation-symmetrically arranged.

A metal wire 411 connected to the well contact portion 22 of each of the pixels 2 and a metal wire 412 connecting the source/drain regions of the AMP pixel 2 and the SEL pixel 2 are formed in the region of the upper 4×2 pixels forming eight pixels in the region 401. The metal wire 411 is connected to a ground (GND) corresponding to the predetermined potential VSS. Moreover, a metal wire 413 is formed to connect the floating diffusion region FD formed in each of the pixels 2 within the pixel unit PU and the gate electrodes 34 of the amplification transistors AMP. Further, a metal wire 414 is formed to connect the source/drain regions of the FDG pixel 2 and the RST pixel 2.

As described above, the AMP pixel 2 and the SEL pixel 2 are arranged in the same row, and the FDG pixel 2 and the RST pixel 2 are arranged in the same row. This configuration can shorten the metal wire 412 and the metal wire 414, and thus can facilitate connection between the FDG pixel 2 and the RST pixel 2 and connection between the AMP pixel 2 and the SEL pixel 2.

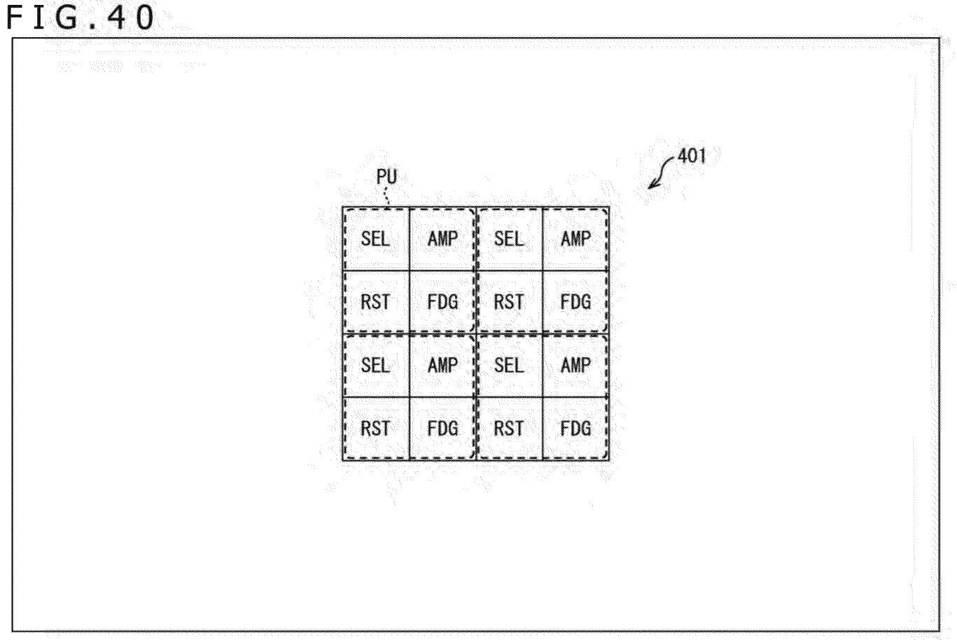

FIG. 40 is a diagram depicting a different arrangement example of the switching transistor FDG, the reset transistor RST, the amplification transistor AMP, and the selection transistor SEL in the region 401 including 4×4 pixels forming 16 pixels.

According to the example described above, the FDG pixels 2, the RST pixels 2, the AMP pixels 2, and the SEL pixels 2 are arranged such that 4×2 pixels forming eight pixels in the upper two rows and 4×2 pixels forming eight pixels in the lower two rows are line-symmetrically arranged as depicted in FIG. 38.

Meanwhile, as depicted in FIG. 40, the FDG pixel 2, the RST pixel 2, the AMP pixel 2, and the SEL pixel 2 included in the one pixel unit PU may be translation-symmetrically arranged in both the lateral direction and the longitudinal direction. Note that, also in this case, the AMP pixel 2 and the SEL pixel 2 are arranged in the same row and that the FDG pixel 2 and the RST pixel 2 are arranged in the same row within 2×2 pixels forming four pixels included in the pixel unit PU.

The AMP pixel 2 and the SEL pixel 2 are arranged in the same row, and the FDG pixel 2 and the RST pixel 2 are arranged in the same row. This configuration can shorten the metal wire 412 and the metal wire 414, and thus can facilitate connection between the FDG pixel 2 and the RST pixel 2 and connection between the AMP pixel 2 and the SEL pixel 2.

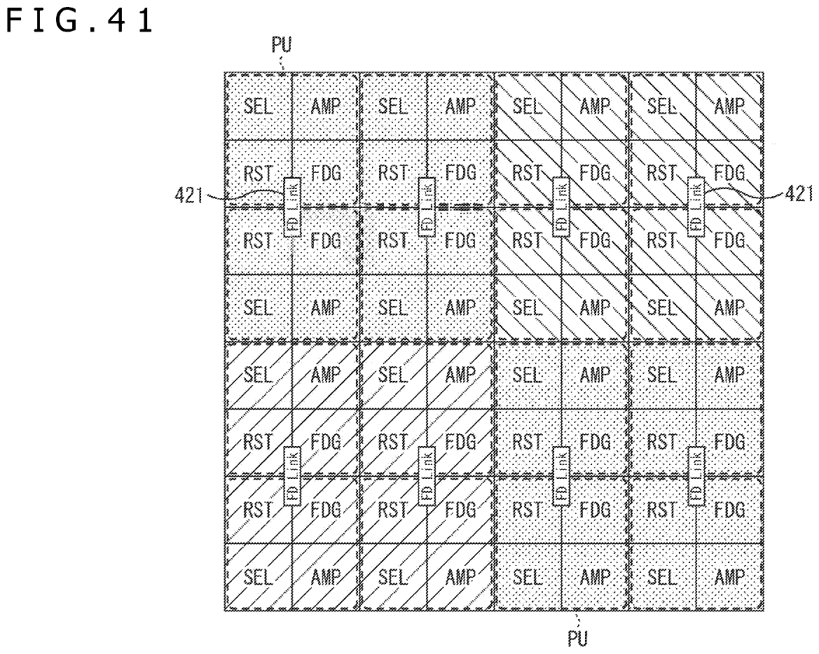

Connection examples of the FD link 41 adoptable for the pixel unit PU according to the eighth configuration example will next be described with reference to FIGS. 41 to 44.

FIG. 41 is a plan diagram depicting a first connection example of the FD link 41 of the pixel unit PU according to the eighth configuration example.

In the first connection example in FIG. 41, the two pixel units PU adjacent to each other in the longitudinal direction are connected by an FD link 421.

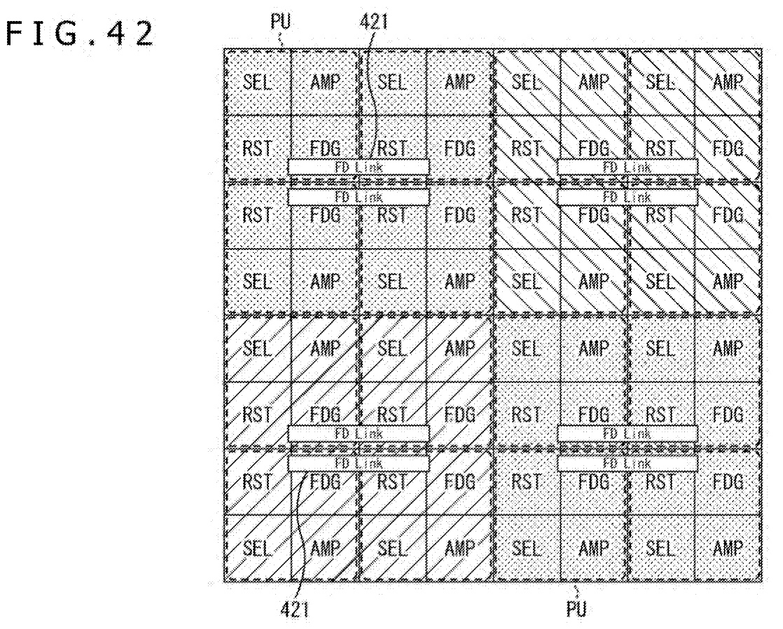

FIG. 42 is a plan diagram depicting a second connection example of the FD link 41 of the pixel unit PU according to the eighth configuration example.

In the second connection example in FIG. 42, the two pixel units PU adjacent to each other in the lateral direction are connected by the FD link 421.

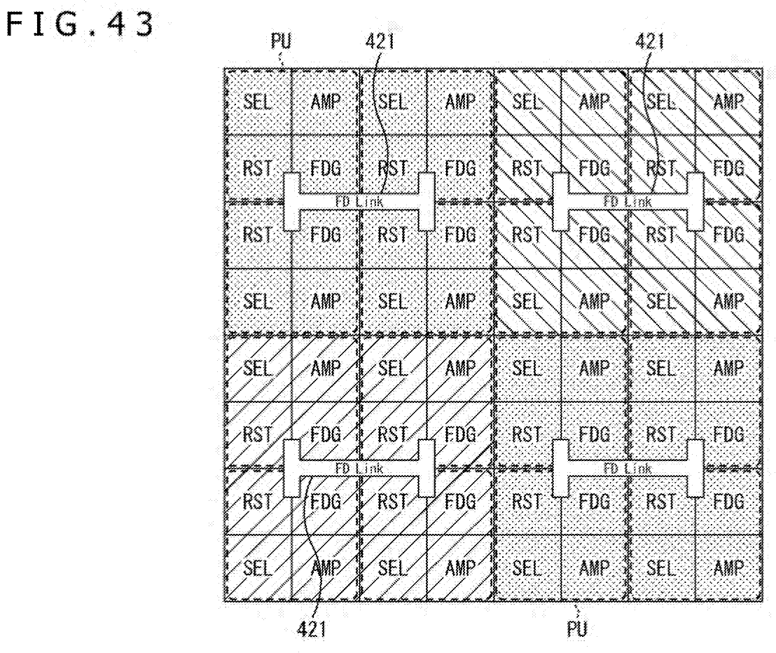

FIG. 43 is a plan diagram depicting a third connection example of the FD link 41 of the pixel unit PU according to the eighth configuration example.

In the third connection example in FIG. 43, the 2×2 pixel units PU forming the four pixel units adjacent to each other in the lateral direction and the longitudinal direction are connected by the FD link 421.

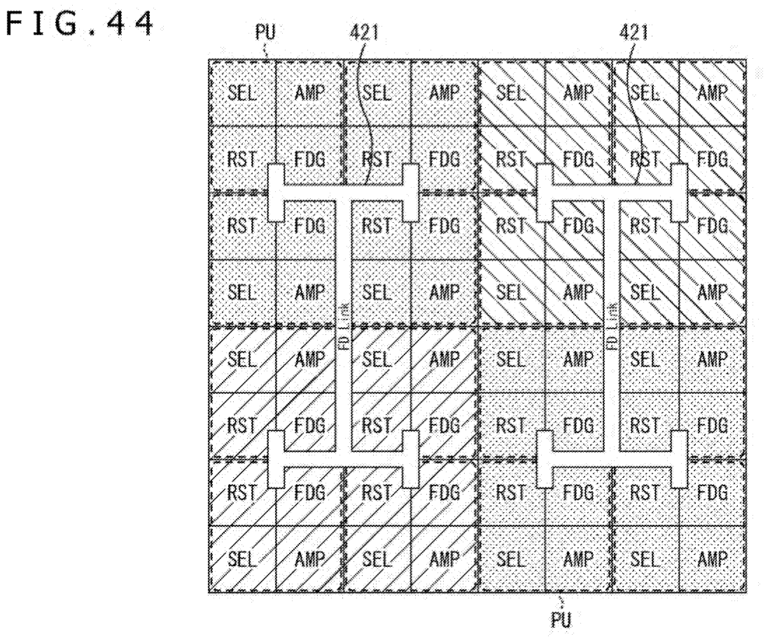

FIG. 44 is a plan diagram depicting a fourth connection example of the FD link 41 of the pixel unit PU according to the eighth configuration example.

In the fourth connection example depicted in FIG. 44, the 2×4 pixel units PU forming the eight pixel units PU adjacent to each other in the lateral direction and the longitudinal direction are connected by the FD link 421.

According to the eighth configuration example, the pixel units PU may be formed in the pixel array unit 3 by connection appropriately selected from any one of the first to fourth connection examples described above. The configuration which electrically connects a plurality of pixel units PU by the FD link 421 can increase accumulated capacitance of signal charge.

### 17. Ninth Configuration Example of Pixel Unit (4×2)

Described next will be a case of the pixel unit PU including 4×2 pixels forming eight pixels. As in the eighth configuration example, the first example of the different in-pixel layout depicted in B of FIG. 24 is adopted as the in-pixel layout of the pixels 2.

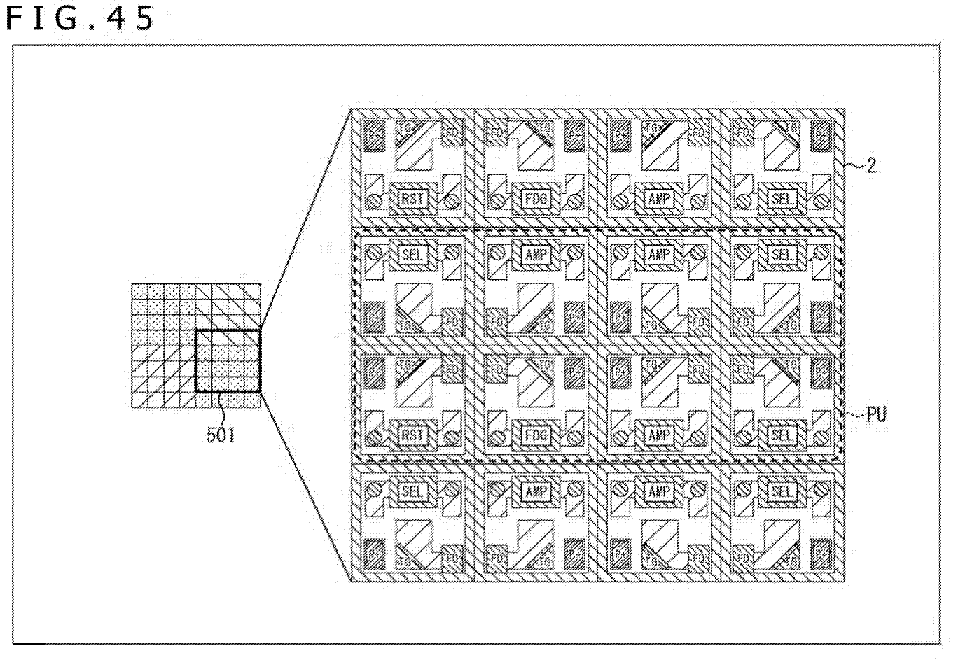

FIG. 45 is a plan diagram explaining a ninth configuration example of the pixel unit.

A left figure of FIG. 45 is a plan diagram depicting an arrangement of the pixel units PU constituting a part of the pixel array unit 3.

A right figure of FIG. 45 is an enlarged diagram depicting a pixel arrangement of the respective pixels 2 in a region 501 including 4×4 pixels in a pixel region of 8×8 pixels forming 64 pixels depicted in the left figure of FIG. 45.

While reference signs are given to the pixel units PU and the pixel 2 in the enlarged diagram of the region 501 in the right part of FIG. 45, reference signs are not given to the transfer transistor TG, the floating diffusion region FD, the well contact portion 22, and the pixel transistor Tr within each pixel to avoid complication of the figure. “FGD,” “RST,” “AMP,” or “SEL” is given onto the gate electrode 34 of each of the pixel transistors Tr to indicate which one of the switching transistor FDG, the reset transistor RST, the amplification transistor AMP, and the selection transistor SEL corresponds to the pixel transistor Tr of each of the pixels 2. Moreover, “TG” is given to the part corresponding to the gate electrode 33 in the transfer transistor TG, “FD” is given to the floating diffusion region FD, and “P+” is given to the well contact portion 22.

According to the ninth configuration example, the pixel unit PU includes 4×2 pixels forming eight pixels. As the pixel transistors Tr of the four pixels in the upper one row of the pixel unit PU, the selection transistor SEL, the amplification transistor AMP, the amplification transistor AMP, and the selection transistor SEL are provided in this order from the left. As the pixel transistors Tr of the four pixels in the lower one row of the pixel unit PU, the reset transistor RST, the switching transistor FDG, the amplification transistor AMP, and the selection transistor SEL are provided in this order from the left.

Accordingly, the pixel unit PU of the ninth configuration example includes the three AMP pixels 2, the three SEL pixels 2, the one FDG pixel 2, and the one RST pixel 2.

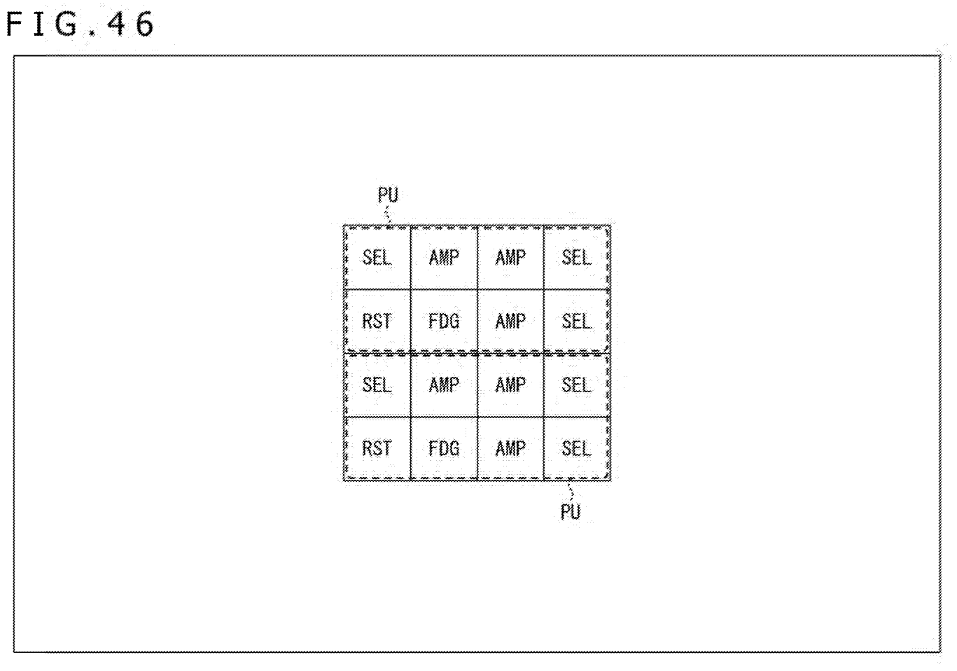

FIG. 46 depicts an arrangement of the pixel unit PU of the ninth configuration example in the pixel region including 4×4 pixels each having the color filter in the same color.

In the pixel array unit 3 in the ninth configuration example, the pixel units PU having the pixel arrays described with reference to FIG. 45 are translation-symmetrically arranged in the lateral direction and the longitudinal direction.

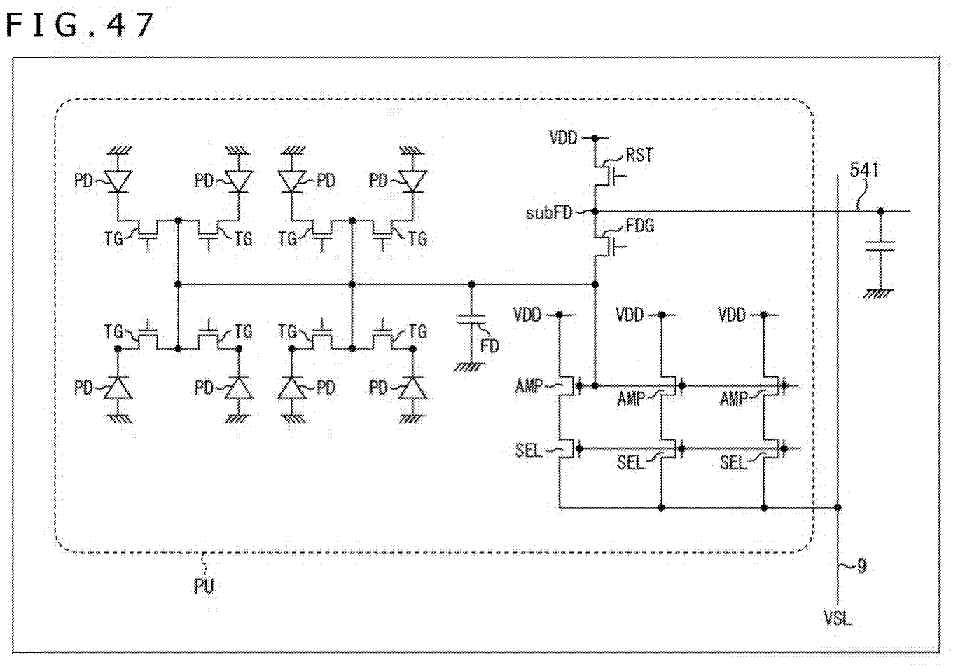

FIG. 47 depicts a circuit configuration example of the pixel unit PU according to the ninth configuration example.

The pixel unit PU individually has the floating diffusion region FD, the photodiode PD, and the transfer transistor TG for each of the pixels, and shares the floating diffusion region FD, the switching transistor FDG, the reset transistor RST, the three amplification transistors AMP, the three selection transistors SEL, and the additional capacitance subFD between the eight pixels within the pixel unit PU.

The three amplification transistors AMP are connected in parallel, and the three selection transistors SEL are also connected in parallel. The parallel connection between the three amplification transistors AMP can effectively increase the channel width W, and thus can reduce noise components.

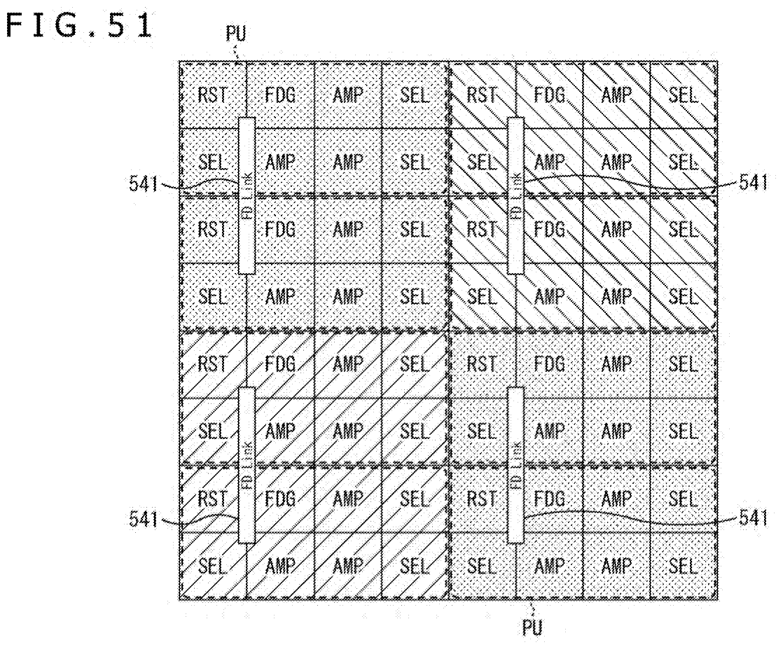

The pixel unit PU is electrically connected to at least one different pixel unit PU by an FD link 541. The connection with the different pixel unit PU by the FD link 541 will be described later with reference to FIGS. 51 to 56.

In a case where the two pixel units PU each having the circuit configuration depicted in FIG. 47 are connected by the FD link 541, the solid-state imaging device 1 is operable while changing accumulated charge capacitance of the floating diffusion region FD in the following manners according to a light quantity of incident light or an operation mode, for example.

For example, a first operation mode as a mode for reading the pixel signal VSL is achievable by turning off the switching transistors FDG of both the two pixel units PU connected by the FD link 541 and transferring charge accumulated in the photodiodes PD of the respective pixels 2 within the pixel unit PU to the floating diffusion region FD included in the own pixel unit PU.

For example, a second operation mode as a mode for reading the pixel signal VSL is achievable by turning on only the switching transistor FDG of the own pixel unit PU of the two pixel units PU connected by the FD link 541 and transferring charge accumulated in the photodiodes PD of the respective pixels 2 within the pixel units PU to the floating diffusion region FD and the additional capacitance subFD including the FD link 541 within the own pixel unit PU.

For example, a third operation mode as a mode for reading the pixel signal VSL is achievable by turning on the switching transistor FDG of both the two pixel units PU connected by the FD link 541 and transferring charge accumulated in the photodiodes PD of the respective pixels 2 within the pixel units PU to the floating diffusion region FD within the own pixel unit PU and the additional capacitances subFD of the two pixel units PU connected by the FD link 541.

An accumulated amount of signal charge is switchable in three levels with use of the first operation mode to the third operation mode. In each of the first operation mode to the third operation mode, the pixel signal VSL may be read for each pixel unit of one pixel, or for each pixel unit of a plurality of pixels. In a case where the pixel signal VSL is read for each unit of a plurality of pixels, FD addition which adds a plurality of pixel signals VSL is executed by the floating diffusion region FD.

In addition, a fourth operation mode as a mode for simultaneously reading the pixel signals VSL of all the 16 pixels of the two pixel units PU is achievable by turning on the switching transistors FDG of both the two pixel units PU connected by the FD link 541. In this case as well, the pixel signals VSL of the 16 pixels of the two pixel units PU are added by FD addition via the floating diffusion regions FD and the additional capacitances subFD of the respective pixel units PU and the FD link 541.

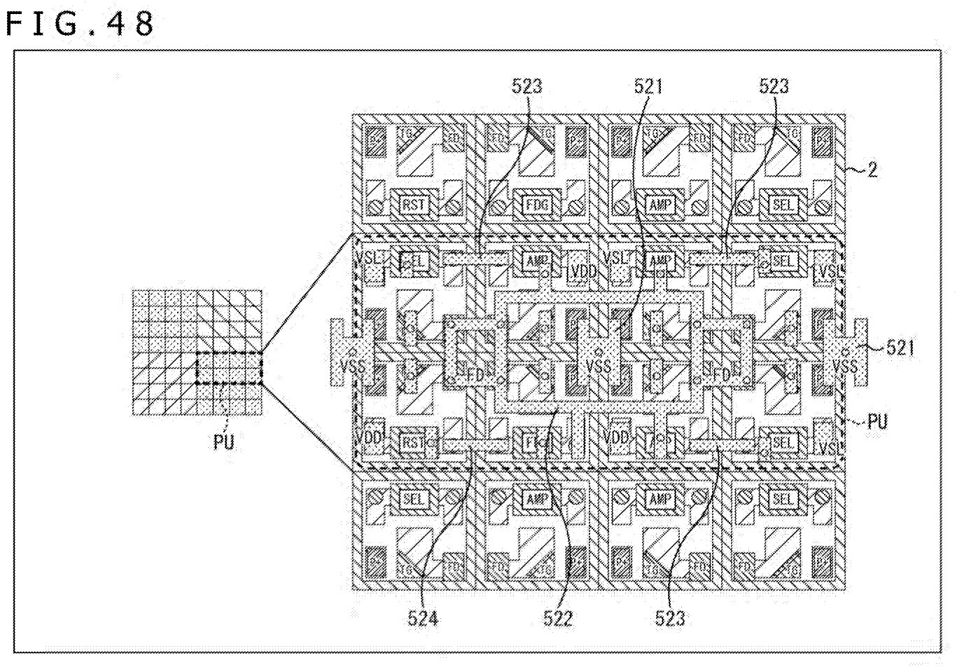

FIG. 48 is a plan diagram depicting a wiring example of metal wires within the pixel unit PU.

A metal wire 521 connected to the well contact portion 22 of each of the pixel 2 and a metal wire 522 connecting the floating diffusion region FD formed in each of the pixels 2 within the pixel unit PU and the gate electrodes 34 of the amplification transistors AMP are formed in a region of 4×2 pixels forming eight pixels constituting the pixel unit PU. The metal wire 521 is connected to a ground (GND) corresponding to the predetermined potential VSS. Further, a metal wire 523 connecting source/drain regions of the AMP pixel 2 and the SEL pixel 2, and a metal wire 524 connecting source/drain regions of the FDG pixel 2 and the RST pixel 2 are formed.

The AMP pixel 2 and the SEL pixel 2 are arranged in the same row, and the FDG pixel 2 and the RST pixel 2 are arranged in the same row. This configuration can shorten the metal wire 523 and the metal wire 524, and thus can facilitate connection between the FDG pixel 2 and the RST pixel 2 and connection between the AMP pixel 2 and the SEL pixel 2.

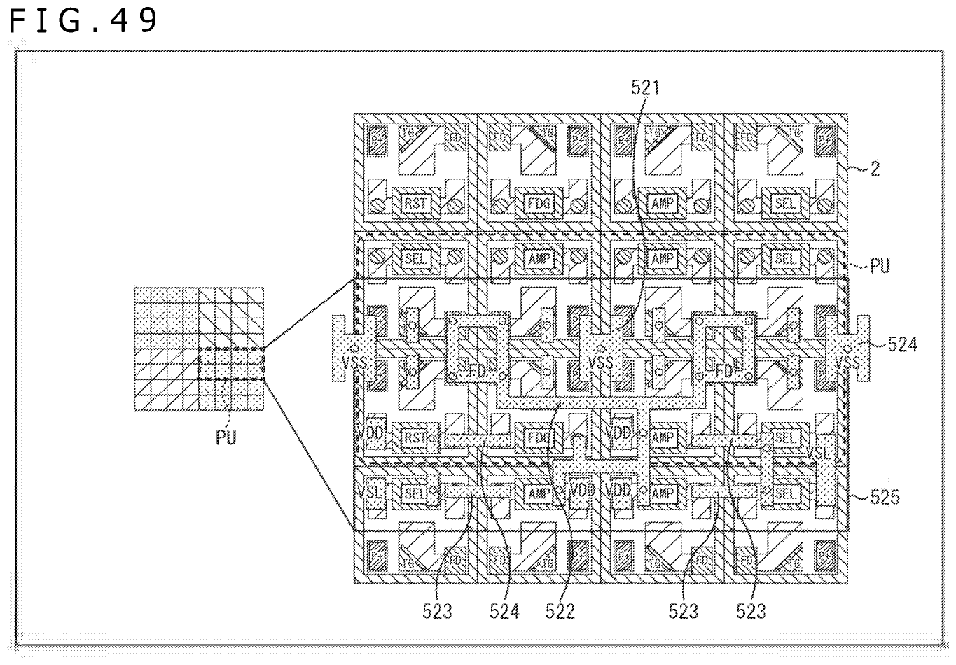

FIG. 49 is a plan diagram depicting a different wiring example of metal wires within the pixel unit PU.

The wiring example in FIG. 48 has been a wiring example which completes wiring by using the pixel transistors Tr within the pixel unit PU which is a sharing unit for sharing the floating diffusion regions FD.

In contrast, the wiring example in FIG. 49 is such a wiring example which uses the pixel transistors Tr provided out of the pixel unit PU which is a sharing unit for sharing the floating diffusion regions FD. Specifically, the selection transistor SEL, the amplification transistor AMP, the amplification transistor AMP, and the selection transistor SEL of the pixels 2 located one row below the pixel unit PU are used in place of the selection transistor SEL, the amplification transistor AMP, the amplification transistor AMP, and the selection transistor SEL of the pixels 2 in the upper row within the pixel unit PU. A region 525 indicates a region of the pixel transistors and the metal wires used for the one pixel unit PU.

The metal wire 521 is connected to a ground (GND) corresponding to the predetermined potential VSS, and connects the well contact portions 22 of the respective pixels 2. A metal wire 522 connects the floating diffusion region FD formed in each of the pixels 2 within the pixel unit PU and the gate electrodes 34 of the amplification transistors AMP. A metal wire 523 connects source/drain regions of the AMP pixel 2 and the SEL pixel 2. A metal wire 524 connects source/drain regions of the FDG pixel 2 and the RST pixel 2.

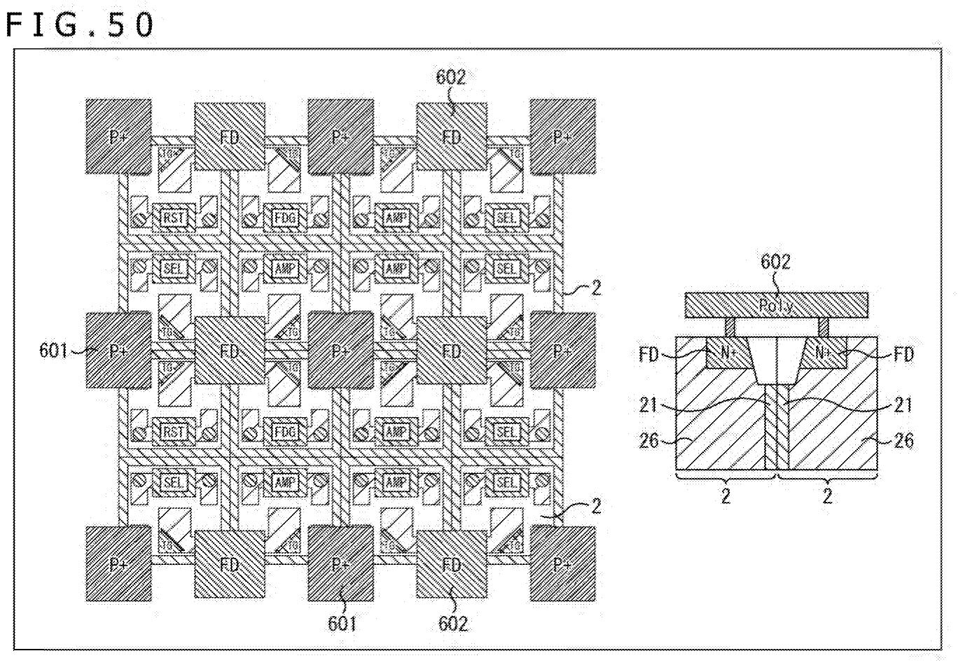

FIG. 50 is a plan diagram depicting a modification of metal wires of the pixel unit PU.

The metal wire 521 connected to the well contact portions 22 of the respective pixels 2, and the metal wire 522 connecting the floating diffusion regions FD of the respective pixels 2 included in the wiring examples of the metal wires depicted in FIGS. 48 and 49 may be replaced with shared wires 601 and 602 as depicted in FIG. 50.

The shared wire 601 is arranged in a portion on an upper side corresponding to a vertical direction of a substrate surface of a region where the well contact portions 22 of the four pixels 2 are arranged close to each other, and is connected to the four well contact portions 22 arranged close to each other.

The shared wire 602 is arranged in a portion on an upper side corresponding to a vertical direction of a substrate surface of a region where the floating diffusion regions FD of the four pixels 2 are arranged close to each other, and is connected to the four floating diffusion regions FD arranged close to each other. A right cross-sectional diagram of FIG. 50 depicts connection between the shared wire 602 and the four floating diffusion regions FD arranged on the lower side in the vertical direction of the substrate surface.

For example, the shared wires 601 and 602 may be formed with use of polysilicon or metal wires. The configuration equipped with the shared wires 601 and 602 can reduce wiring of the multilayer wiring layer.

Connection examples of the FD link 541 adoptable for the pixel units PU according to the ninth configuration example will next be described with reference to FIGS. 51 to 56.

FIG. 51 is a plan diagram depicting a first connection example of the FD link 541 of the pixel units PU according to the ninth configuration example.

In the first connection example in FIG. 51, the two pixel units PU adjacent to each other in the longitudinal direction are connected by the FD link 541.

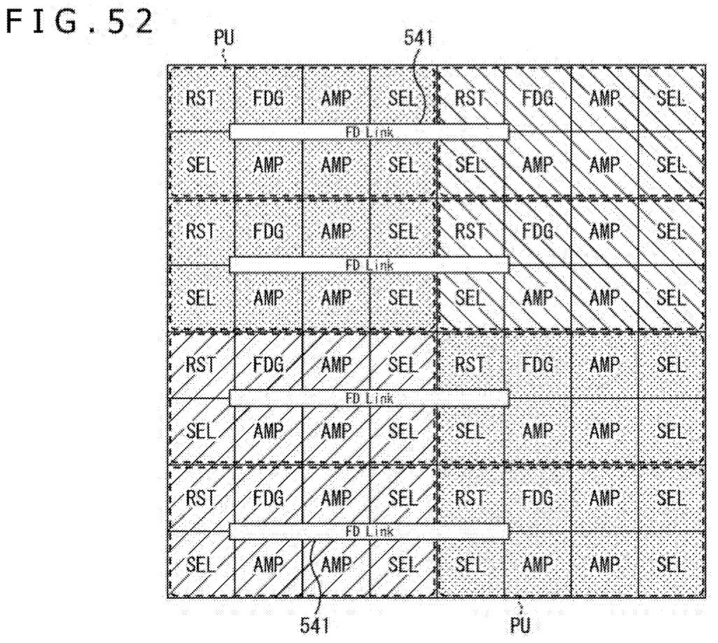

FIG. 52 is a plan diagram depicting a second connection example of the FD link 541 of the pixel units PU according to the ninth configuration example.

In the second connection example in FIG. 52, the two pixel units PU adjacent to each other in the lateral direction are connected by the FD link 541.

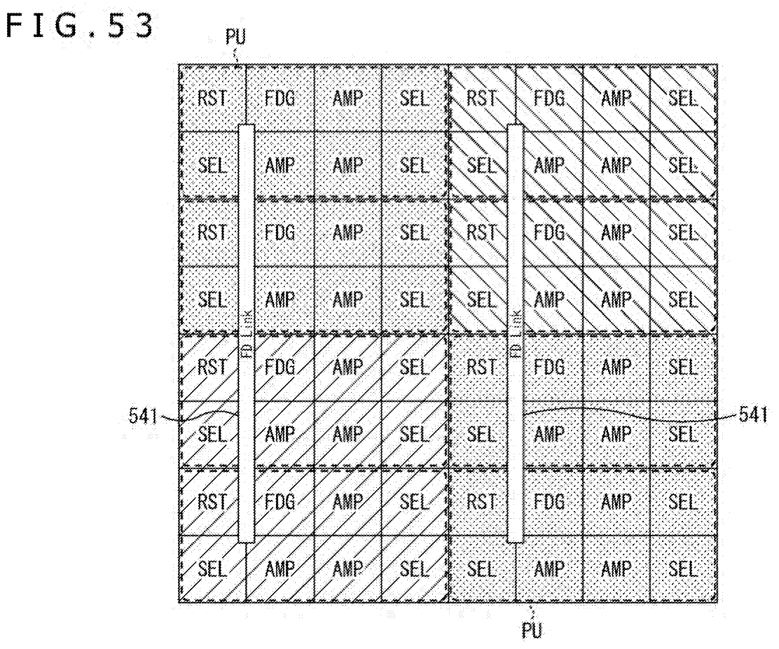

FIG. 53 is a plan diagram depicting a third connection example of the FD link 541 of the pixel units PU according to the ninth configuration example.

In the third connection example in FIG. 53, the four pixel units PU adjacent to each other in the longitudinal direction are connected by the FD link 541.

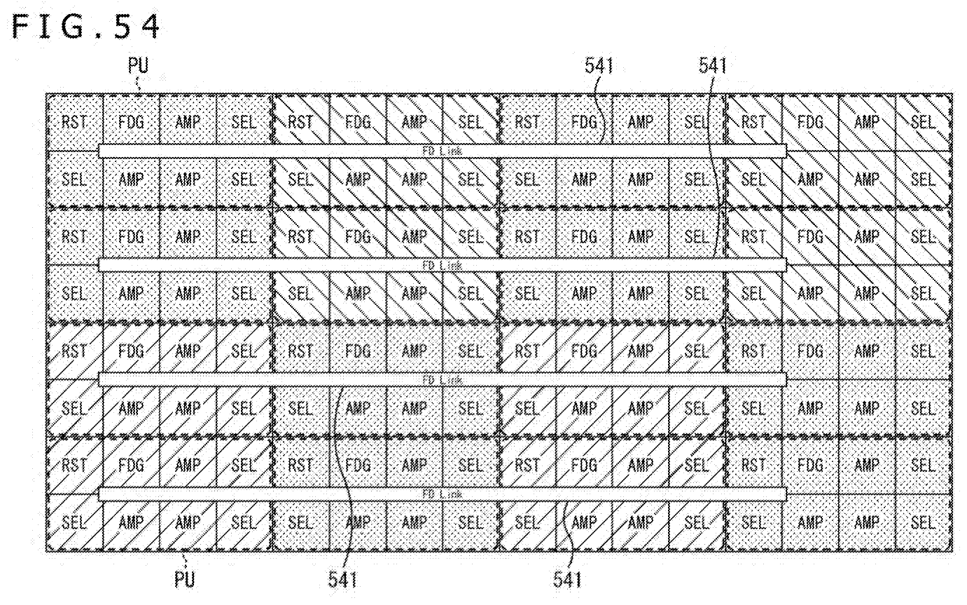

FIG. 54 is a plan diagram depicting a fourth connection example of the FD link 541 of the pixel units PU according to the ninth configuration example.

In the fourth connection example in FIG. 54, the four pixel units PU adjacent to each other in the lateral direction are connected by the FD link 541.

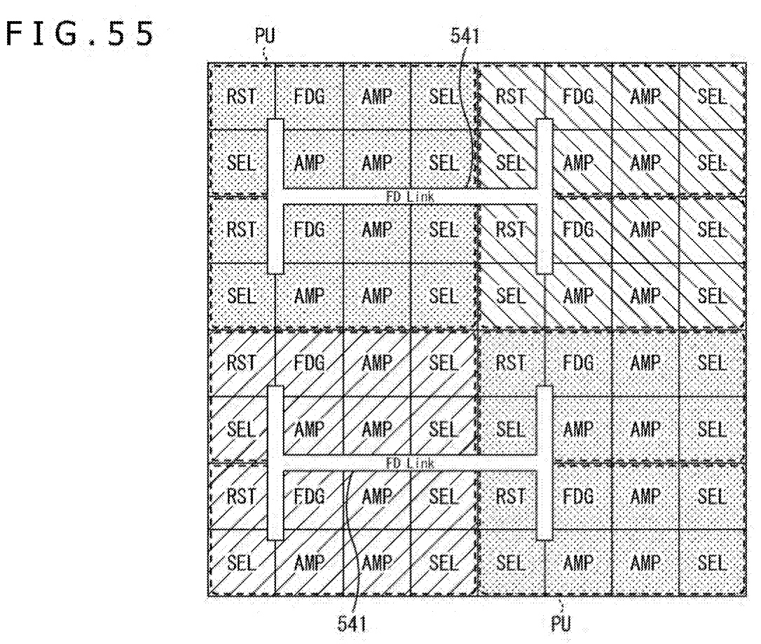

FIG. 55 is a plan diagram depicting a fifth connection example of the FD link 541 of the pixel units PU according to the ninth configuration example.

In the fifth connection example in FIG. 55, the 2×2 pixel units PU forming the four pixel units PU adjacent to each other in the lateral direction and the longitudinal direction are connected by the FD link 541. The FD link 541 is wired in an H-shaped arrangement in the longitudinal direction.

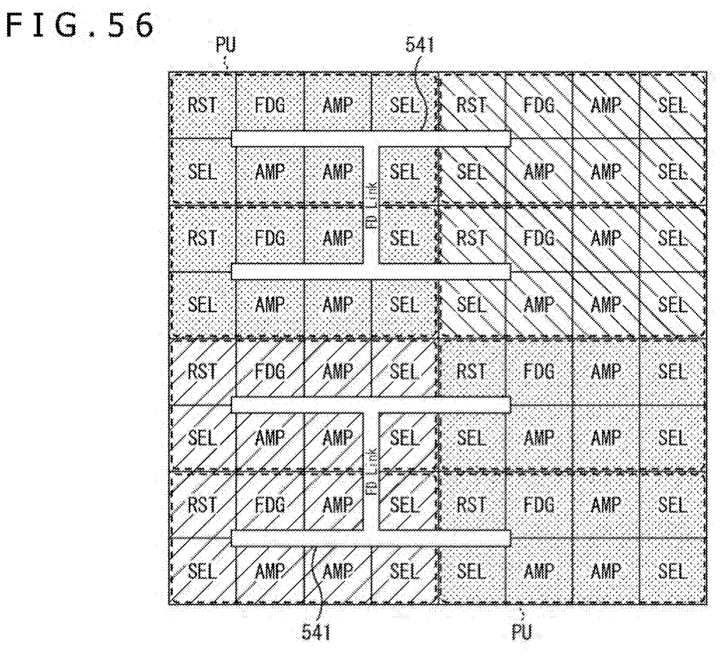

FIG. 56 is a plan diagram depicting a sixth connection example of the FD link 541 of the pixel units PU according to the ninth configuration example.

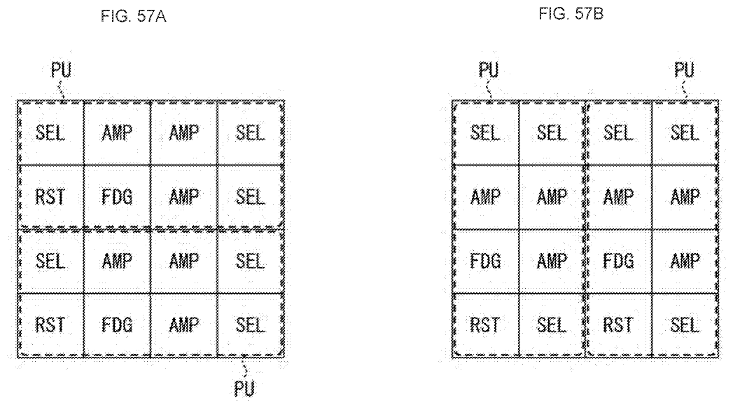

In the sixth connection example in FIG. 57, the 2×2 pixel units PU forming the four pixel units PU adjacent to each other in the lateral direction and the longitudinal direction are connected by the FD link 541. The FD link 541 is wired in an H-shaped arrangement in the lateral direction, i.e., rotated arrangement of the longitudinally H-shaped arrangement by 90 degrees.

According to the ninth configuration example, the pixel units PU may be formed in the pixel array unit 3 by connection appropriately selected from any one of the first to sixth connection examples described above. The configuration which electrically connects a plurality of pixel units PU by the FD link 541 can increase accumulated capacitance of signal charge.

Next described with reference to FIGS. 57 to 61 will be various types of arrangement examples of the switching transistor FDG, the reset transistor RST, the amplification transistor AMP, and the selection transistor SEL in the pixel unit PU according to the ninth configuration example.

A of FIG. 57 depicts an arrangement example of the pixel transistors Tr depicted in FIG. 46. This arrangement example will hereinafter be referred to as a first arrangement example of the pixel transistors Tr in the pixel unit PU of the ninth configuration example.

According to the first configuration example, the one pixel unit PU includes 4×2 pixels forming eight pixels, and has a laterally elongated shape. As the pixel transistors Tr of the four pixels in the upper one row, the pixel unit PU includes the selection transistor SEL, the amplification transistor AMP, the amplification transistor AMP, and the selection transistor SEL in this order from the left. As the pixel transistors Tr of the four pixels in the lower one row, the pixel unit PU includes the reset transistor RST, the switching transistor FDG, the amplification transistor AMP, and the selection transistor SEL in this order from the left. Moreover, the pixel unit PU having this pixel transistor arrangement is translation-symmetrically arranged in both the lateral direction and the longitudinal direction for each unit of a region including 4×4 pixels forming 16 pixels and having the color filters in the same color.

B of FIG. 57 depicts a second arrangement example of the pixel transistors Tr in the pixel unit PU of the ninth configuration example.

According to the second configuration example, the one pixel unit PU includes 2×4 pixels forming eight pixels, and has a longitudinally elongated shape. The arrangement of the respective pixel transistors Tr is a switched arrangement of the first arrangement example in A of FIG. 57 into a longitudinally elongated shape. Specifically, as the pixel transistors Tr of the four pixels in the right one column, the pixel unit PU includes the selection transistor SEL, the amplification transistor AMP, the amplification transistor AMP, and the selection transistor SEL in this order from the top. As the pixel transistors Tr of the four pixels in the left one column, the pixel unit PU includes the selection transistor SEL, the amplification transistor AMP, the switching transistor FDG, and the reset transistor RST in this order from the left.

The pixel unit PU having this pixel transistor arrangement is translation-symmetrically arranged in both the lateral direction and the longitudinal direction for each unit of a region including 4×4 pixels forming 16 pixels and having the color filters in the same color.

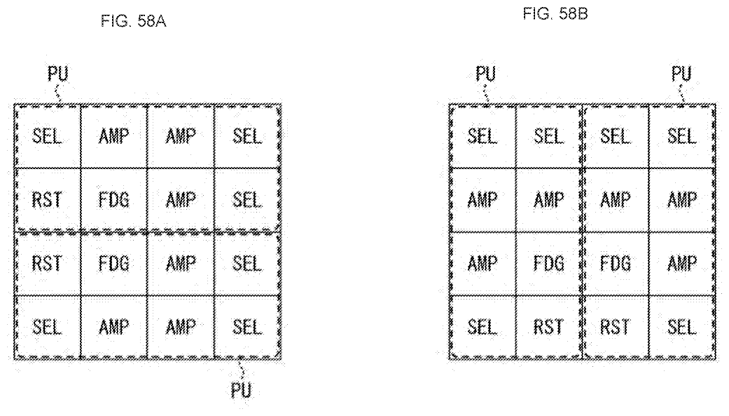

A of FIG. 58 depicts a third arrangement example of the pixel transistors Tr in the pixel units PU of the ninth configuration example.

According to the third configuration example, the one pixel unit PU includes 4×2 pixels forming eight pixels, and has a laterally elongated shape. The two pixel units PU within a region including 4×4 pixels forming 16 pixels and having the color filters in the same color are line-symmetrically arranged in the longitudinal direction.

Specifically, the upper pixel unit PU includes the selection transistor SEL, the amplification transistor AMP, the amplification transistor AMP, and the selection transistor SEL sequentially arranged in this order from the left in the upper one row, and includes the reset transistor RST, the switching transistor FDG, the amplification transistor AMP, and the selection transistor SEL sequentially arranged in this order from the left in the lower one row. The lower pixel unit PU includes the reset transistor RST, the switching transistor FDG, the amplification transistor AMP, and the selection transistor SEL sequentially arranged in this order from the left in the upper one row, and includes the selection transistor SEL, the amplification transistor AMP, the amplification transistor AMP, and the selection transistor SEL sequentially arranged in this order from the left in the lower one row.

The pixel unit PU having this pixel transistor arrangement is translation-symmetrically arranged in both the lateral direction and the longitudinal direction for each unit of a region including 4×4 pixels forming 16 pixels and having the color filters in the same color.

B of FIG. 58 depicts a fourth arrangement example of the pixel transistors Tr in the pixel units PU of the ninth configuration example.

According to the fourth configuration example, the one pixel unit PU includes 2×4 pixels forming eight pixels, and has a longitudinally elongated shape. The arrangement of the respective pixel transistors Tr is a switched arrangement of the third arrangement example in A of FIG. 58 into a longitudinally elongated shape. The two pixel units PU within a region including 4×4 pixels forming 16 pixels and having the color filters in the same color are line-symmetrically arranged in the lateral direction.

The pixel unit PU having this pixel transistor arrangement is translation-symmetrically arranged in both the lateral direction and the longitudinal direction for each unit of a region including 4×4 pixels forming 16 pixels and having the color filters in the same color.

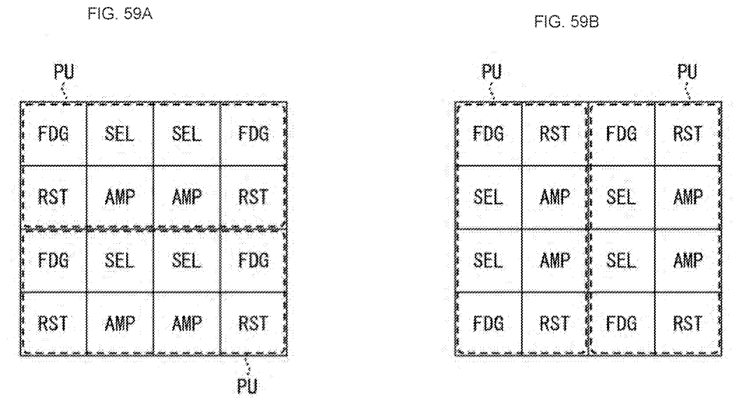

A of FIG. 59 depicts a fifth arrangement example of the pixel transistors Tr in the pixel units PU of the ninth configuration example.

According to the fifth configuration example, the one pixel unit PU includes 4×2 pixels forming eight pixels, and has a laterally elongated shape. The two pixel units PU located on the upper side and the lower side are translation-symmetrically arranged. According to the first to fourth wiring examples described above, the one pixel unit PU has the three amplification transistors AMP and the three selection transistors SEL, and further has the one reset transistor RST and the one switching transistor FDG. In the fifth arrangement example, the one pixel unit PU has the two amplification transistors AMP and the two selection transistors SEL, and further has the two reset transistors RST and the two switching transistors FDG.

Specifically, the pixel unit PU includes the switching transistor FDG, the selection transistor SEL, the selection transistor SEL, and the switching transistor FDG sequentially arranged in this order from the left in the upper one row, and includes the reset transistor RST, the amplification transistor AMP, the amplification transistor AMP, and the reset transistor RST sequentially arranged in this order from the left in the lower one row.

The pixel unit PU having this pixel transistor arrangement is translation-symmetrically arranged in both the lateral direction and the longitudinal direction for each unit of a region including 4×4 pixels forming 16 pixels and having the color filters in the same color.

B of FIG. 59 depicts a sixth arrangement example of the pixel transistors Tr in the pixel units PU of the ninth configuration example.

According to the sixth arrangement example, the one pixel unit PU includes 2×4 pixels forming eight pixels, and has a longitudinally elongated shape. The arrangement of the respective pixel transistors Tr is a switched arrangement of the fifth arrangement example in A of FIG. 59 into a longitudinally elongated shape. Specifically, as the pixel transistors Tr of the four pixels in the right one column, the pixel unit PU includes the reset transistor RST, the amplification transistor AMP, the amplification transistor AMP, and the reset transistor RST in this order from the top. As the pixel transistors Tr of the four pixels in the left one column, the pixel unit PU includes the switching transistor FDG, the selection transistor SEL, the selection transistor SEL, and the switching transistor FDG in this order from the left.

The pixel unit PU having this pixel transistor arrangement is translation-symmetrically arranged in both the lateral direction and the longitudinal direction for each unit of a region including 4×4 pixels forming 16 pixels and having the color filters in the same color.

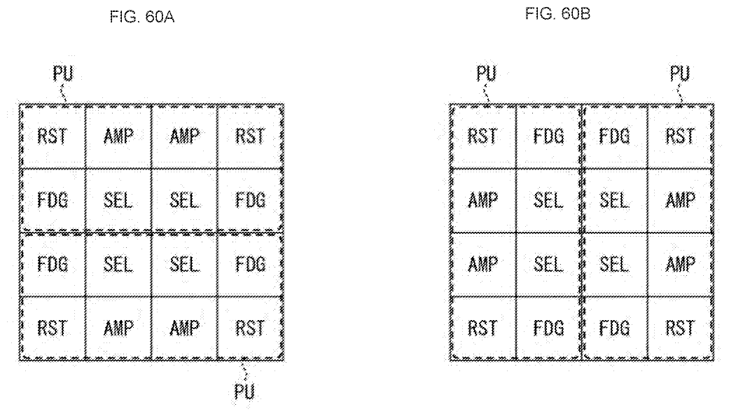

A of FIG. 60 depicts a seventh arrangement example of the pixel transistors Tr in the pixel units PU of the ninth configuration example.

According to the seventh arrangement example, the one pixel unit PU includes 4×2 pixels forming eight pixels, and has a laterally elongated shape. The one pixel unit PU has two sets of the amplification transistor AMP, the selection transistor SEL, the reset transistor RST, and the switching transistor FDG. The two pixel units PU within a region including 4×4 pixels forming 16 pixels and having the color filters in the same color are line-symmetrically arranged in the longitudinal direction.

Specifically, the upper pixel unit PU includes the reset transistor RST, the amplification transistor AMP, the amplification transistor AMP, and the reset transistor RST sequentially arranged in this order from the left in the upper one row, and includes the switching transistor FDG, the selection transistor SEL, the selection transistor SEL, and the switching transistor FDG sequentially arranged in this order from the left in the lower one row. The lower pixel unit PU includes the switching transistor FDG, the selection transistor SEL, the selection transistor SEL, and the switching transistor FDG sequentially arranged in this order from the left in the upper one row, and includes the reset transistor RST, the amplification transistor AMP, the amplification transistor AMP, and the reset transistor RST sequentially arranged in this order from the left in the lower one row.

The pixel unit PU having this pixel transistor arrangement is translation-symmetrically arranged in both the lateral direction and the longitudinal direction for each unit of a region including 4×4 pixels forming 16 pixels and having the color filters in the same color.

B of FIG. 60 depicts an eighth arrangement example of the pixel transistors Tr in the pixel units PU of the ninth configuration example.

According to the eighth arrangement example, the one pixel unit PU includes 2×4 pixels forming eight pixels, and has a longitudinally elongated shape. The arrangement of the respective pixel transistors Tr is a switched arrangement of the seventh arrangement example in A of FIG. 60 into a longitudinally elongated shape. The two pixel units PU within a region including 4×4 pixels forming 16 pixels and having the color filters in the same color are line-symmetrically arranged in the lateral direction.

The pixel unit PU having this pixel transistor arrangement is translation-symmetrically arranged in both the lateral direction and the longitudinal direction for each unit of a region including 4×4 pixels forming 16 pixels and having the color filters in the same color.

According to the fifth to eighth arrangement examples where two sets of the amplification transistor AMP and the selection transistor SEL and two sets of the reset transistor RST and the switching transistor FDG are provided, linkage by the FD link 541 is facilitated by arranging the switching transistors FDG at both the ends and allowing the switching transistors FDG to be adjacent to the switching transistors FDG of the different pixel unit PU.

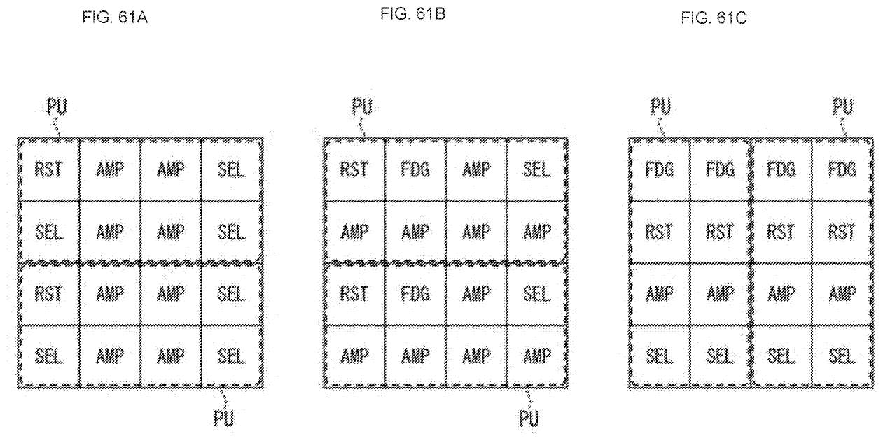

A of FIG. 61 depicts a ninth arrangement example of the pixel transistors Tr in the pixel units PU of the ninth configuration example.

The ninth arrangement example is such a pixel transistor arrangement example which includes, as the pixel transistors Tr of the eight pixels constituting one pixel unit PU, four amplification transistors AMP, three selection transistors SEL, and one reset transistor RST, and eliminates the switching transistor FDG.

According to the ninth arrangement example, the one pixel unit PU includes 4×2 pixels forming eight pixels, and has a laterally elongated shape. The two pixel units PU located on the upper side and the lower side are translation-symmetrically arranged. The pixel unit PU includes the reset transistor RST, the amplification transistor AMP, the amplification transistor AMP, and the selection transistor SEL sequentially arranged in this order from the left in the upper one row, and includes the selection transistor SEL, the amplification transistor AMP, the amplification transistor AMP, and the selection transistor SEL sequentially arranged in this order from the left in the lower one row. The two pixel units PU located on the upper side and the lower side may be arranged line-symmetrically rather than translation-symmetrically.

The pixel unit PU having this pixel transistor arrangement is translation-symmetrically arranged in both the lateral direction and the longitudinal direction for each unit of a region including 4×4 pixels forming 16 pixels and having the color filters in the same color.

B of FIG. 61 depicts a tenth arrangement example of the pixel transistors Tr in the pixel units PU of the ninth configuration example.

The tenth arrangement example is such a pixel transistor arrangement example which includes, as the pixel transistors Tr of the eight pixels constituting one pixel unit PU, the five amplification transistors AMP and one set of the reset transistor RST, the switching transistor FDG, and the selection transistor SEL.

According to the tenth arrangement example, the one pixel unit PU includes 4×2 pixels forming eight pixels, and has a laterally elongated shape. The two pixel units PU located on the upper side and the lower side are translation-symmetrically arranged. The pixel unit PU includes the reset transistor RST, the switching transistor FDG, the amplification transistor AMP, and the selection transistor SEL sequentially arranged in this order from the left in the upper one row, and includes the four amplification transistors AMP in the lower one row. The two pixel units PU located on the upper side and the lower side may be arranged line-symmetrically rather than translation-symmetrically.

The pixel unit PU having this pixel transistor arrangement is translation-symmetrically arranged in both the lateral direction and the longitudinal direction for each unit of a region including 4×4 pixels forming 16 pixels and having the color filters in the same color.

C of FIG. 61 depicts an eleventh arrangement example of the pixel transistors Tr in the pixel units PU of the ninth configuration example.

The eleventh arrangement example is such a pixel transistor arrangement example which includes, as the pixel transistors Tr of the eight pixels constituting one pixel unit PU, two sets of the switching transistor FDG, the reset transistor RST, the amplification transistor AMP, and the selection transistor SEL.

According to the eleventh arrangement example, the one pixel unit PU includes 2×4 pixels forming eight pixels, and has a longitudinally elongated shape. The two pixel units PU located on the left side and the right side are translation-symmetrically arranged. The pixel unit PU includes the switching transistor FDG, the reset transistor RST, the amplification transistor AMP, and the selection transistor SEL sequentially arranged in this order from the top in the right one column, and includes the switching transistor FDG, the reset transistor RST, the amplification transistor AMP, and the selection transistor SEL sequentially arranged in this order from the top in the left one row.

The pixel unit PU having this pixel transistor arrangement is translation-symmetrically arranged in both the lateral direction and the longitudinal direction for each unit of a region including 4×4 pixels forming 16 pixels and having the color filters in the same color.

### 18. Summary

The solid-state imaging device 1 includes the pixel array unit 3 that includes the pixels 2 two-dimensionally arranged in a matrix shape. Each of the pixels 2 has the photodiode PD as a photoelectric conversion element, the floating diffusion region FD, and the transfer transistor TG, and further has, as the one pixel transistor Tr other than the transfer transistor TG, any one of the reset transistor RST, the switching transistor FDG, the amplification transistor AMP, or the selection transistor SEL. In other words, each of the pixels 2 includes only two transistors, i.e., the pixel transistor Tr which is any one of the reset transistor RST, the switching transistor FDG, the amplification transistor AMP, or the selection transistor SEL, and the transfer transistor TG. This configuration increases the size of the pixel transistors and achieves a high resolution and a high dynamic range in a case where only one pixel transistor other than the transfer transistor is arrangeable within one pixel by more size reduction of pixels.

### 19. Examples of Application to Electronic Apparatus

Application of the technology of the present disclosure is not limited to application to a solid-state imaging device. Specifically, the technology of the present disclosure is applicable to electronic apparatuses in general each including a solid-state imaging device as an image pickup unit (photoelectric conversion unit), such as an imaging device as exemplified by a digital still camera or a video camera, a portable terminal device having an imaging function, and a copying machine including a solid-state imaging device as an image reading unit. The solid-state imaging device may have a one-chip form, or a module-shaped form having an imaging function as a package collectively including an imaging unit and a signal processing unit or an optical system.

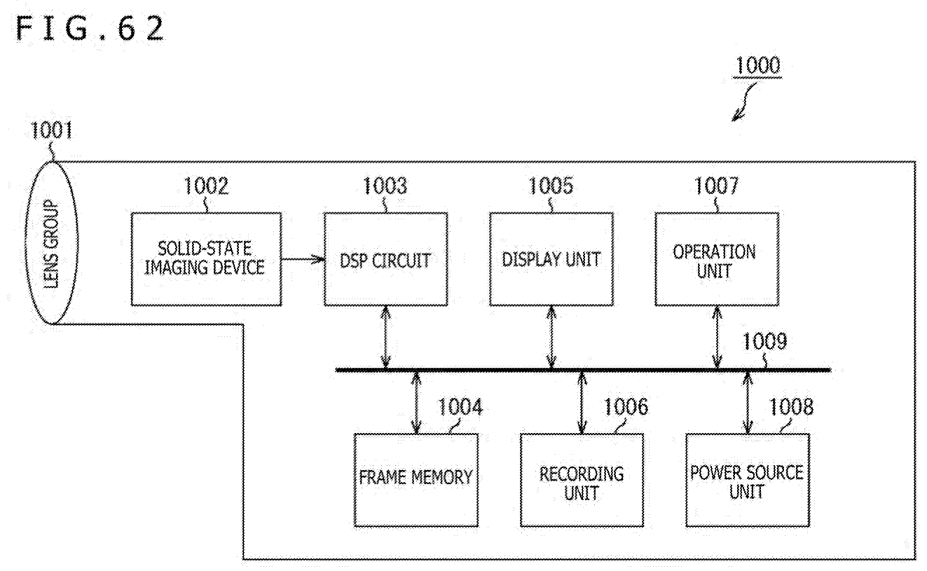

FIG. 62 is a block diagram depicting a configuration example of an imaging device as an electronic apparatus to which the technology of the present disclosure is applied.

An imaging device 1000 in FIG. 62 includes an optical unit 1001 having a lens group and the like, a solid-state imaging device (image capturing device) 1002 adopting the configuration of the solid-state imaging device 1 in FIG. 1, and a DSP (Digital Signal Processor) circuit 1003 which is a camera signal processing circuit. The imaging device 1000 further includes a frame memory 1004, a display unit 1005, a recording unit 1006, an operation unit 1007, and a power source unit 1008. The DSP circuit 1003, the frame memory 1004, the display unit 1005, the recording unit 1006, the operation unit 1007, and the power source unit 1008 are connected to one another via a bus line 1009.

The optical unit 1001 introduces incident light (image light) coming from a subject, and forms an image of the incident light on an imaging surface of the solid-state imaging device 1002. After the image of the incident light is formed on the imaging surface by the optical unit 1001, the solid-state imaging device 1002 converts light quantities of the incident light into electric signals for each pixel, and outputs the electric signals as pixel signals. The solid-state imaging device 1002 here may be the solid-state imaging device 1 in FIG. 1, i.e., a solid-state imaging device including the pixel array unit 3 which has the pixels 2 each including the photodiode PD as a photoelectric conversion element, the floating diffusion region FD, and the transfer transistor TG, and further including any one of the reset transistor RST, the switching transistor FDG, the amplification transistor AMP, or the selection transistor SEL as the one pixel transistor Tr other than the transfer transistor TG.

For example, the display unit 1005 includes a thin display such as an LCD (Liquid Crystal Display) and an organic EL (Electro Luminescence) display, and displays moving images or still images captured by the solid-state imaging device 1002. The recording unit 1006 records the moving images or the still images captured by the solid-state imaging device 1002 in a recording medium such as a hard disk and a semiconductor memory.

The operation unit 1007 issues operation commands associated with various functions of the imaging device 1000 under operation by a user. The power source unit 1008 appropriately supplies various types of power sources corresponding to operation power sources for the DSP circuit 1003, the frame memory 1004, the display unit 1005, the recording unit 1006, and the operation unit 1007 to these supply targets.

As described above, the large-sized pixel transistors are arrangeable, and a high resolution and a high dynamic range are achievable by adopting the solid-state imaging device 1 described above as the solid-state imaging device 1002. Accordingly, high-quality images are also acquirable by the imaging device 1000 such as a video camera and a digital still camera, and further a camera module for cellular phones and other mobile devices.

### Use Examples of Image Sensor

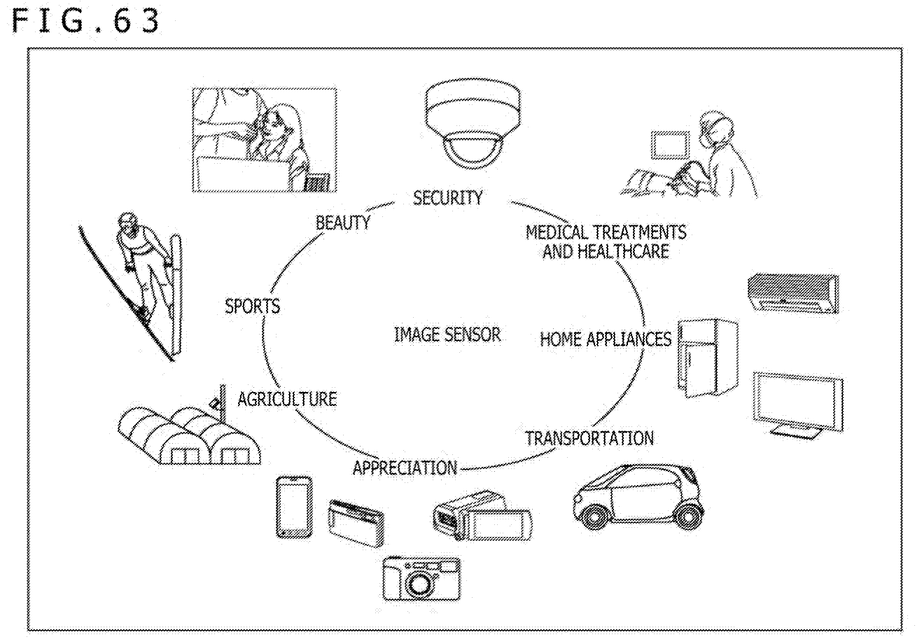

FIG. 63 is a diagram depicting use examples of an image sensor including the solid-state imaging device 1 described above.

For example, the solid-state imaging device 1 described above is available as an imaging sensor in various cases associated with sensing of light such as visible light, infrared light, ultraviolet light, and X-rays as will be described below.
A device for capturing images provided for appreciation, such as a digital camera and a portable device equipped with a camera function
A device provided for transportation, such as an in-vehicle sensor for capturing images before and behind, surroundings, and an interior of a car, a monitoring camera for monitoring running vehicles and roads, and a distance measuring sensor for measuring distances between vehicles and the like, each for purposes of safety driving such as an automatic stop, recognition of a state of a driver, and others
A device provided for home appliances, such as a television set, a refrigerator, and an air conditioner, for capturing an image of a gesture of a user and performing a device operation according to the gesture
A device provided for medical treatments and healthcare, such as an endoscope and a device performing angiogram by received infrared light
A device provided for security, such as a monitoring camera for crime prevention and a camera for person authentication
A device provided for beauty, such as a skin measuring device for capturing an image of skin and a microscope for capturing an image of scalp
A device provided for sports, such as an action camera for sports and a wearable camera
A device provided for agriculture, such as a camera for monitoring states of fields and crops

### 20. Examples of Application to Mobile Body

The technology according to the present disclosure (present technology) is applicable to various products. For example, the technology according to the present disclosure may be implemented as a device mounted on any type of mobile bodies such as a car, an electric car, a hybrid electric car, a motorcycle, a bicycle, a personal mobility, an airplane, a drone, a vessel, and a robot.

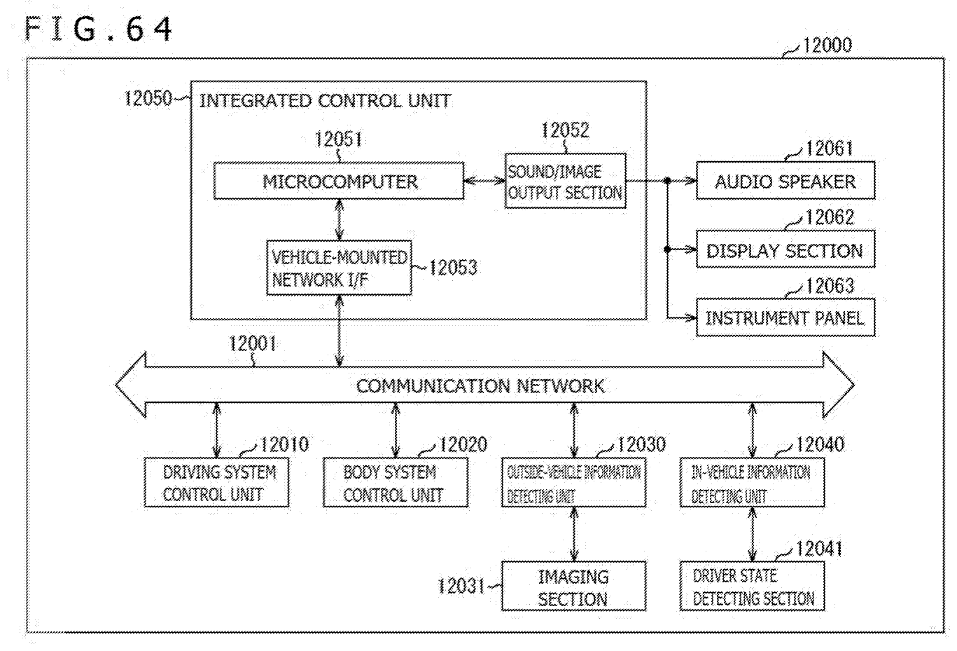

FIG. 64 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 64, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 64, an audio speaker 12061, a display section 12062, and an instrument panel 12063 are illustrated as the output device. The display section 12062 may, for example, include at least one of an on-board display and a head-up display.

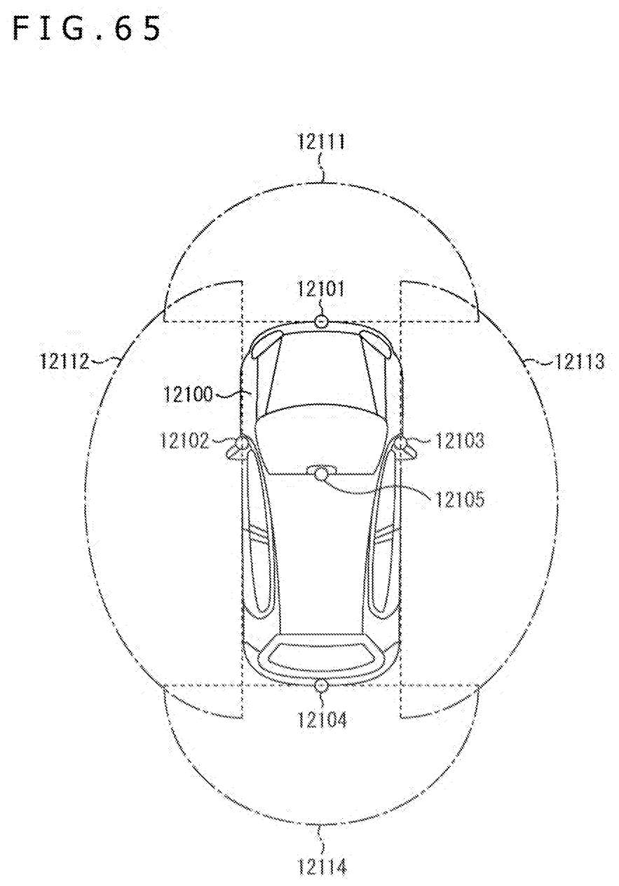

FIG. 65 is a diagram depicting an example of the installation position of the imaging section 12031.

In FIG. 65, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 65 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Described above has been one example of the vehicle control system to which the technology according to the present disclosure is applicable. The technology according to the present disclosure is applicable to the imaging section 12031 in the configuration described above. Specifically, the solid-state imaging device 1 described above is applicable to the imaging section 12031. The imaging section 12031 to which the technology according to the present disclosure is applied allows acquisition of a captured image achieving a high resolution and a high dynamic range, and acquisition of distance information. Moreover, reduction of fatigue of the driver and improvement of safety of the driver and the vehicle are achievable with use of the captured image and the distance information thus acquired.

While described in the above examples has been the solid-state imaging device which designates the P-type as the first conductivity-type, the N-type as the second conductivity-type, and electrons as signal charge, the present disclosure is also applicable to a solid-state imaging device designating holes as signal charge. Specifically, opposite conductivity-type semiconductor regions may be formed in the respective semiconductor regions described above by designating the N-type as the first conductivity-type and the P-type as the second conductivity-type.

Moreover, application of the present disclosure is not limited to application to a solid-state imaging device which detects distribution of incident light quantity of visible light and obtains the distribution as an image, and may be application to a solid-state imaging device which obtains distribution of an incident quantity of infrared rays, X-rays, particles, or the like as an image, and solid-state imaging devices (physical quantity distribution detection devices) in general in a broad sense, such as a fingerprint detection sensor which detects distribution of pressure, capacitance, or other physical quantities, and obtains the distribution as an image.

Further, the technology according to the present disclosure is applicable to not only a solid-state imaging device, but also semiconductor devices in general each including a different semiconductor integrated circuit.

Embodiments of the present disclosure are not limited to the embodiments described above, and may be modified in various manners within the scope not departing from the subject matters of the technology of the present disclosure.

For example, a mode combining all or a part of the plurality of embodiments described above may be adopted.

Note that advantageous effects to be offered are not limited to those described in the present description presented only by way of example. Advantageous effects other than those described in the present description may be offered.

Note that the technology of the present disclosure can take the following configurations.

(1)

A solid-state imaging device including:
a pixel array unit that includes pixels each having a photoelectric conversion element, a floating diffusion region, a transfer transistor, and one pixel transistor other than a transfer transistor, the pixels being two-dimensionally arranged in a matrix shape, in which
the one pixel transistor is any one of a reset transistor, a switching transistor, an amplification transistor, or a selection transistor.

(2)

The solid-state imaging device according to (1) above, in which
a pixel unit has four or more pixels including,
   as the one pixel transistor, a reset transistor pixel that is the pixel having the reset transistor,
   as the one pixel transistor, a switching transistor pixel that is the pixel having the switching transistor,
   as the one pixel transistor, an amplification transistor pixel that is the pixel having the amplification transistor, and
   as the one pixel transistor, a selection transistor pixel that is the pixel having the selection transistor, and
the pixel unit shares the switching transistor, the amplification transistor, the reset transistor, and the selection transistor, and the floating diffusion regions of the respective pixels.

(3)

The solid-state imaging device according to (2) above, in which the pixel unit includes 1×4 pixels forming four pixels.

(4)

The solid-state imaging device according to (2) above, in which the pixel unit includes 2×2 pixels forming four pixels.

(5)

The solid-state imaging device according to (2) above, in which the pixel unit includes 4×2 pixels forming eight pixels.

(6)

The solid-state imaging device according to (5) above, in which the eight pixels included in the pixel unit are one set of the switching transistor pixel, one set of the reset transistor pixel, three sets of the amplification transistor pixels, and three sets of the selection transistor pixels.

(7)

The solid-state imaging device according to any one of (2) through (6) above, in which the pixel array unit includes a plurality of the pixel units where the switching transistor pixels are electrically connected to each other via a metal wire.

(8)

The solid-state imaging device according to any one of (2) through (7) above, in which
the reset transistor pixel and the switching transistor pixel are arranged adjacently to each other within the pixel unit, and
the amplification transistor pixel and the selection transistor pixel are arranged adjacently to each other within the pixel unit.

(9)

The solid-state imaging device according to any one of (2) through (8) above, in which
the reset transistor pixel and the switching transistor pixel are line-symmetrically arranged with respect to a center line of the reset transistor pixel and the switching transistor pixel, and
the amplification transistor pixel and the selection transistor pixel are line-symmetrically arranged with respect to a center line of the amplification transistor pixel and the selection transistor pixel.

(10)

The solid-state imaging device according to (9) above, in which
the floating diffusion region of each of the pixels is located closer to the center line than the pixel transistor, and
the pixel transistor of each of the pixels is located farther from the center line than the floating diffusion region.

(11)

The solid-state imaging device according to (9) above, in which
the pixel transistor of each of the pixels is located closer to the center line than the floating diffusion region, and
the floating diffusion region of each of the pixels is located farther from the center line than the pixel transistor.

(12)

The solid-state imaging device according to any one of (2) through (11) above, in which the reset transistor pixel and the switching transistor pixel and the amplification transistor pixel and the selection transistor pixel are line-symmetrically arranged with respect to a center line of the reset transistor pixel and the switching transistor pixel and the amplification transistor pixel and the selection transistor pixel.

(13)

The solid-state imaging device according to any one of (2) through (12) above, in which the amplification transistor pixel is arranged in either one of inner two pixels of the pixel unit including the 1×4 pixels forming the four pixels.

(14)

The solid-state imaging device according to any one of (2) through (13) above, in which two sets of the pixel units adjacent to each other in a longitudinal direction are line-symmetrically arranged with respect to a center line of the two pixel units.

(15)

The solid-state imaging device according to any one of (2) through (14) above, in which two sets of the pixel units adjacent to each other in a lateral direction are line-symmetrically arranged with respect to a center line of the two pixel units.

(16)

The solid-state imaging device according to any one of (2) through (15) above, in which a plurality of the pixel units are translation-symmetrically arranged in a lateral direction of the pixel array unit.

(17)

The solid-state imaging device according to any one of (2) through (16) above, in which a plurality of the pixel units are translation-symmetrically arranged in a longitudinal direction of the pixel array unit.

(18)

The solid-state imaging device according to any one of (1) through (17) above, in which the one pixel transistor includes a Fin-type MOS transistor.

(19)

The solid-state imaging device according to any one of (1) through (18) above, in which
each of the pixels includes a pixel separation portion in an outer peripheral portion of a pixel region, and
the pixel separation portion is contained in an element separation region in a planar view, the element separation region being a portion separating the transfer transistor from the one pixel transistor.

(20)

An electronic apparatus including:
a solid-state imaging device including a pixel array unit that includes pixels each having a photoelectric conversion element, a floating diffusion region, a transfer transistor, and one pixel transistor other than a transfer transistor, the pixels being two-dimensionally arranged in a matrix shape, in which
the one pixel transistor is any one of a reset transistor, a switching transistor, an amplification transistor, or a selection transistor.

### REFERENCE SIGNS LIST

1: Solid-state imaging device
2: Pixel
PD: Photodiode
TG: Transfer transistor
Tr: Pixel transistor
FD: Floating diffusion region
FDG: Switching transistor
RST: Reset transistor
SEL: Selection transistor
subFD: Additional capacitance
AMP; Amplification transistor
PU: Pixel unit
OCL: On-chip lens
1M: Wiring layer
2M: Wiring layer
3: Pixel array unit
12: Semiconductor substrate
21: Pixel separation portion
22: Well contact portion
23: High concentration N-type layer
26: Active region
27: Element separation region
31: Planar portion
32: Included portion
33: Gate electrode
34: Gate electrode
41, 421, 541: FD link
601, 602: Shared wire
1000: Imaging device
1002: Solid-state imaging device

1. A solid-state imaging device comprising:
a pixel array unit that includes pixels each having a photoelectric conversion element, a floating diffusion region, a transfer transistor, and one pixel transistor other than a transfer transistor, the pixels being two-dimensionally arranged in a matrix shape, wherein
the one pixel transistor is any one of a reset transistor, a switching transistor, an amplification transistor, or a selection transistor.

2. The solid-state imaging device according to claim 1, wherein
a pixel unit has four or more pixels including,
as the one pixel transistor, a reset transistor pixel that is the pixel having the reset transistor,
as the one pixel transistor, a switching transistor pixel that is the pixel having the switching transistor,
as the one pixel transistor, an amplification transistor pixel that is the pixel having the amplification transistor, and
as the one pixel transistor, a selection transistor pixel that is the pixel having the selection transistor, and
the pixel unit shares the switching transistor, the amplification transistor, the reset transistor, and the selection transistor, and the floating diffusion regions of the respective pixels.

3. The solid-state imaging device according to claim 2, wherein the pixel unit includes 1×4 pixels forming four pixels.

4. The solid-state imaging device according to claim 2, wherein the pixel unit includes 2×2 pixels forming four pixels.

5. The solid-state imaging device according to claim 2, wherein the pixel unit includes 4×2 pixels forming eight pixels.

6. The solid-state imaging device according to claim 5, wherein the eight pixels included in the pixel unit are one set of the switching transistor pixel, one set of the reset transistor pixel, three sets of the amplification transistor pixels, and three sets of the selection transistor pixels.

7. The solid-state imaging device according to claim 2, wherein the pixel array unit includes a plurality of the pixel units where the switching transistor pixels are electrically connected to each other via a metal wire.

8. The solid-state imaging device according to claim 2, wherein
the reset transistor pixel and the switching transistor pixel are arranged adjacently to each other within the pixel unit, and
the amplification transistor pixel and the selection transistor pixel are arranged adjacently to each other within the pixel unit.

9. The solid-state imaging device according to claim 2, wherein
the reset transistor pixel and the switching transistor pixel are line-symmetrically arranged with respect to a center line of the reset transistor pixel and the switching transistor pixel, and
the amplification transistor pixel and the selection transistor pixel are line-symmetrically arranged with respect to a center line of the amplification transistor pixel and the selection transistor pixel.

10. The solid-state imaging device according to claim 9, wherein
the floating diffusion region of each of the pixels is located closer to the center line than the pixel transistor, and
the pixel transistor of each of the pixels is located farther from the center line than the floating diffusion region.

11. The solid-state imaging device according to claim 9, wherein
the pixel transistor of each of the pixels is located closer to the center line than the floating diffusion region, and
the floating diffusion region of each of the pixels is located farther from the center line than the pixel transistor.

12. The solid-state imaging device according to claim 2, wherein the reset transistor pixel and the switching transistor pixel and the amplification transistor pixel and the selection transistor pixel are line-symmetrically arranged with respect to a center line of the reset transistor pixel and the switching transistor pixel and the amplification transistor pixel and the selection transistor pixel.

13. The solid-state imaging device according to claim 2, wherein the amplification transistor pixel is arranged in either one of inner two pixels of the pixel unit including the 1×4 pixels forming the four pixels.

14. The solid-state imaging device according to claim 2, wherein two sets of the pixel units adjacent to each other in a longitudinal direction are line-symmetrically arranged with respect to a center line of the two pixel units.

15. The solid-state imaging device according to claim 2, wherein two sets of the pixel units adjacent to each other in a lateral direction are line-symmetrically arranged with respect to a center line of the two pixel units.

16. The solid-state imaging device according to claim 2, wherein a plurality of the pixel units are translation-symmetrically arranged in a lateral direction of the pixel array unit.

17. The solid-state imaging device according to claim 2, wherein a plurality of the pixel units are translation-symmetrically arranged in a longitudinal direction of the pixel array unit.

18. The solid-state imaging device according to claim 1, wherein the one pixel transistor includes a Fin-type MOS transistor.

19. The solid-state imaging device according to claim 1, wherein
each of the pixels includes a pixel separation portion in an outer peripheral portion of a pixel region, and
the pixel separation portion is contained in an element separation region in a planar view, the element separation region being a portion separating the transfer transistor from the one pixel transistor.

20. An electronic apparatus comprising:
a solid-state imaging device including a pixel array unit that includes pixels each having a photoelectric conversion element, a floating diffusion region, a transfer transistor, and one pixel transistor other than a transfer transistor, the pixels being two-dimensionally arranged in a matrix shape, wherein
the one pixel transistor is any one of a reset transistor, a switching transistor, an amplification transistor, or a selection transistor.
